(19) United States
(12) Patent Application Publication
(10) Pub. No.: US 2023/0280395 A1
(43) Pub. Date: Sep. 7, 2023

(54) COUPLER SENSING BASED VOLTAGE-STANDING-WAVE-RATIO IMPEDANCE AND POWER DETECTOR AND METHOD

(71) Applicant: Georgia Tech Research Corporation, Atlanta, GA (US)

(72) Inventors: David J. Munzer, Atlanta, GA (US); Naga Sasikanth Mannem, Atlanta, GA (US); Hua Wang, Atlanta, GA (US)

(21) Appl. No.: 18/168,545

(22) Filed: Feb. 13, 2023

Related U.S. Application Data
(60) Provisional application No. 63/267,847, filed on Feb. 11, 2022.
(60) Provisional application No. 63/267,840, filed on Feb. 11, 2022.
(60) Provisional application No. 63/386,458, filed on Dec. 7, 2022.

(51) Int. Cl. G01R 31/28; G01R 27/26

(52) U.S. Cl. CPC G01R 31/2856; G01R 27/2664; G01R 31/2837

(57) ABSTRACT

A broadband-capable coupler sensing-based VSWR resilient true power/impedance detector (also referred to as a power/impedance sensor) and method are disclosed that can be used for single-ended interfaces of individual phased array elements of a phased array antenna, e.g., large-scaled integrated phased-arrays. The true power and impedance detectors, as Built-in-Self-Test circuitries, may each employ an in situ load invariant power and impedance sensor to provide true measurements of power and impedance that can be used to detect and/or monitor for VSWR variations and/or variations in the antenna driving impedance due to antenna element coupling and/or other effects. The measured power and impedance output(s) of each BIST circuitry can then be used to adjust or drive respective passive or active tuning circuitry, e.g., in the power amplifier or other front-end circuitries of the phased array antenna, for performance recovery (or optimization) of a respective array element.

### RELATED APPLICATION

This U.S. application claims priority to, and the benefit of, U.S. Provisional Patent Application No. 63/267,847, filed Feb. 11, 2022, entitled “SYSTEMS AND METHODS FOR A SINGLE ENDED COUPLED BROADBAND SENSOR”; U.S. Provisional Patent Application No. 63/386,458, filed Dec. 7, 2022, entitled “A COMPACT AND BROADBAND VSWR-RESILIENT POWER GAIN ESTIMATOR WITH DYNAMIC RANGE COMPENSATION FOR PHASED ARRAY APPLICATIONS”; U.S. Provisional Patent Application No. 63/267,840, filed Feb. 11, 2022, entitled “SYSTEMS AND METHODS FOR A COUPLER-BASED SENSOR AND DETECTOR,” each of which is hereby incorporated by reference in its entirety.

### FIELD OF THE DISCLOSURE

The various embodiments of the present disclosure relate generally to systems and methods for electric circuits, e.g., for use with a phased array antenna, in particular for 5G, mm-Wave, or RADAR applications.

### BACKGROUND

5G mm-Wave (24-40 GHz) is an enabling technology to support data traffic with a wide-available spectrum and spectrally efficient modulation schemes, such as high-order quadrature amplitude modulation (QAM) and orthogonal frequency-division multiplexing (OFDM). mm-Wave 5G wireless can readily support multi-Gb/s datalinks.

To overcome the mm-Wave free space path loss, phased arrays are widely employed. However, antenna element coupling within arrays is inevitable through near field couplings and substrate modes, causing the antenna driving impedance to deviate from the nominal 50Ω antenna's Voltage Standing Wave Ratio (VSWR) or the array's active impedance. In phased arrays, antenna VSWR is a dynamic phenomenon that can vary with the beam steering angle, antenna element placement, array configuration, and operation modes (e.g., MIMO/beamforming). That is, the antenna coupling can cause dynamic beam-dependent impedance variations (antenna VSWR) and front-end degradation. Even well-designed low-coupling arrays can experience up to 3:1 VSWR.

Multiple designs have demonstrated VSWR resilient impedance sensing on single-ended loads. However, they either add signal loss, limit the power amplifier (PA) output matching network (OMN)s bandwidth (BW), or modify the OMN's impedance transformation ratio, at a single frequency.

There is a benefit to improving phased array implementations for mm-Wave devices and other applications described herein.

### SUMMARY

A broadband-capable coupler sensing-based VSWR resilient true power/impedance detector (also referred to as a power/impedance sensor) and method are disclosed that can be used for single-ended interfaces of individual phased array elements of a phased array antenna, e.g., large-scaled integrated phased-arrays. A broadband-capable current/voltage sensing-based VSWR resilient true power/impedance detector (also referred to as a power/impedance sensor) and method are also disclosed that can be used for single-ended interfaces of individual phased array elements of a phased array antenna, e.g., large-scaled integrated phased-arrays. Either true power and impedance detectors, as Built-in-Self-Test (BiST or BIST) circuitries, may each employ an in situ load invariant power and impedance sensor to provide true measurements of power and impedance that can be used to detect and/or monitor for VSWR variations and/or variations in the antenna driving impedance due to antenna element coupling and/or other effects. The measured power and impedance output(s) of each BIST circuitry can then be used to adjust or drive respective passive or active tuning circuitry, e.g., in the power amplifier or other front-end circuitries of the phased array antenna, for performance recovery (or optimization) of a respective array element.

The term “array” is a set of multiple connected antennas which work together as a single antenna to transmit or receive radio waves and can include any type of array, such as, for example, multiple-input and multiple-output (MIMO) arrays.

The exemplary power/impedance may employ one or more sets of current and voltage sensing structures integrated into each phased array element to provide sensed current(s) and voltage(s). In some embodiments, one set of the sensed current and voltage measurements can be multiplied, via an analog multiplier, to provide the sensed power measurement for that phased array element, and the second set of the sensed current and voltage measurements may be employed in a spaced-optimized dual amplitude detector to determine the amplitude of the current and voltage to provide for the sensed impedance measurement. In an implementation, the exemplary sensor employs a balun in combination with a symmetric multiplier that can provide accurate broadband operation over the entire Ka-band and the 5G FR2 24/28/39 GHz bands and can be applied to any power-amplifier architecture.

A first prototype circuit employing the balun in combination with the symmetric multiplier was fabricated using 45 nm CMOS SOI processes. At 34 GHz, the prototyped circuit can provide measurements with a power sensing error (PSE)≤±1 dB for 3:1 VSWR and ±0.5 dB for 2:1 VSWR. Over the 22-41 GHz, the measured PSE is ≤±3.4 dB for 3:1 VSWR and ±1.5 dB for 2:1 VSWR. In addition, the prototyped circuit under a 50Ω load demonstrated a maximum dynamic range of 22.89 dB at 42 GHz and a dynamic range >21.46 dB over 27-41 GHz. At 33 GHz, the measured |Γ|/∠Γ errors were ≤0.072/7.3° for 3:1 VSWR and ≤0.04/7.13° for 2:1 VSWR, while demonstrating |Γ|/∠Γ errors of ≤0.2/34° for 3:1 VSWR and ≤0.11/27° for 2:1 VSWR over the entire 27-41 GHz BW. The chip die occupied an area of 0.97×1.99 mm2 and a sensor core area of 0.48×1.66 mm2.

In another implementation, the exemplary sensor replaces the balun and symmetric multiplier of the power detector with a space-and-power-optimized parallel power detector comprising (i) a differential current/voltage sensor and (ii) a single-ended voltage passive sensing circuit that employs a differential voltage sensing in combination with an error cancellation circuit. With respect to space, rather than employing two sets of differential signals via the above-noted symmetric multiplier, the space-and-power-optimized-differential-current/voltage-and-single-ended-voltage sensing circuit employs a multiplier that (i) operates on a paired differential current and a voltage signal set and (ii) replaced the other differential signal set with a single-end voltage signal. The noted error cancellation circuit generates an intentional offset or error that is employed in the circuit to cancel out undesired errors resulting from the loss of accuracy in employing the single-end voltage signal.

With respect to power, the space-and-power-optimized-differential-current/voltage-and-single-ended-voltage sensing circuit includes (i) an active detector for the differential-current/voltage sensing and (ii) a passive detector using the single-end voltage sensing, as the parallel power detector in which the passive detector can be operated for the most part without any power consumption and in which the active detector provides the paired differential current and voltage signals to accurately update the proportionality function of the passive detector for the various varying loads. Without this update, the proportionality function would be inaccurate for the passive detector as the load varies.

A second prototype circuit employing the space-and-power-optimized differential current/single-ended voltage sensing circuit was fabricated also using 45 nm CMOS SOI processes. The space-and-power-optimized sensing circuitries can provide a 10× reduction in size for the baluns employed in the first prototype circuit while providing comparable operational performance and capabilities. With respect to power, in using the passive detector in combination with the active detector to track load, the space-and-power-optimized sensing circuitries substantially reduced power usage by almost 4× as compared to the first prototype circuit. By updating the passive detector using the active detector at a pre-defined update cycle, the power saving would increase greater than 4×. In addition, by employing the passive detector, a detector would be in continuous operations, thus improving latency metrics since the passive detector does not need to be turned off.

In an aspect, a system (e.g., a phased array RADAR system, a 5G and/or mmWave base station, or a 5G or mmWave handset) is disclosed comprising a set of amplifiers (e.g., reconfigurable power amplifiers), wherein each of the set of amplifiers is connected via an output transmission line to a respective phased array antenna element of a phased array antenna; and a set of built-in self-test circuits, including a first built-in self-test circuit, wherein each of the set of built-in self-test circuits is configured to measure a voltage standing wave ratio (VSWR) or load impedance deviation for a respective amplifier of the set of amplifiers, including a first amplifier (e.g., to reconfigure the respective amplifier to compensate for phased array antenna element coupling or other couplings), wherein the first built-in self-test circuit comprises: a self-test circuit sensing circuit configured to output a sensed signal and a sensed impedance signal, via coupler-based sensing, as the measure of the voltage standing wave ratio (VSWR) or load impedance deviation; a first sensing electromagnetic (EM) structure as a first sensing transmission line that is co-located to the output transmission line to be capacitively coupled therewith, the first sensing electromagnetic structure having (i) a first end that connects to a corresponding end of the output transmission line through a pre-defined impedance and (ii) a second end that connects to a first input of the built-in self-test circuit sensing circuit; and a second sensing electromagnetic structure as a second sensing transmission line that is co-located to the output transmission line to be capacitively coupled therewith, the second sensing electromagnetic structure having (i) a first end that connects to an impedance element having a value corresponding to the phased array antenna element and (ii) a second end that connects to a second input of the built-in self-test circuit sensing circuit.

In some embodiments, the first sensing electromagnetic structure and the second sensing electromagnetic structure each have a length of λ/4.

In some embodiments, the self-test circuit sensing circuit includes an impedance sensing circuit comprising (i) a first amplitude detector (e.g., multi-stage Dickson rectifier) for a first sensed signal at the first input and (ii) a second amplitude detector (e.g., multi-stage Dickson rectifier) for a second sensed signal at the second input, wherein one of the first sensed signal or the second sensed signal corresponds to a sensed current signal and the other to a sensed voltage signal, and wherein the sensed current signal and sensed voltage signal are combined to a provide the sensed impedance signal.

In some embodiments, the first amplifier comprises an output matching network that connects to a first output of the self-test circuit sensing circuit, wherein the output matching network is configured to receive the sensed impedance signal to adjust the output of the first amplifier to compensate for phased array antenna element coupling or other couplings.

In some embodiments, the self-test circuit sensing circuit includes an impedance sensing circuit comprising (i) a first phase shifter (e.g., multi-stage Dickson rectifier) for a first sensed signal at the first input and (ii) a second phase shifter (e.g., multi-stage Dickson rectifier) for a second sensed signal at the second input, wherein the one of the first sensed signal or the second sensed signal corresponds to a sensed current signal and the other to a sensed voltage signal, and wherein the sensed current signal and sensed voltage signal are combined to a provide the sensed power signal.

In some embodiments, the first amplifier comprises an output matching network that connects to a second output of the self-test circuit sensing circuit, wherein the output matching network is configured to receive the sensed power signal to adjust the output of the first amplifier to compensate for phased array antenna element coupling or other couplings.

In some embodiments, the first phase shifter or the second phase shifter is configured to provide a 90° shift.

In some embodiments, the output transmission line, the first sensing electromagnetic structure, and the second sensing electromagnetic structure are fabricated in a multilayer structure, wherein the output transmission line is located on a first layer, wherein the first sensing electromagnetic structure is located on a second layer immediately above or proximal on the same layer to the first layer, and wherein the second sensing electromagnetic structure is located on a third layer immediately below or proximal to on the same layer to the first layer.

In some embodiments, the system further includes the phased array antenna.

In some embodiments, at least one of the first-phase shifter or the second phase shifter comprises a multi-stage Dickson rectifier.

In some embodiments, the system comprises a phased array RADAR system, a phased array RADAR antenna component, a 5G and/or mmWave base station, a 5G or mmWave handset, or a 5G or mmWave phased array antenna component.

In some embodiments, the self-test circuit sensing circuit is configured to generate one or more test signals, via the coupler-based sensing, at one or more antenna array elements to be coupled to one or more adjacent or nearby antenna array elements to evaluate complex coupling, coefficient matrix, power flow, and impedance mismatches for multi-elements or all of the array.

In another aspect, a method is disclosed of compensating for phased array element coupling error during the operation of a phased array antenna (e.g., phased array RADAR system, a 5G and/or mmWave base station, or a 5G or mmWave handset), the method comprising: measuring a voltage standing wave ratio (VSWR) or load impedance deviation for an amplifier of a phased array element comprising a sensed power signal and a sensed impedance signal (e.g., impedance magnitude signal) measured at a set of sensing electromagnetic (EM) structures co-located to an output transmission line connecting between the amplifier and phased array element, wherein the set of sensing electromagnetic (EM) structures includes: a first sensing electromagnetic (EM) structure as a first sensing transmission line that is co-located to the output transmission line to be capacitively coupled therewith, the first sensing electromagnetic structure having (i) a first end that connects to a corresponding end of the output transmission line through a pre-defined impedance and (ii) a second end that connects to a first input of the built-in self-test circuit sensing circuit; and a second sensing electromagnetic structure as a second sensing transmission line that is co-located to the output transmission line to be capacitively coupled therewith, the second sensing electromagnetic structure having (i) a first end that connects to an impedance element having a value corresponding the phased array antenna element and (ii) a second end that connects to a second input of the built-in self-test circuit sensing circuit; and reconfiguring (i) the amplifier, (ii) a phased array element associated circuit, or (iii) a combination thereof, using the sensed power signal and the sensed impedance signal.

In some embodiments, the measuring the voltage standing wave ratio (VSWR) or load impedance deviation includes: sensing amplitude signals, as the sensed impedance signal, corresponding to impedance magnitude via sensing circuitries connected to the first sensing electromagnetic (EM) structure and the second sensing electromagnetic (EM) structure.

In some embodiments, the measuring the voltage standing wave ratio (VSWR) or load impedance deviation includes: generating at least one phased shifted signal via an analog circuitry from at least one signal sensed by the first sensing electromagnetic (EM) structure or the second sensing electromagnetic (EM) structure; and combining (i) the phased shifted signal and (ii) the other of the first sensing electromagnetic (EM) structure or the second sensing electromagnetic (EM) structure not used to generate the phased shifted signal to generate the sensed power signal.

In some embodiments, the phased shifted signal is 90° shifted.

In some embodiments, the method further includes measuring the voltage standing wave ratio (VSWR) or load impedance deviation for a second amplifier of a second phased array element comprising a second sensed power signal and a second sensed impedance signal (e.g., impedance magnitude signal) measured at a second set of sensing electromagnetic structures co-located to a second output transmission line connecting between the second amplifier and the second phased array element (e.g., wherein the second set of sensing electromagnetic (EM) structures includes (a) a first sensing electromagnetic (EM) structure as a first sensing transmission line that is co-located to the output transmission line to be capacitively coupled therewith, the first sensing electromagnetic structure having (i) a first end that connects to a corresponding end of the output transmission line through a pre-defined impedance and (ii) a second end that connects to a first input of the built-in self-test circuit sensing circuit; and (b) a second sensing electromagnetic structure as a second sensing transmission line that is co-located to the output transmission line to be capacitively coupled therewith, the second sensing electromagnetic structure having (i) a first end that connects to an impedance element having a value corresponding the phased array antenna element and (ii) a second end that connects to a second input of the built-in self-test circuit sensing circuit; and sreconfiguring (i) the second amplifier, (ii) a second phased array element associated circuit, or (iii) a combination thereof, using the second sensed power signal and the second sensed impedance signal.

In another aspect, a system (e.g., a RADAR array system, a satellite payload system, a satellite ground terminal, a 5G and/or mmWave base station, or a 5G or mmWave handset) is disclosed comprising an array antenna comprising a set of N array antenna elements; a set of amplifiers (e.g., amplifiers or reconfigurable amplifiers), wherein each of the set of amplifiers is coupled to an array element of the set of N array antenna elements; and a set of built-in self-test circuits, including a first built-in self-test circuit, wherein each of the set of built-in self-test circuits is configured to measure a voltage standing wave ratio (VSWR) or the real or complex load impedance for a respective amplifier of the set of amplifiers (e.g., to reconfigure the respective amplifier to compensate for array element coupling or other couplings), wherein the first built-in self-test circuit comprises: a first voltage sensing structure and a second voltage sensing structure each co-located at, or proximate to, a single-ended terminal or multi-feed terminals defined by the array element; a first current sensing structure and a second current sensing structure each co-located at, or proximate to, the single-ended terminal or multi-feed terminals defined by the array element; a power sensing circuit operatively coupled to the first voltage sensing structure and the first current sensing structure to receive (i) a first sensed voltage signal from the first voltage sensing structure and (ii) a first sensed current signal from the first current sensing structure; and an impedance sensing circuit (e.g., implemented using amplitude detectors) coupled to (i) the first or second voltage sensing structure and (ii) the first or second current sensing structure to receive (iii) the first or a second sensed voltage signal from the first or second voltage sensing structure and (iv) the first or a second sensed current signal from the first or second current sensing structure.

In another aspect, a system (e.g., (i) front-end module (FEM) to couple to an antenna module or (ii) an integrated antenna module, e.g., on-chip, on-package, on-board) is disclosed comprising: a set of amplifiers (e.g., power amplifiers) for an array antenna comprising a set of N array antenna elements, wherein each of the set of amplifiers is coupled to a array element of the set of N array antenna elements; and a set of built-in self-test circuits, including a first built-in self-test circuit, wherein each of the set of built-in self-test circuits is configured to measure a voltage standing wave ratio (VSWR) or the real or complex load impedance for a respective amplifier of the set of amplifiers (e.g., to reconfigure the respective amplifier to compensate for array element coupling or other couplings), wherein the first built-in self-test circuit comprises: a first voltage sensing structure and a second voltage sensing structure each co-located at, or proximate to, a single-ended terminal or multi-feed terminals defined by the array element; a first current sensing structure and a second current sensing structure each co-located at, or proximate to, the single-ended terminal or multi-feed terminals defined by the array element; a power sensing circuit operatively coupled to the first voltage sensing structure and the first current sensing structure to receive (i) a first sensed voltage signal from the first voltage sensing structure and (ii) a first sensed current signal from the first current sensing structure; and an impedance sensing circuit (e.g., implemented using amplitude detectors) coupled to (i) the first or second voltage sensing structure and (ii) the first or second current sensing structure to receive (iii) the first or a second sensed voltage signal from the first or second voltage sensing structure and (iv) the first or a second sensed current signal from the first or second current sensing structure.

In another aspect, an apparatus (e.g., a circuit in a FEM, an IC, or a component for an integrated antenna module) is disclosed comprising: a built-in self-test circuit for a array antenna, wherein the built-in self-test circuit is configured to measure a voltage standing wave ratio (VSWR) or real or complex load impedance for an amplifier connected to an antenna array element (e.g., to reconfigure the respective amplifier to compensate for array element coupling or other couplings), wherein the built-in self-test circuit comprises: a first voltage sensing structure and a second voltage sensing structure each co-located at, or proximate to, a single-ended terminal defined by the array element; a first current sensing structure and a second current sensing structure each co-located at, or proximate to, the single-ended terminal defined by the array element; a power sensing circuit operatively coupled to the first voltage sensing structure and the first current sensing structure to receive (i) a first sensed voltage signal from the first voltage sensing structure and (ii) a first sensed current signal from the first current sensing structure; and an impedance sensing circuit (e.g., implemented using amplitude detectors) coupled to (i) the first or second voltage sensing structure and (ii) the first or second current sensing structure to receive (iii) the first or a second sensed voltage signal from the first or second voltage sensing structure and (iv) the first or a second sensed current signal from the first or second current sensing structure.

In another aspect, an apparatus (e.g., a circuit in a FEM, an IC, or a component for an integrated antenna module) is disclosed comprising: an impedance sensing circuit and a power sensing circuit for an antenna array or antenna element, wherein the impedance sensing circuit and the power sensing circuit are configured to measure a voltage standing wave ratio (VSWR) or real or complex load impedance for at least one of (i) amplifier or (i) electronic circuit connected to the array antenna or the antenna element, wherein the impedance sensing circuit includes: a first voltage sensing structure and a first current sensing structure each co-located at, or proximate to, a single-ended terminal defined by the array element; wherein the power sensing circuit includes: a second voltage sensing structure and a second current sensing structure each co-located at, or proximate to, a single-ended terminal defined by the array element.

In another aspect, an apparatus is disclosed comprising one or more power sensing and impedance sensing structures located at a single-ended antenna array element of an antenna array (e.g., phased array); and an array-level built-in-self-test circuit configured to perform at least one of inter-element coupling evaluation, inter-element power flow, and/or impedance mismatch detection, wherein the array-level built-in-self-test circuit employs a VSWR power and impedance sensing circuit that includes the features of any one of claims 5-15.

In some embodiments, each antenna element, or a portion of the antenna elements, is coupled with a transmitter element.

In some embodiments, each antenna element, or a portion of the antenna elements, is coupled with a receiver element.

In some embodiments, each antenna element, or a portion of the antenna elements, is connected to one or multiple transmitters and receivers through a matching and/or switch network

In some embodiments, the one or more power sensing and impedance sensing structures include at least one of one or more voltage sensors, current sensors, power sensors, and impedance sensors.

In some embodiments, the array-level built-in-self-test circuit is configured to generate one or more test signals at one or more antenna array elements to be coupled to one or more adjacent or nearby antenna array elements to evaluate complex coupling, coefficient matrix, power flow, and impedance mismatches for multi-elements or all of the array (e.g., to achieve the whole array level calibration, built-in-self-testing (BiST), and performance optimization).

In another aspect, an apparatus is disclosed comprising two or more power sensing and impedance sensing structures located at an input or output of a subcircuit or components of an electric circuit; and a VSWR power and impedance sensing circuit coupled to the two or more power sensing and impedance sensing structures to detect power flow or impedance mismatch (i) within the subcircuit or components or (ii) between the subcircuit or components and other circuits. In some embodiments, the VSWR power and impedance sensing circuit include any of the below-discussed features.

In some embodiments, the power sensing circuit or the respective power sensing circuit comprises: a single-ended to differential signal converter (e.g., Balun); and an analog multiplier circuit operatively connected to the single-ended to differential converter.

In some embodiments, the power sensing circuit or the respective power sensing circuit either (i) further comprises a filter connected to the analog multiplier circuit or (ii) wherein the analog multiplier circuit comprises an integrated filter or has integrated filtering capability.

In some embodiments, the analog multiplier circuit comprises at least one of a single-balanced Gilbert multiplier (SBGM) circuit or a double-balanced Gilbert multiplier (DBGM) circuit, or a nonlinear circuit.

In some embodiments, the power sensing circuit or the respective power sensing circuit comprises a complementary analog multiplier configured to multiply the two sensed signals (e.g., while providing low-pass filtering).

In some embodiments, the complementary analog multiplier circuit comprises a complementary multiplier (PCM) comprising two parallel pairs of double-balanced Gilbert multiplier cells having inputs for a sensed current signal and a sensed voltage signal (e.g., wherein the signals are flipped).

In some embodiments, the two parallel pairs of double-balanced Gilbert multiplier cells comprise two or more symmetric signal paths between the multiplier and the respective sensors, wherein the symmetric signal paths provide symmetric input loading there between (e.g., avoid amplitude/phase mismatch to the sensor inputs and the multiplier cells).

In some embodiments, the power sensing circuit or the respective power sensing circuit further comprises an error cancellation circuit.

In some embodiments, the error cancellation circuit is configured to add a pre-defined phase offset (e.g., phase offset error), as a pre-defined load-dependent adjustment (e.g., load-dependent error), between the second voltage sensing structure and the second current sensing structure to cancel magnitude error in the first sensed voltage signal from the first voltage sensing structure and the first sensed current signal from the first current sensing structure.

In some embodiments, the error cancellation circuit is configured to receive calibration or updates from an active power detector.

In some embodiments, the impedance sensing circuit or the respective impedance sensing circuit comprises an amplitude detector (e.g., multi-stage Dickson rectifier) for the second sensed voltage signal and the second sensed current signal, or amplified signals thereof.

In some embodiments, the power sensing circuit or the respective power sensing circuit is configured to output a sensed power signal using the first sensed voltage signal and the first sensed current signal, wherein the impedance sensing circuit or the respective power sensing circuit is configured to output a sensed impedance signal using the second sensed voltage signal and the second sensed current signal, and wherein the sensed power signal and the sensed impedance signal are employed to reconfigure (i) the amplifier, (ii) an array element associated circuit, or (iii) a combination thereof, to compensate for array element coupling (or other couplings) during operation of the array antenna.

In another aspect, a method is disclosed of compensating for array element coupling error during operation of a array antenna (e.g., array RADAR system, a 5G and/or mmWave base station, or a 5G or mmWave handset), the method comprising: measuring a voltage standing wave ratio (VSWR) or real or complex load impedance for an amplifier of a array element based on a sensed power signal and a sensed impedance signal measured at a single-ended terminal defined by a array element, wherein the measurements of the sensed power signal and the sensed impedance signal are respectively determined (i) from one or more sensed current signals connected to one or more current sensing structures co-located at, or proximate to, a single-ended terminal defined by a array element and (ii) from one or more sensed voltage signals connected to one or more voltage sensing structures co-located at, or proximate to, the single-ended terminal defined by the array element; and reconfiguring (i) an amplifier, (ii) a matching network, (iii) an impedance tuner, (iv) a array element associated circuit, or (v) a combination thereof, using the sensed power signal and the sensed impedance signal.

In another aspect, a method comprising: measuring a voltage standing wave ratio (VSWR) or real or complex load impedance for an amplifier of a array element based on a sensed power signal and a sensed impedance signal measured at a single-ended terminal defined by a array element, wherein the measurements of the sensed power signal and the sensed impedance signal are respectively determined (i) from one or more sensed current signals connected to one or more current sensing structures co-located at, or proximate to, a single-ended terminal defined by a array element and (ii) from one or more sensed voltage signals connected to one or more voltage sensing structures co-located at, or proximate to, the single-ended terminal defined by the array element; and outputting the sensed power signal and the sensed impedance signal, wherein the outputted sensed power signal and the sensed impedance signal are employed to reconfigure (i) an amplifier, (ii) a matching network, (iii) an impedance tuner, (iv) a array element associated circuit, or (v) a combination thereof.

In some embodiments, the steps are performed using any one of the above-discussed systems or apparatuses.

### BRIEF DESCRIPTION OF THE DRAWINGS

The following detailed description of specific embodiments of the disclosure will be better understood when read in conjunction with the appended drawings. For the purpose of illustrating the disclosure, specific embodiments are shown in the drawings. It should be understood, however, that the disclosure is not limited to the precise arrangements and instrumentalities of the embodiments shown in the drawings.

FIGS. 1A, and 1C each shows an exemplary antenna module system configured for broadband-capable current/voltage sensing-based VSWR resilient true power/impedance detection in accordance with an illustrative embodiment.

FIG. 1B shows various embodiments of the broadband-capable current/voltage sensing-based VSWR resilient true power/impedance detection of FIGS. 1A, 1C, 1D, and 1E in accordance with an illustrative embodiment.

FIG. 1D shows an embodiment of the broadband-capable current/voltage sensing-based VSWR resilient true power/impedance detection implemented as an integrated circuit in accordance with an illustrative embodiment.

FIG. 1E shows an embodiment of the current/voltage sensing-based VSWR resilient true power/impedance detection implemented as an in-situ circuit in any analog or mixed-signal circuitries in accordance with an illustrative embodiment.

FIG. 1F shows an embodiment of the coupler sensing-based VSWR resilient true power/impedance detection implemented as an in-situ circuit in any analog or mixed-signal circuitries in accordance with an illustrative embodiment.

FIGS. 2A, 2B, and 2C each shows an exemplary power sensing operation for the built-in-self-test circuitries, and associated sensing mechanisms, using sensed current and voltage measurements in accordance with an illustrative embodiment.

FIGS. 2D, 2E, 2F, and 2G show experimental results or simulations associated with the exemplary power sensing operation for the built-in self-test circuitries and associated sensing mechanisms, using sensed current and voltage measurements in accordance with an illustrative embodiment.

FIG. 2H shows an exemplary impedance sensing operation for the built-in self-test circuitries using sensed current and voltage measurements in accordance with an illustrative embodiment.

FIGS. 3A, 3B, 3C, 3D, 3E, 3F, 3G, 3H, and 3I each shows example coupler-based impedance/power sensing detectors, and its associated simulations results, for the exemplary antenna module system of any one of FIGS. 1A-1E in accordance with various illustrative embodiments.

FIGS. 4A, 4B, 4C, and 4D each shows example power sensing and impedance sensing circuits for the exemplary antenna module system of any one of FIGS. 1A-1E in accordance with various illustrative embodiments.

FIGS. 5A, 5B, 5C, 5D, 5E, and 5F each shows example compact VSWR power sensing and impedance sensing circuits for the exemplary antenna module system of any one of FIGS. 1A-1E in accordance with various illustrative embodiments.

FIGS. 6A, 6B, 6C, 6D, 6E, 6F, 6G, 6H, 6I, 6J, and 6K show experimental results, simulation results, and characterizations of the example power sensing and impedance sensing circuits of FIGS. 4A-4D in accordance with various illustrative embodiments.

FIGS. 7A, 7B, 7C, 7D, 7E, 7F, 7G, 7H, 7I, 7J, and 7K show experimental results, simulation results, and characterizations of the compact VSWR power sensing and impedance sensing circuits of FIGS. 5A-4F in accordance with various illustrative embodiments.

FIGS. 8A, 8B, 8C, 8D, and 8E show experimental results, simulation results, and characterizations of the coupled-based VSWR power and impedance sensing circuits of FIGS. 3A-3I in accordance with various illustrative embodiments.

### DETAILED DESCRIPTION

To facilitate an understanding of the principles and features of the present disclosure, various illustrative embodiments are explained below. The components, steps, and materials described hereinafter as making up various elements of the embodiments disclosed herein are intended to be illustrative and not restrictive. Many suitable components, steps, and materials that would perform the same or similar functions as the components, steps, and materials described herein are intended to be embraced within the scope of the disclosure. Such other components, steps, and materials not described herein can include but are not limited to, similar components or steps that are developed after the development of the embodiments disclosed herein.

Some references, which may include various patents, patent applications, and publications, are cited in a reference list and discussed in the disclosure provided herein. The citation and/or discussion of such references is provided merely to clarify the description of the present disclosure and is not an admission that any such reference is “prior art” to any aspects of the present disclosure described herein. In terms of notation, “[n]” corresponds to the nth reference in the list. All references cited and discussed in this specification are incorporated herein by reference in their entireties and to the same extent as if each reference was individually incorporated by reference.

Example Systems

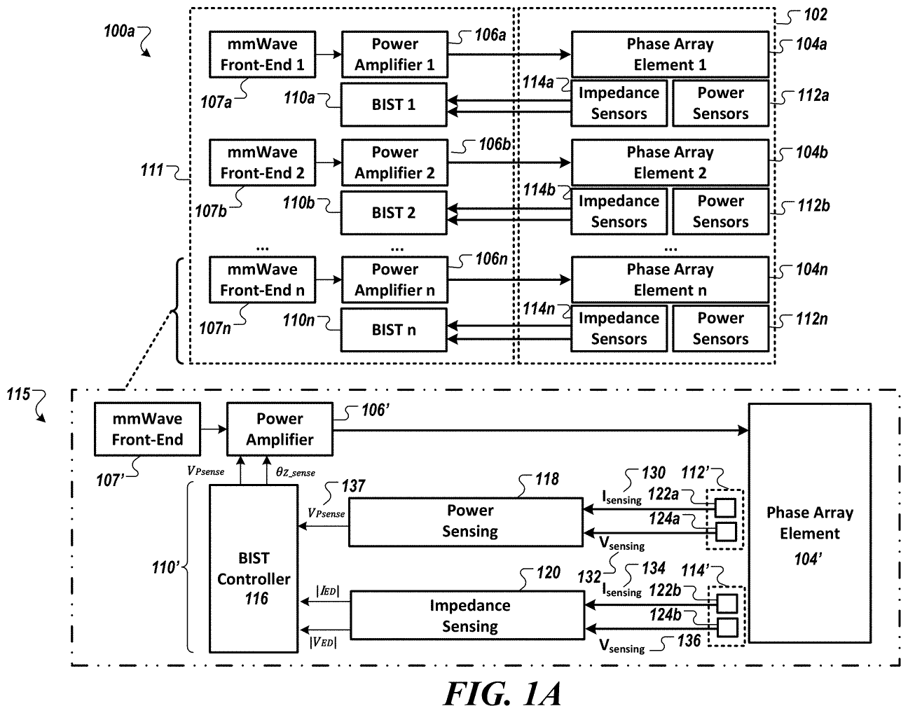

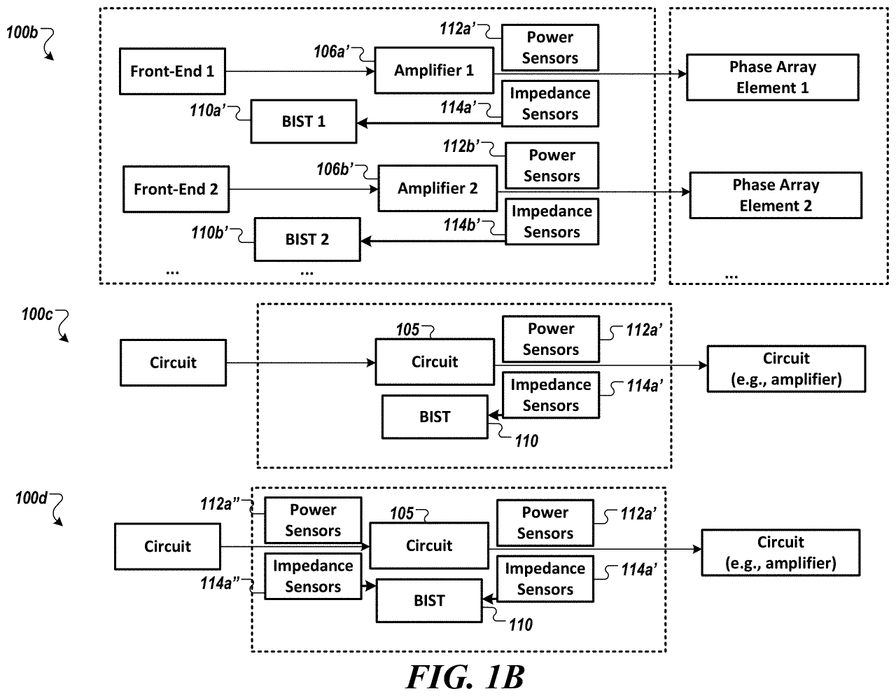

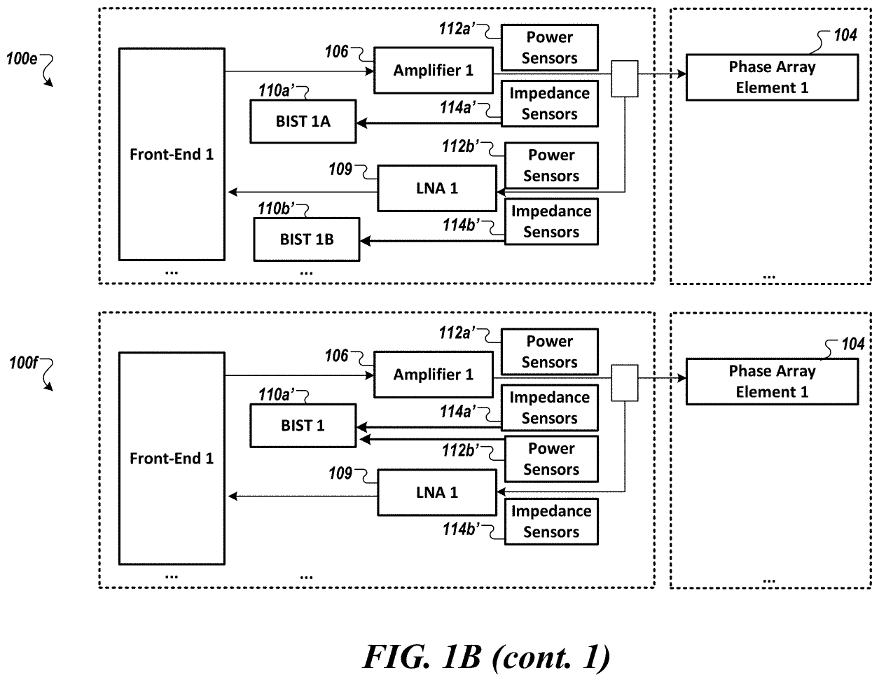

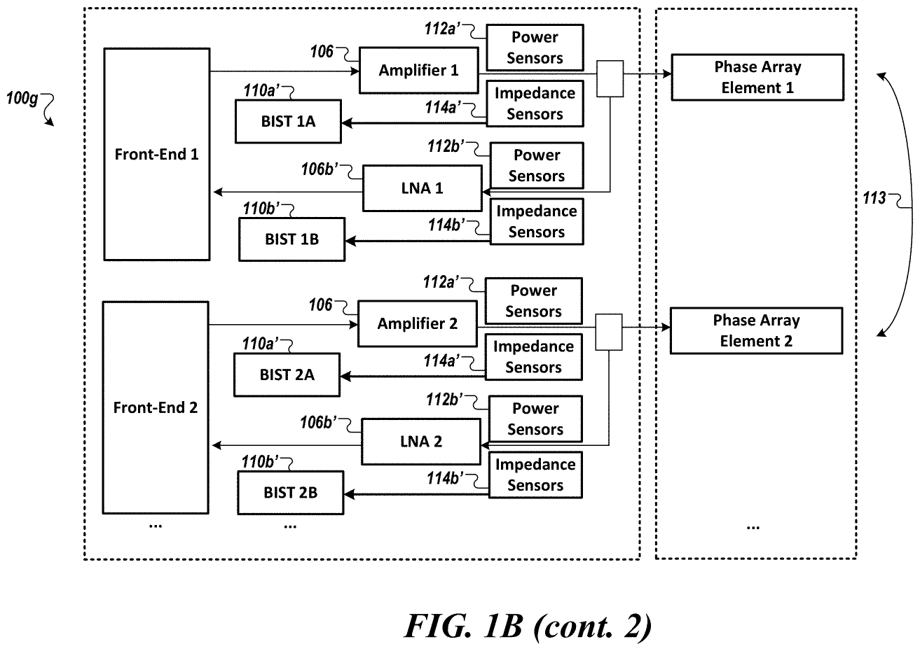

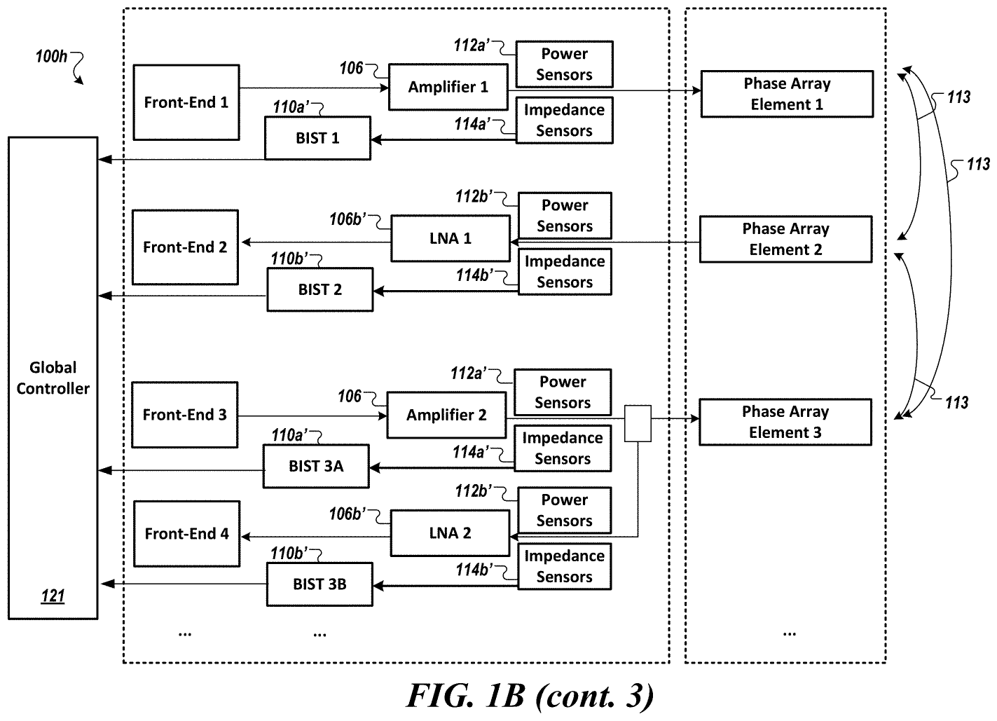

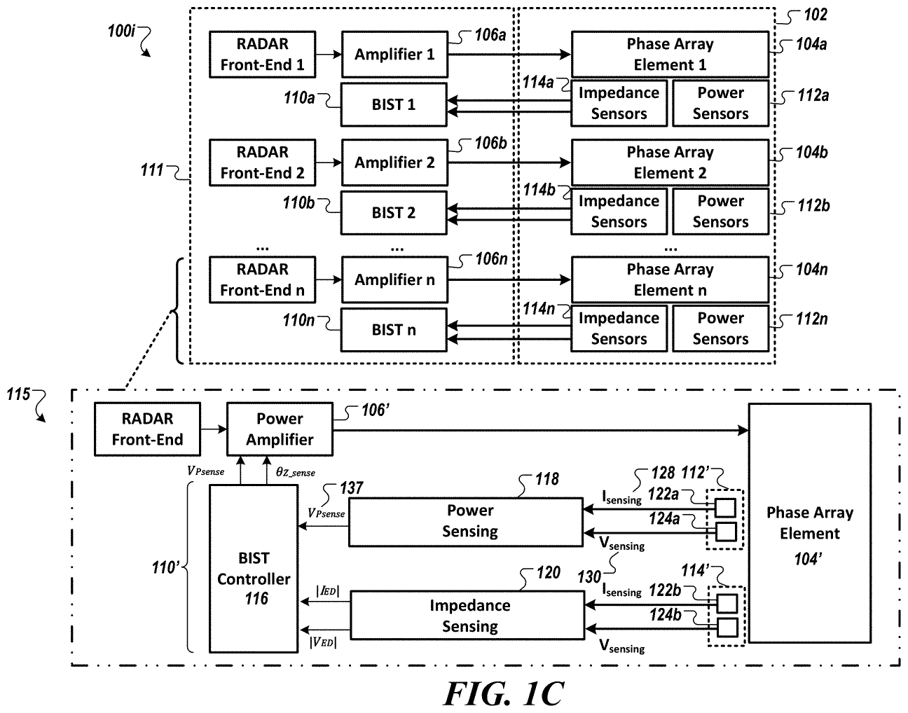

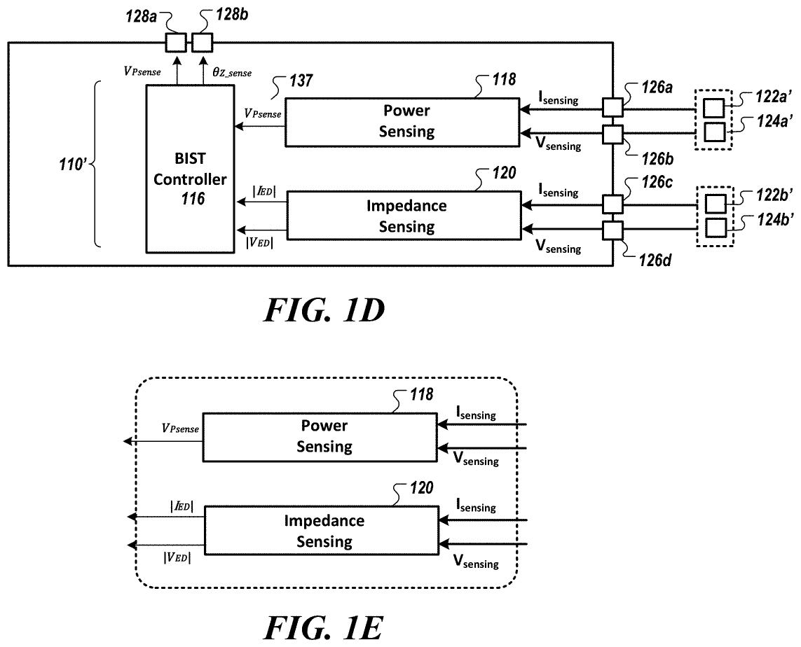

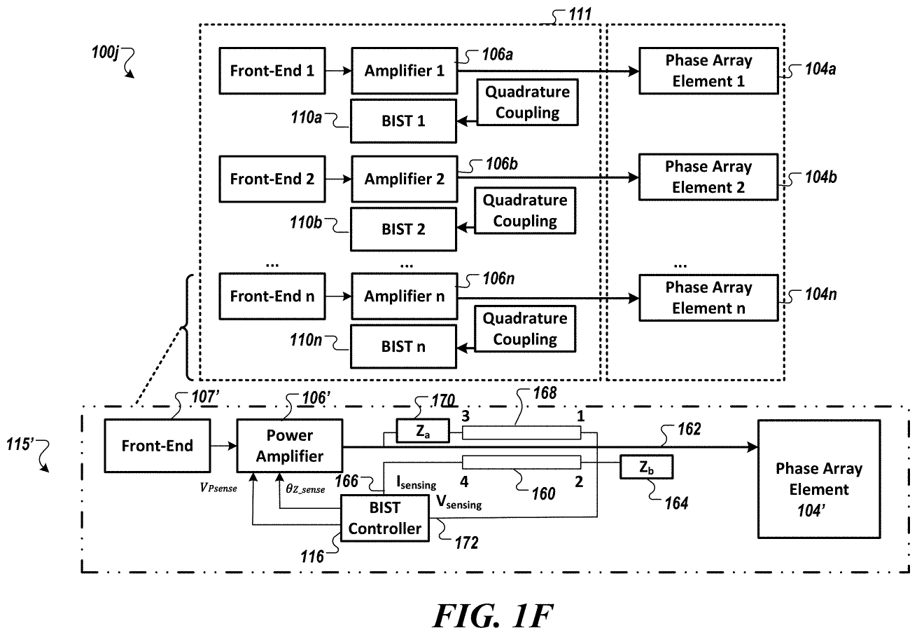

FIGS. 1A, and 1C each shows an exemplary antenna module system 100 (shown as 100a) configured for broadband-capable current/voltage sensing-based VSWR resilient true power/impedance detection in accordance with an illustrative embodiment.

5G and/or mmWave Application. In the example shown in FIG. 1A, the exemplary 5G or mmWave antenna module system 100a includes a 5G or mmWave phased array antenna module 102 (shown having element “1” 104a, element “2” 104b, . . . element “n” 104n) and associated circuitries, including power amplifier 106 (shown as 106a, 106b, . . . , 106n) and other 5G or mmWave front-end circuitries 107 (shown as mmWave Front-End “1” 107a, Front-End “2” 107b . . . , Front-End “n” 107n), each array element (104a, 104b, . . . , 104n) configured with independent built-in-self-test circuitries 110 (shown as 110a, 110b, . . . , 110n). In the example shown in FIG. 1C, the same or similar broadband-capable current/voltage sensing-based VSWR resilient true power/impedance detection configuration is shown for a RADAR antenna module system 100g.

The built-in-self-test circuitries (e.g., 110a, 110b, . . . , 110n) are located in a front-end module 111, and each, or a subset thereof, is configured to provide single-ended broadband VSWR resilient joint true power/impedance sensing for a given phased array element 104. The BIST circuitries (e.g., 110a, 110b, . . . , 110n) each may include a set of power-sensing sensors 112 (shown as “Power Sensors” 112a, 112b, . . . 112n) and a set of impedance-sensing sensors 114 (shown as “Impedance Sensors” 114a, 114b, . . . 114n). In FIG. 1A, the set of power-sensing sensors (e.g., 112a, 112b, . . . 112n) and the set of impedance-sensing sensors (e.g., 114a, 114b, . . . 114n) are positioned next to the phased array element (e.g., 104a, 104b, . . . 104n) in the phased array antenna module 102. The power/impedance sensing may be employed for other applications, e.g., by being (i) positioned at the output of the power amplifier or (ii) at the input and output of the power amplifier, among others (e.g., see FIG. 1B).

While the example in FIG. 1A shows a single voltage or single current sensing for each of the power or impedance sensing, two or more voltage and/or current sensing structures can be implemented for each power or impedance sensing, i.e., more than two respective sensing structures may be implemented per array element, at the array itself or front-end circuitries. In some embodiments, the current and voltage sensing may be implemented over more than one antenna feed or waveguide.

Channel 115 shows the front-end components, sensor or sensing structure, and BIST, for an example phased array element 104 (shown as 104′). The channel 115 includes a power amplifier 106 (shown as 106′), other front-end circuitry 107′ in addition to the power amplifier 106′ and built-in-self-test circuitries 110 (shown as 110′). In the example shown in FIG. 1A, the built-in self-test circuitries 110′ includes a BIST controller 116, a power sensing circuit 118, and an impedance sensing circuit 120.

The power sensing circuit 118 is coupled to a power-sensing sensor 112 (shown as 112′) comprising (i) a current sensor or current sensing structure 122 (shown as 122a) and (ii) a voltage sensor or voltage sensing structure 124 (shown as 124a) to provide sensed current I_{sensing} 130 and sensed voltage V_{sensing} 132 to be used to determine the true power of the phased array element (e.g., 104a, 104b, . . . 104n), or a variation thereof, at the singled-ended termination point of the element 104. In the example shown in FIG. 1A, the power sensing circuit 118 employs the sensed current I_{sensing} 130 and sensed voltage V_{sensing} 132 to generate a sensed power V_{Psense} signal 137.

The impedance-sensing circuit 120 is coupled to an impedance-sensing sensor 114 (shown as 114′) comprising (i) a current sensor or current sensing structure 122 (shown as 122b) and (ii) a voltage sensor or voltage sensing structure 124 (shown as 124b) to provide sensed current 134 and sensed voltage 136 to be used to determine the true impedance of, or a variation thereof at, at the singled-ended termination point of the element 104′. In the example shown in FIG. 1A, the impedance sensing circuit 120 employs the sensed current I_{sensing} 130 and sensed voltage V_{sensing} 132 to generate a sensed impedance signal (e.g., that can be determined from the magnitude of the sensed current and voltage in combination with the sensed power V_{Psense} signal.

Other Applications.

As noted above, the power/impedance sensing may be employed for other applications, e.g., by being (i) positioned at the output of the amplifier or (ii) at the input and output of the amplifier, among others. For example, the power gain of the amplifier or various circuits, may be sensed by sensing power and/or impedance at the input and output of the amplifier or circuit. The compressive behavior of the amplifier may be estimated, e.g., to evaluate magnitude or phase linearity or the performance metric of interest.

FIG. 1B shows other antenna or circuit systems 100 (shown as 100b, 100c, 100d, 100e, 100f, 100g) configured for current/voltage sensing-based true power/impedance detection in accordance with another illustrative embodiment.

Amplifier Power and/or Impedance Evaluation.

In system 100b, the BIST circuitries (e.g., 110a′, 110b′, . . . ) each may include a set of power-sensing sensors (112a′, 112b′, . . . ) and a set of impedance-sensing sensors (114a′, 114b′, . . . ) positioned at the output of the amplifier (106a′, 106b′) to provide an evaluation of the amplifier.

Inter-Circuit Power and/or Impedance Evaluation.

In systems 100c and 100d (FIG. 1B), the BIST circuitries (e.g., 110) each may include a set of one or more power-sensing sensors (shown as 112a′) and/or a set of one or more impedance-sensing sensors (e.g., 114a′) positioned respectively at the output of a circuit 105 (e.g., amplifier, passive networks) that is connected to another circuitry (e.g., amplifier, waveguide, etc., or other active components). System 100d further includes a second set of one or more power-sensing sensors (shown as 112a′″) and/or a set of one or more impedance-sensing sensors (e.g., 114a″) located at the input of the amplifier (e.g., 106). Because of its compact design, the BIST circuitries (e.g., 110) may be employed for the characterization of inter-circuit components.

Channel-Level Power and/or Impedance Evaluation.

In systems 100e and 100f (FIG. 1B (cont. 1)), the BIST circuitries (e.g., 110) each may include a set of one or more power-sensing sensors (shown as 112a′) and/or a set of one or more impedance-sensing sensor (e.g., 114a′) positioned respectively at the output of the amplifier (e.g., 106) coupled to the phased array element (e.g., 104) as well as a lower-noise amplifier (LNA) 109 (shown as “LNA 1” 109). The power and/or impedance measurement of the LNA can be used in combination to adjust or quantify the performance of the channel 115 more comprehensively.

Array-Level Power and/or Impedance Evaluation.

In systems 100e, 100f (FIG. 1B (cont. 1) and 100g (FIG. 1B (cont. 2), the BIST circuitries (e.g., 110) each may include a set of one or more power-sensing sensors (shown as 112a′) and/or a set of one or more impedance-sensing sensors (e.g., 114a′) positioned respectively at the output of the amplifier (e.g., 106) coupled to the phased array element (e.g., 104) as well as the input (or output) of the lower-noise amplifier (LNA) 109 (shown as “LNA 1” 109). The power and/or impedance measurement of the LNA can be used in combination to adjust or quantify the performance of the channel 115 more comprehensively.

In systems 100h (FIG. 1B (cont. 3), the BIST circuitries (e.g., 110) each may include a set of one or more power-sensing sensors (shown as 112a′) and/or a set of one or more impedance-sensing sensor (e.g., 114a′) positioned respectively at either (i) an output of the amplifier (e.g., 106) coupled to the phased array element (e.g., 104) the input (or output) of the lower-noise amplifier (LNA) 109 (shown as “LNA 1” 109). The power and/or impedance measurement of the LNA can be used in combination to adjust or quantify the performance of the channel 115 more comprehensively. To this end, system 100h illustrates an antenna array having a portion of array elements only connected to transmitters and a portion of the array elements, e.g., the remainder, only connected to receivers to which the transmitters and receivers are instrumented by the in-situ power-sensing sensors and/or one or more impedance-sensing sensors.

Array-level BIST or channel-level BIST can additionally or alternatively be used to perform or assess inter-element coupling (113), power flow, and impedance mismatch detection, among others, for a portion or all the elements in an array. A practical antenna array always has inter-element coupling. For a typical antenna array, it can be assumed: (1) each antenna element is coupled with a transmitter element, i.e., the antenna is driven by the output(s) of one or more amplifiers through a matching and/or switch network, (2) each antenna element is coupled with a receiver element, i.e., the antenna is feeding the input(s) of one or more amplifiers through a matching and/or switch network, (3) each antenna element is connected to one or multiple transmitters and receivers through a matching and/or switch network. In some embodiments, the interfaces between the corresponding antenna element and its coupled transmitter/receiver circuits may be instrumented/implemented with one or more voltage sensors, current sensors, power sensors, and impedance sensors, as described herein.

In other antenna arrays, the antenna array can have a portion of array elements only connected to transmitters and a portion of the array elements, e.g., the remainder, only connected to receivers to which the transmitters and receivers are instrumented by the in-situ power-sensing sensors and/or one or more impedance-sensing sensors, e.g., as shown and described in relation to system 100h in FIG. 1B (cont. 3).

In some embodiments, one or more array elements can generate one or more testing signals, e.g., by using their transmitters, while the testing signals are coupled to other adjacent or non-adjacent antenna elements. Next, the BIST controller (e.g., 116), or a global controller (shown as 121) for the array, can read out the outputs of the one or more voltage sensors, current sensors, power sensors, and impedance sensors of the array elements that generate those test signals. Then, the BIST controller, or a global controller can read out the outputs of the one or more voltage sensors, current sensors, power sensors, and impedance sensors of the array elements that are coupled with the transmitter array elements. Finally, by processing and aggregating the aforementioned sensing data, the whole complex coupling coefficient matrix, power flow, and impedance mismatches for all the elements of the entire array can be determined to achieve the whole array level calibration, built-in self-testing, and performance optimization.

The global controller (e.g., 121) can process and aggregate sensing data from any number of BISTs (e.g., 110), including, e.g., those in systems 100a-100i shown in FIGS. 1A-1E, to determine the whole complex coupling coefficient matrix, power flow, and impedance mismatches for any set of subsets of the elements of the array or for any number of components in a circuit topology. The global controller (e.g., 121) may be used to perform whole array level calibration, built-in-self-testing, and performance optimization, among other functions described or referenced herein.

Radar Application.

As noted above, FIG. 1C shows the same or similar broadband-capable current/voltage sensing-based VSWR resilient true power/impedance detection configuration being employed in a RADAR antenna module system 100i.

Integrated Circuits.

The broadband-capable current/voltage sensing-based true power/impedance detection may be employed in other form factors. For example, in FIG. 1D, the built-in-self-test circuitries 110 (shown as 110′) is implemented in a packaged integrated-circuit (IC) having ports 126 (shown as 126a, 126, 126c, 126d) to interface to current or voltage sensors or sensing structure (shown as 122a′, 122b′, 124a′, 124b′) located at a load circuit of interest. In the example shown in FIG. 1D, the built-in-self-test circuitries 110′ includes outputs that are coupled to the ports 128 (shown as 128a, 128b) that provide an output measure of the sensed power and sensed impedance. Other topologies may be employed, e.g., differential current/voltage sensor pair for impedance sensing and a voltage sensor for power sensing, e.g., as described herein.

The current/voltage sensing-based VSWR power/impedance detector may be employed in combination with a coupling-based power/impedance detector, e.g., for redundancy and/or monitoring at different frequency ranges. An example coupling-based power/impedance detector is disclosed in [32] and [61′], which is hereby incorporated by reference in its entirety. The system may include a first sensing electromagnetic (EM) structure as a first sensing transmission line that is co-located to the output transmission line to be capacitively coupled therewith, the first sensing electromagnetic structure having (i) a first end that connects to a corresponding end of the output transmission line through a pre-defined impedance and (ii) a second end that connects to a first input of the built-in self-test circuit sensing circuit; and a second sensing electromagnetic structure as a second sensing transmission line that is co-located to the output transmission line to be capacitively coupled therewith, the second sensing electromagnetic structure having (i) a first end that connects to an impedance element having a value corresponding the phased array antenna element and (ii) a second end that connects to a second input of the built-in self-test circuit sensing circuit.

In some embodiments, the first sensing electromagnetic structure and the second sensing electromagnetic structure each have a length of λ/4.

Example Coupler-Based VSWR Power/Impedance Sensing

FIG. 1F shows an exemplary antenna module system 100j configured for broadband-capable coupler-sensing-based VSWR resilient true power/impedance detection in accordance with an illustrative embodiment. The coupler-sensing-based VSWR power/impedance detector of FIG. 1F may be implemented as an in-situ circuit in any analog or mixed-signal circuitries, e.g., similarly as shown in relation to FIGS. 1A and 1C for communication or RADAR applications. The coupler-sensing-based VSWR power/impedance detector of FIG. 1F may be implemented to instrument circuits or amplifiers as described in relation to FIG. 1E. The coupler-sensing-based VSWR power/impedance detector of FIG. 1F may be implemented in arrays for inter-array assessment, e.g., as described in relation to FIG. 1B.

The coupler-sensing-based VSWR power/impedance detector of FIG. 1F may be implemented may be employed independently of other power/impedance detectors or may be employed in combination, e.g., for redundancy and the like.

In the example shown in FIG. 1F, the exemplary 5G, mmWave, RADAR antenna module system 100j includes a phased array antenna module 102 (shown having element “1” 104a, element “2” 104b, . . . element “n” 104n) and associated circuitries, including amplifier 106 (shown as 106a, 106b, . . . , 106n) and other front-end circuitries 107 (shown as Front-End “1” 107a, Front-End “2” 107b . . . , Front-End “n” 107n), each array element (104a, 104b, . . . , 104n) configured with independent built-in-self-test circuitries 110 (shown as 110a, 110b, . . . , 110n).

The built-in-self-test circuitries (e.g., 110a, 110b, . . . 110n) is located in a front-end module 111, and each, or a subset thereof, is configured to provide single-ended broadband VSWR resilient joint true power/impedance sensing for a given phased array element 104. The BIST circuitries (e.g., 110a, 110b, . . . 110n) each may include a first sensing electromagnetic (EM) structure 160 as a first sensing transmission line that is co-located to the output transmission line 162 to be capacitively coupled therewith. The first sensing electromagnetic structure 160 has (i) a first end that connects to a corresponding end of the output transmission line 162 through a pre-defined impedance 164 (shown as “Zₐ” 164) and (ii) a second end that connects to a first input 166 of the built-in self-test circuit 110. In an example, the pre-defined impedance 164 may have an impedance characteristic similar to that of the antenna element 104′.

The BIST circuitries (e.g., 110a, 110b, . . . 110n) also include a second sensing electromagnetic structure 168 as a second sensing transmission line that is co-located to the output transmission line 162 to be capacitively coupled therewith. The second sensing electromagnetic structure 168 has (i) a first end that connects to an impedance element 170 (shown as “Zₐ” 170) and (ii) a second end that connects to a second input 172 of the built-in self-test circuit sensing circuit. Implement elements (e.g., 164, 170) may be implemented with active or passive components, such as switches, resisters, and other components.

The power/impedance sensing may be employed for other applications, e.g., by being (i) positioned at the output of the power amplifier or (ii) at the input and output of the power amplifier, among others (e.g., see FIG. 1B).

Channel 115′ shows the front-end components, sensor or sensing structure, and BIST for an example phased array element 104 (shown as 104′). The channel 115′ includes an amplifier 106 (shown as 106′), other front-end circuitry 107′ in addition to the amplifier 106′ and built-in-self-test circuitries 110 (shown as 110′). In the example shown in FIG. 1F, the built-in self-test circuitries 110′ includes a BIST controller 116 and the quadrature coupling structure.

The first sensing electromagnetic structure 160 is configured to provide sensed current Iₛₑₙₛₑ to be used to determine the true power of the phased array element (e.g., 104a, 104b, . . . 104n), or a variation thereof, at the singled-ended termination point of the element 104. The second sensing electromagnetic structure 168 is configured to provide sensed voltage Vₛₑₙₛₑ to be used together with the determined sensed voltage.

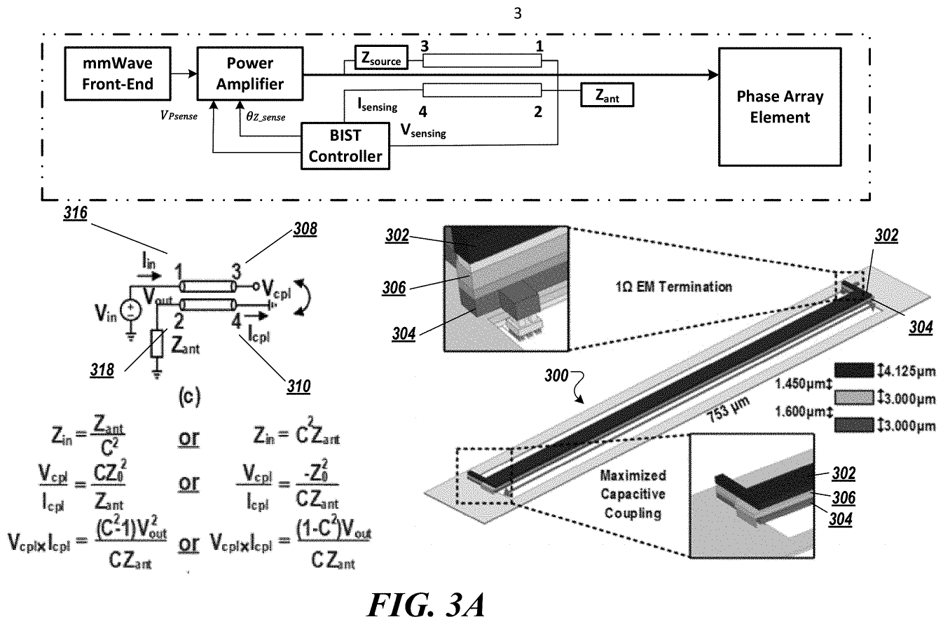

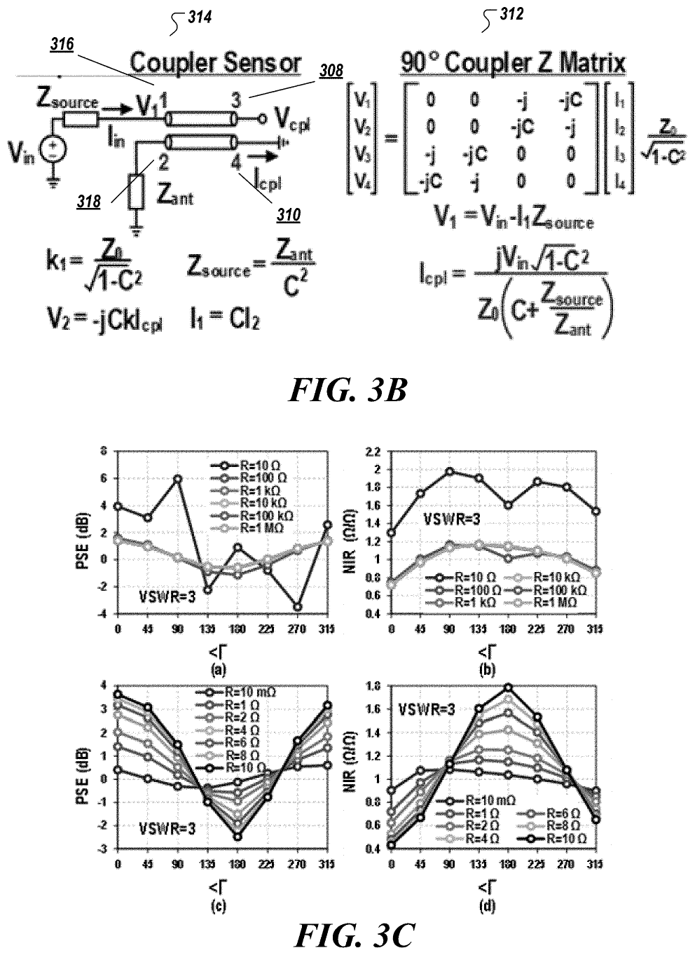

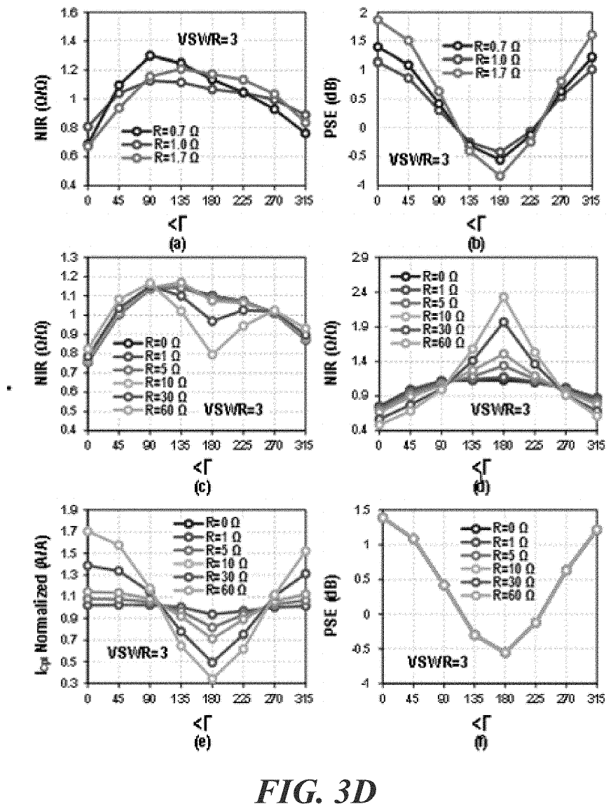

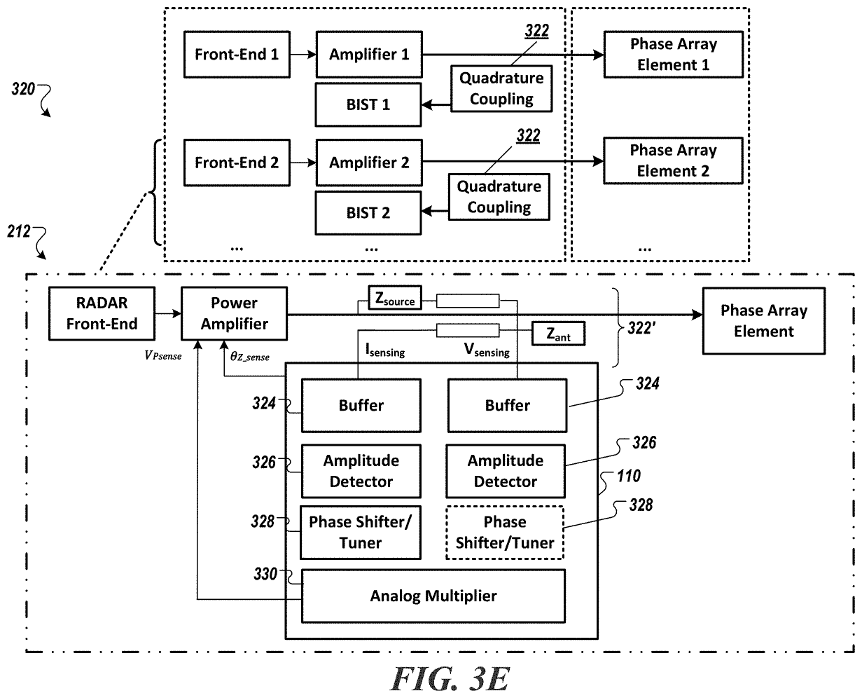

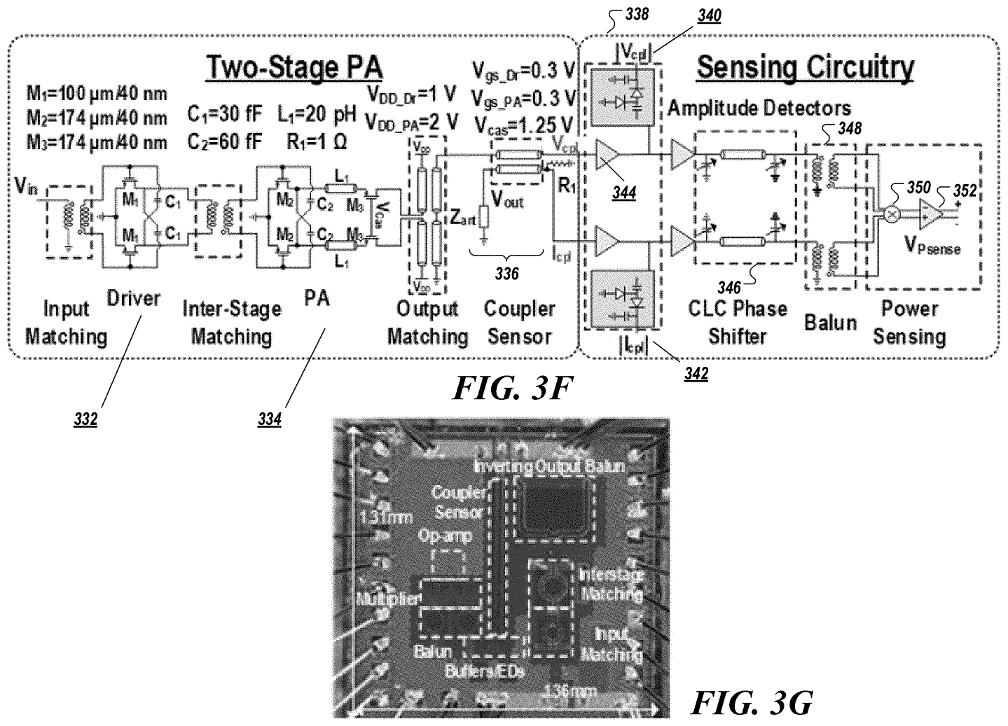

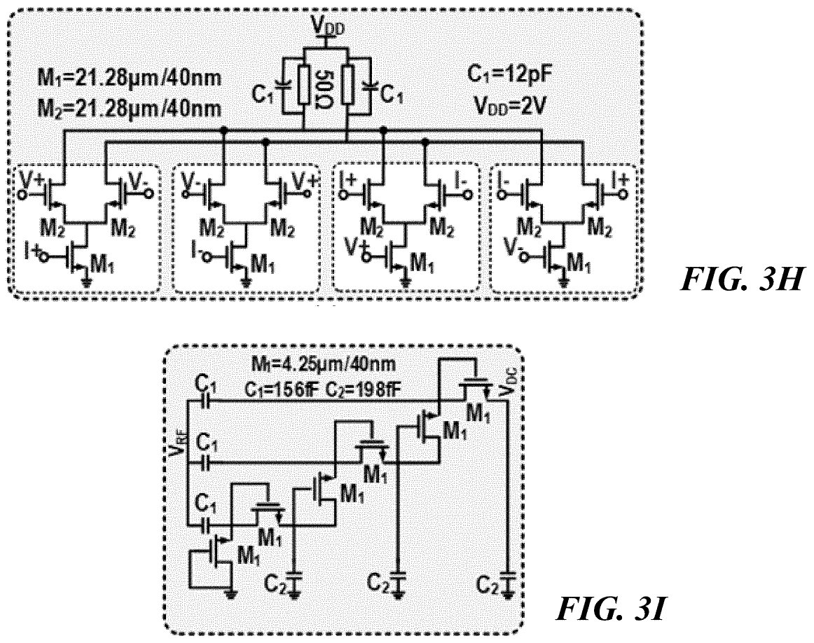

Example discussion of the operation of the coupled-based power/impedance sensing is provided in relation to FIGS. 3A-3I.

Example Current/Voltage-Based Power Sensing Operation

Power Sensing.

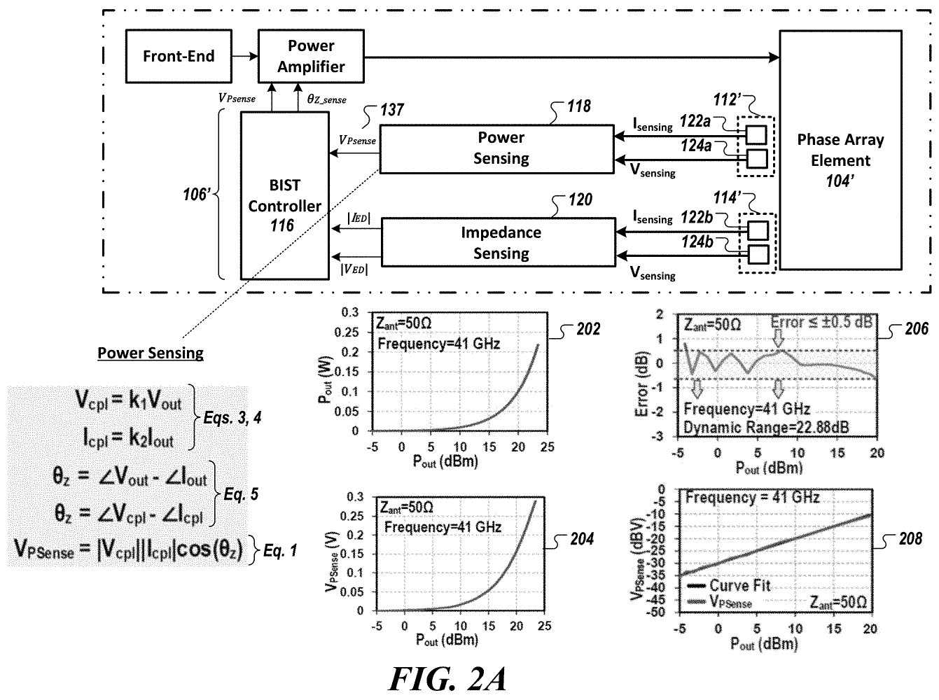

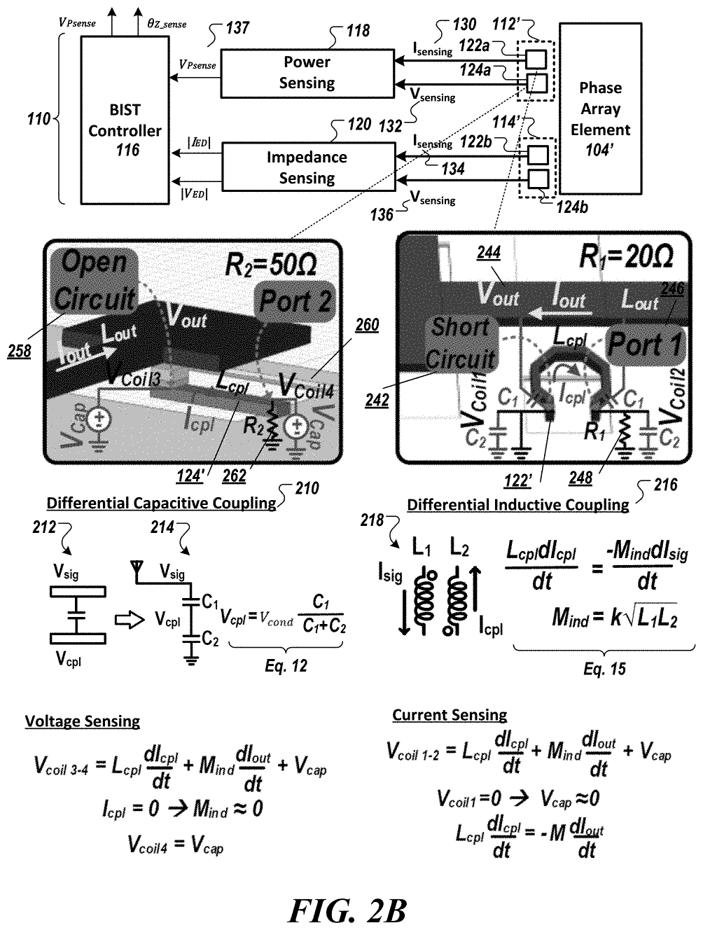

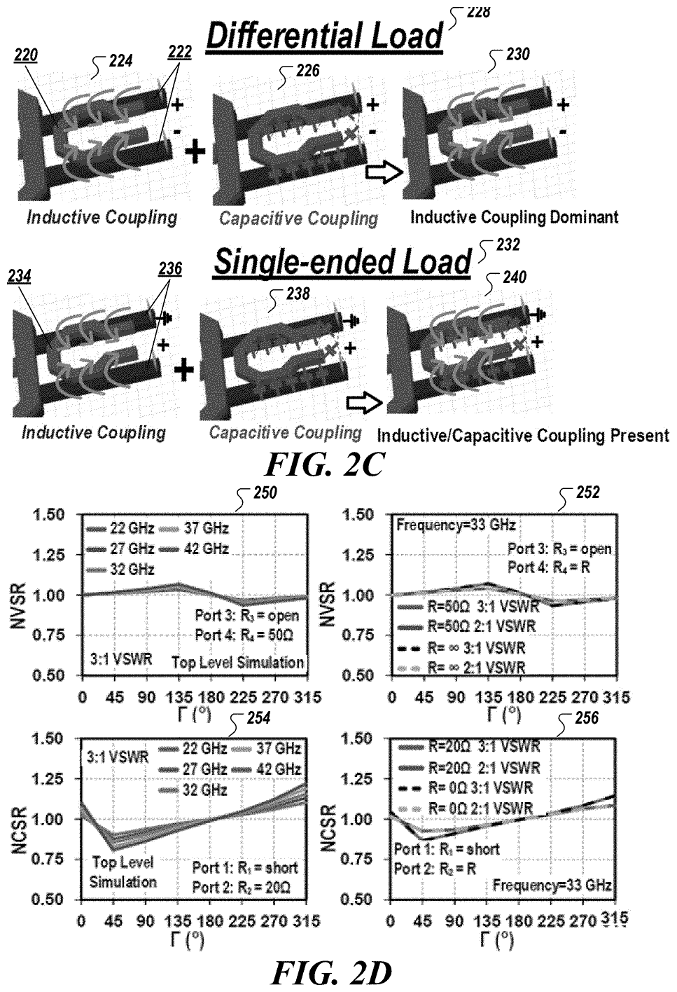

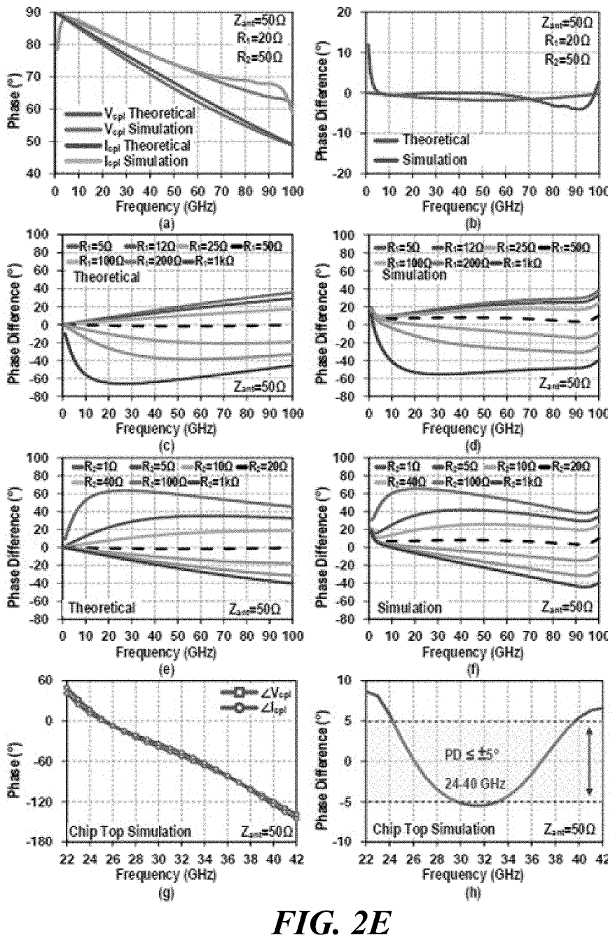

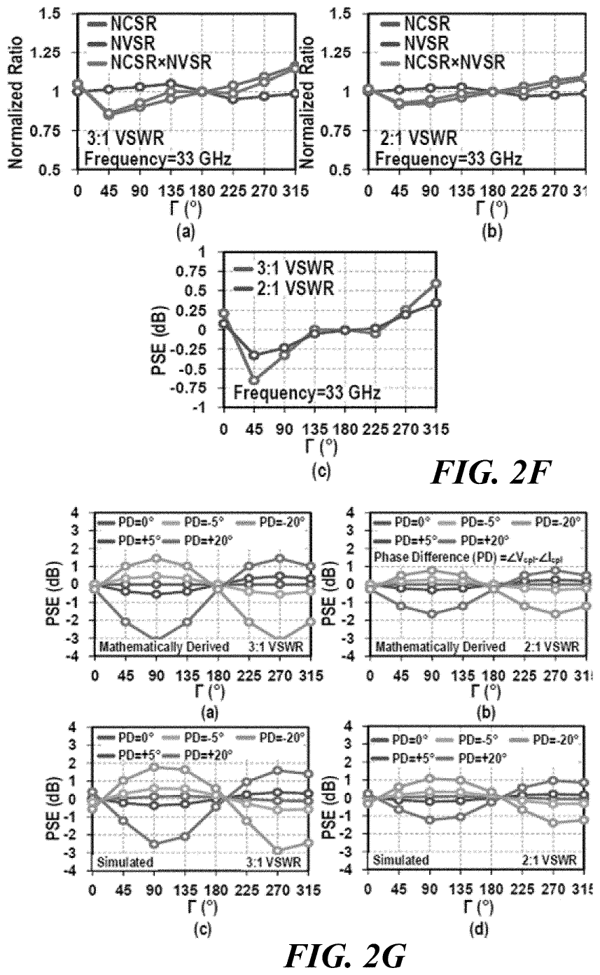

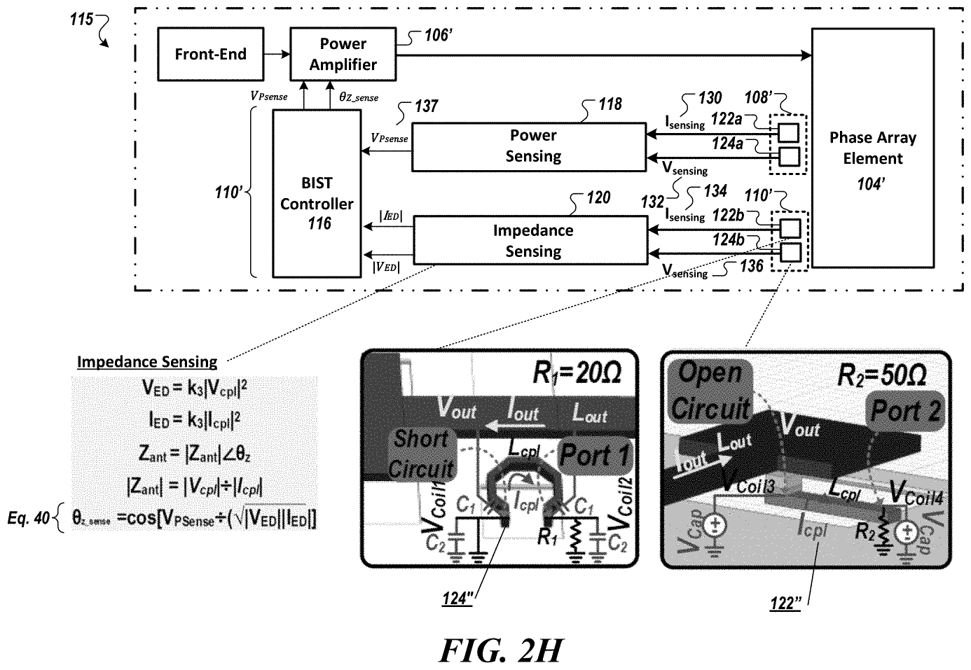

As noted above, in some embodiments, the true sensed power measurement for a given phased array element can be determined using the sensed current and voltage measurements, which can be multiplied via an analog multiplier. FIG. 2A shows an exemplary power sensing operation for the built-in self-test circuitries (e.g., 106) using sensed current and voltage measurements in accordance with an illustrative embodiment.

In the example shown in FIG. 2A, the sensed power V_{Psense} can be determined, e.g., per the power sensing circuit 118, by multiplying the sensed output current and sensed voltage waveforms through hardware and performing low-pass filtering the result to provide an output signal that is proportional in amplitude to the real power delivered to the antenna load per Equation 1:

V_{Psense}=0.5k₁k₂×|Vₒᵤₜ∥Iₒᵤₜ|cos(θ_{Z}) (Eq. 1)

In Equation 1, Vₒᵤₜ is the antenna output voltage peak amplitude, Iₒᵤₜ is the antenna output current peak amplitude, θ_{Z} is the phase of the antenna impedance in which all are measured at the desired carrier frequency, and k₁ and k₂ are proportionality factors. The antenna output current peak amplitude Iₒᵤₜ and the antenna output voltage peak amplitude Vₒᵤₜ can be determined from a sensed current I_{cpl} and a sensed voltage V_{cpl} via in inductive sensor or structure and a capacitive sensor or structure through inductive coupling and capacitive coupling, respectively, rather than a direct tap. Indeed, the sensor or structure can provide sensing via electrical coupling, magnetic coupling, and/or electromagnetic coupling.

This power sensing scheme aims to provide an output that is proportional to the true power delivered to the antenna load. This proportionality can be observed in Diagrams 202 and 204, which show the measured output power in Watts and the sensor voltage in Volts for 50Ω at 41 GHz. The true average power delivered to a complex antenna load [24] can be determined per Equation 2:

Pₒᵤₜ=0.5×|Vₒᵤₜ∥Iₒᵤₜ|cos(θ_{Z}) (Eq. 2)

where Pₒₙₜ is the average power delivered to the antenna load. This result is equivalent to the low-frequency content when multiplying the output voltage and current [24]. The power sensing scheme can sense output voltage V_{cpl} and current I_{cpl} via coupling means instead of direct signal tapping and then multiply the sensed signals per Equation 3:

V_{cpl}=k₁Vₒᵤₜ (Eq. 3)

I_{cpl}=k₂Iₒᵤₜ (Eq. 4)

where k₁ and k₂ are the proportionality factors. The sensing loops are designed such that the phase difference θ_{Z} of the sensed voltage ∠V_{cpl} and current ∠I_{cpl} is the same phase difference as that of the output voltage ∠Vₒᵤₜ and current ∠Iₒᵤₜ as shown in Equation 5.

θ_{Z}=∠Vₒᵤₜ−∠Iₒᵤₜ=∠V_{cpl}−∠I_{cpl}, (Eq. 5)

Using Equations 2, 3, and 4, the sensed power can be expressed as Equation 6.

V_{Psense}=0.5×|V_{cpl}∥I_{cpl}∥I_{cpl}|cos(∠V_{cpl}−∠I_{cpl}), (Eq. 6)

In Equation 6, the sensed power V_{Psense} is the DC output signal generated by the sensor structure under device under test (DUT) conditions. Using Equations (2)-(6), the sensed power V_{Psense} can be defined per Equation 7:

V_{Psense}=0.5k₁k₂×|Vₒᵤₜ∥Iₒᵤₜ|cos(θ_{Z}) (Eq. 7)

Diagrams 202 and 204 show the DC output signal of the sensor DUT being proportional to the true output power Pₒᵤₜ of the antenna load. As shown in diagrams 202 and 204, the measured sensor signal has the same dependence on the true output power in dBm as the true output power in Watts. To have a one-to-one correspondence between the sensor output and the true power, a proportionality factor PF can be defined as the average of the instantaneous ratio of the sensor output V_{Psense} and Pₒᵤₜ, e.g., as shown in Equation 8:

$$P F = avg ( \frac{{V}_{Psense}}{{P}_{out}} ) , \qquad ( Eq . 8 )$$

Due to noise and large signal compression of the multiplier and integrated op-amp, there could potentially be a limited power region, dynamic range, in which this proportionality factor is held constant to which output power monitoring can be accurately performed. To determine the power sensing dynamic range, the integral non-linearity (INL) may be evaluated of the actual PF versus its averaged value under the 50Ω load, e.g., per Equation 9.

$$I N L = 10 {log}_{10} ( \frac{( \frac{{V}_{Psense 50 Ω}}{{P}_{out 50 Ω}} )}{avg ( \frac{{V}_{Psense 50 Ω}}{{P}_{out 50 Ω}} )} ) \qquad ( Eq . 9 )$$

This dynamic range allows for the evaluation of the region of operation where the sensed power V_{Psense} is a proper linear fit compared to the predicted output power under any antenna load. The dynamic range may be defined as the region in which the INL is within ±0.5 dB error. Diagrams 206 and 208 show, respectively, the power sensing error plot (206) and linear fit plot (208) of the dynamic range as a function of output power. The plots are shown in relation to 50Ω.

Capacitive Coupling for Voltage Sensing.

To sense the output voltage, the BIST circuit (e.g., 110) would need to have pure capacitive coupling or have capacitive coupling be dominant. However, when two conductors are placed close by, both capacitive and inductive couplings are present.

For voltage sensing, the BIST circuit may employ capacitive/voltage coupling based on an E-field-based coupling mechanism that operates as a capacitive divider due to the parasitic overlap between the two conductors and the parasitic overlap to the ground. In FIG. 2B, diagram 210 shows the coupling mechanism 212 modeled as a capacitive divider 214 in which the sensed voltage V_{cpl} can be defined per Equation 12:

$${V}_{cpl} = \frac{{V}_{cond} \times {C}_{1}}{{C}_{1} + {C}_{2}} \qquad ( 12 )$$

where V_{cond} is the conductor voltage to sense, C₁ is the capacitive overlap between the conductor and a sense coil, and C₂ is the capacitive overlap between the sense coil and ground. The voltage sensing ratio can then be defined per Equation 13.

$$Voltage Sensing Ratio = \frac{{V}_{cpl}}{{V}_{cond}} = \frac{{C}_{1}}{{C}_{1} + {C}_{2}} \qquad ( Eq . 13 )$$

It can be observed that the sensing ratio is frequency independent and a constant, assuming high Q capacitors with minimal routing inductance, thus broadband capable.

Inductive Coupling for Current Sensing.

To sense the output current, e.g., along a trace path as in the example shown in FIG. 1B, the BIST circuit (e.g., 110) would need to have pure inductive/magnetic coupling between two conductors or have the inductive coupling be dominant. For voltage sensing, the BIST circuit may employ inductive coupling based on an H-field-based coupling mechanism that operates as two inductors magnetically coupled to one another. In FIG. 2B, diagram 216 shows the coupling mechanism 218 in which the voltage contribution due to inductive coupling can be defined per Equation 14.

$${V}_{coil} = {L}_{cpl} \frac{{dI}_{cpl}}{dt} + {M}_{ind} \frac{{dI}_{out}}{dt} , \qquad ( Eq . 14 )$$

where V_{coil} is the voltage of the sense coil, L_{cpl} and I_{cpl} are the inductance and current flowing within the sense coil, respectively, M_{md} is the mutual inductance between the sense coil and main conductor, and Iₒᵤₜ is the current flowing through the main conductor. By ensuring a short coil termination, the following relationship can be approximated:

$${V}_{coil} \sim 0 \to {L}_{cpl} \frac{{dI}_{cpl}}{dt} = {- M}_{ind} \frac{{dI}_{out}}{dt} , \qquad ( Eq . 15 )$$

Assuming that the inductance and mutual inductance are time-invariant, Equation 15 can be simplified as Equation 16, in which the current through the sense coil I_{cpl} is proportional to the current through the conductor Iₒᵤₜ. The mutual inductance M_{ind} can be defined per Equation 17.

$${I}_{cpl} = - \frac{{M}_{ind} \times {I}_{out}}{{L}_{cpl}} , \qquad ( Eq . 16 )$$

$$\\ \begin{matrix}{M}_{ind} = k \sqrt{{L}_{cpl} {L}_{cond}} , & ( Eq . 17 )\end{matrix}$$

In Equation 17, k is the inductive coupling coefficient, and L_{cond} is the inductance of the conductor. From Equations 16 and 17, the current sensing ratio (Current Sensing Ratio) can be defined per Equation 18.

$$Current Sensing Ratio = \frac{{I}_{cpl}}{{I}_{out}} = - k \sqrt{\frac{{L}_{cond}}{{L}_{cpl}}} , \qquad ( Eq . 18 )$$

From Equation 18, it can be observed that current sensing is insensitive to the frequency of operation and thus broadband capable. In practice, the sensing ratio and hence sensing strength can vary over frequency due to frequency-dependent factors, such as the magnetic coupling k.

Capacitive and Inductive Coupling for Current/Voltage Sensing for Single-Ended Loads.

For single-ended load sensing, e.g., as described in relation to FIGS. 1A and 1C, among others described herein, appropriate termination conditions to enhance the desired coupling mechanism while suppressing the undesired may be performed.

By way of background, when placing a sensing coil 220 (see FIG. 2C) symmetrically in proximity to a differential trace 222, the sense coil 220 experiences both capacitive (224) and inductive (226) coupling. However, for differential outputs 228, the sense coil 220 capacitively couples with both differential output traces 222, partially canceling each other and minimizing the overall capacitive coupling contribution, thus making inductive coupling as the dominant coupling mechanism 230. To this end, current sensing via inductive coupling can be readily extracted for sufficient proportionality factor k. For voltage sensing, a shunt capacitor to the differential output trace, as an example implementation of the sensing, can be used to sense the differential output voltage.

In contrast, for single-ended loads 232, when placing a sensing coil 234 symmetrically in proximity to a single-ended trace 236, the capacitive coupling 238 contribution does not partially cancel and hence is no longer negligible as shown in diagram 240. As noted, in some embodiments, appropriate termination conditions can be selected for the desired coupling mechanism while suppressing the undesired.

Termination Conditions for Single-Ended Loads.

As noted above, the sense coil (in diagram 240) can experience both inductive and capacitive coupling. The port voltages for the sense coil 234 due to both inductive and capacitive coupling mechanisms can be expressed per Equation 19:

$${V}_{coil 1 - 4} = {L}_{cpl} \frac{{dI}_{cpl}}{dt} + {M}_{ind} \frac{{dI}_{out}}{dt} + {V}_{cap} , \qquad ( Eq . 19 )$$

where V_{cap} is the voltage contribution due to capacitive coupling.

Accurate Current Sensing.

To ensure accurate, current sensing and hence the inductive coupling is dominant, the effect of capacitive coupling should be mitigated. In FIG. 2B, the current sensor or sensing structure 122 (shown as 122′), e.g., that can be implemented for sensors 122a and/or 122b, is shown implemented with a short circuit termination 242. The voltage 244 of Port “1” 246 of the sense coil 122a′ may be defined from Equation 19 per Equation 20.

$${V}_{coil 1} = {L}_{cpl} \frac{{dI}_{cpl}}{dt} + {M}_{ind} \frac{{dI}_{out}}{dt} + {V}_{cap} , \qquad ( Eq . 20 )$$

By implementing the short circuit termination, the voltage 244 at the port and capacitive coupling voltage contribution are forced to zero. By doing so, the resulting relationship shown per Equations 21-23 can be derived.

$${V}_{c o i l 1} = 0 \to {V}_{c a p} ∼ 0 \qquad ( Eq . 21 )$$

$${L}_{c p l} \frac{{dI}_{c p l}}{d t} = - {M}_{i n d} \frac{{dI}_{o u t}}{d t} , \qquad ( Eq . 22 )$$

$${I}_{c p l} = - \frac{{M}_{i n d}}{{L}_{cpl}} {I}_{o u t} , \qquad ( Eq . 23 )$$

From Equations 21-23, it can be observed that the sense coil current is proportional to that of the output current, demonstrating current sensing. However, current-to-voltage conversion is desired to drive the post-processing circuitry (e.g., the BIST 110) while still ensuring that the port voltage is low enough to ensure inductive coupling is the dominant mechanism. In the example shown in FIG. 2B, the current sensor or sensing structure further includes a 20Ω termination (R₁) 248, instead of an ideal short circuit termination. The 20Ω termination 248 can provide sufficient input drive for high dynamic range power sensing, provide phase alignment between the two sensing paths, and ensure accurate, current sensing.

To quantify the current sensing accuracy under VSWR, the normalized current sensing ratio (NCSR) may be employed for the evaluation per Equation 24.

$$N C S R = \frac{{I}_{c p l} ( V S W R )}{{I}_{o u t} ( V S W R )} \times {( \frac{{I}_{c p l} ( 50 Ω )}{{I}_{o u t} ( 50 Ω )} )}^{- 1} , \qquad ( Eq . 24 )$$

NCSR is the ratio between the sensed current I_{cpl} and output current Iₒᵤₜ over antenna VSWR normalized with respect to the ratio at 50Ω. An NCSR=1 would mean that the sensed current is perfectly tracking the output current under antenna load variation. The study simulated NCSR over the 22-41 GHz bandwidth with and without the additional 20Ω termination at Port “2.” FIG. 2D shows (i) an example simulated NVSR across the 22-41 GHz BW (plot 250) and (ii) simulated NVSR across the 22-41 GHz BW with/without the additional 50Ω termination at Port 4 (plot 252). FIG. 2D shows (i) an example simulated NCSR across the 22-41 GHz BW (254) and (ii) simulated NCSR across the 22-41 GHz BW with/without the additional 20Ω termination at Port 2 (256). From plots 254 and 256, it can be observed that the NCSR is close to 1 even in conditions up to 3:1 VSWR over a broad bandwidth and that the addition of the 20Ω termination does not introduce additional error in the current sensing.

Accurate Voltage Sensing.

To ensure voltage sensing and hence that capacitive coupling is dominant, the effect of inductive coupling should be mitigated. In FIG. 2B, the voltage sensor or sensing structure 124 (shown as 124′), e.g., that can be implemented for sensors 124a and/or 124b, is shown implemented as a voltage tracking sense coil with an open circuit termination 258. The voltage 260 of Port “4” of the sense coil 124′ may be defined per Equation 25.

$${V}_{c o i l 4} = {L}_{c p l} \frac{{dI}_{c p l}}{d t} + {M}_{i n d} \frac{{dI}_{o u t}}{d t} + {V}_{c a p} , \qquad ( Eq . 25 )$$

The inductive coupling contribution is likely due to the magnetic coupling of the sense coil current and single-ended trace current. By implementing the open circuit termination 258, it is ensured that no current flows through the sense coil 124′ and that there is no mutual inductance present. The result relationships are shown in Equations 26 and 27.

$${I}_{c p l} = 0 \to {M}_{i n d} ∼ 0 , \qquad ( Eq . 26 )$$

$${V}_{c o i l 4} = {L}_{c p l} \times 0 + 0 \times \frac{{dI}_{o u t}}{d t} + {V}_{c a p} = {V}_{c a p} . \qquad ( Eq . 27 )$$

From Equations 26 and 27, it can be observed that accurate voltage sensing can be ensured under a single-ended load by utilizing open circuit terminations. With this sensing, by ensuring phase alignment of the two sensed signals, the sensor or sensing structure can be implemented without the need for an integrated phase shifter [36]-[39]. In the example shown in FIG. 2B, the voltage sensor or sensing structure 124′ further includes a 50Ω resistive termination (R₂) 262 instead of a perfect open circuit termination to align the phases of the sensed current and voltage. Such implementation allows some current flow through the sense coil. Despite having this effect, by ensuring sufficient capacitive overlap between the output trace and the sense coil, the sensing structure is configured to have capacitive coupling as the dominant coupling mechanism.

To quantify the voltage sensing accuracy under VSWR load mismatch, the normalized voltage sensing ratio (NCSR) may be employed for the evaluation per Equation 28.

$$N V S R = \frac{{V}_{c p l} ( V S W R )}{{V}_{o u t} ( V S W R )} \times {( \frac{{V}_{c p l} ( 50 Ω )}{{V}_{o u t} ( 50 Ω )} )}^{- 1} . \qquad ( Eq . 28 )$$

NVSR is the ratio between the sensed voltage V_{cpl} and output voltage Vₒᵤₜ over antenna VSWR normalized with respect to the ratio when the antenna load is 50Ω. An NVSR=1 means that the sensed voltage is perfectly tracking the output voltage under antenna load variation. The simulated NVSR over the 22-41 GHz bandwidth with and without the additional 50Ω termination at Port 4 is shown in FIG. 2D. From plots 250, 252, it can be observed that the NVSR is close to 1 even up to 3:1 VSWR over a broad bandwidth and that the addition of the 50Ω termination does not introduce additional error in the voltage sensing.

Phase Alignment.

As mentioned in Equation 7 for power sensing (and later Equation 40 for impedance sensing), the phase offset between current and voltage coupling paths, if applicable, should be minimal to accurately track the true power delivered to the antenna load and extract the phase of the impedance when mismatched. In other words, the sensed signals must be phase-aligned, where they have the same phase over the frequency profile. The current sensing loop must have a resistive termination for the current-to-voltage conversion. Therefore, the port voltage can be defined per Equations 29 and 30:

$${V}_{Icpl} = {L}_{c p l} \frac{{dI}_{c p l}}{d t} + {M}_{i n d} \frac{{dI}_{o u t}}{d t} = - {I}_{c p l} ( {R}_{1} \vert \vert \frac{1}{j ω {C}_{1}} ) , \qquad ( Eq . 29 )$$

$${sL}_{c p l} {I}_{c p l} + s {M}_{i n d} {I}_{o u t} = - {I}_{c p l} ( {R}_{1} \vert \vert \frac{1}{s {C}_{1}} ) , \qquad ( Eq . 30 )$$

where R₁ is the resistive termination, L_{cpl} is the sense coil inductance, M_{ind} is the mutual inductance, and C₁ is the parasitic capacitance of the proceeding active post-processing circuitry. The ratio of sensed current I_{cpl} and output current Iₒᵤₜ can be derived per Equation 31.

$$\frac{{I}_{c p l}}{{I}_{o u t}} = - ( \frac{( 1 + s {C}_{1} {R}_{1} ) s {M}_{i n d}}{{R}_{1} + {s}^{2} {L}_{cpl} {C}_{1} {R}_{1} + s {L}_{c p l}} ) . \qquad ( Eq . 31 )$$

Equation 31 can then be multiplied by an RC load for the current-to-voltage conversion to get Equation 32.

$$\frac{{V}_{Icpl} ( s )}{{I}_{o u t} ( s )} = \frac{s \times \frac{{R}_{1} {M}_{ind}}{{L}_{c p l} {C}_{1} {R}_{1}}}{{s}^{2} + \frac{s}{{C}_{1} {R}_{1}} + \frac{1}{{L}_{cpl} {C}_{1}}} . \qquad ( Eq . 32 )$$

Equation 32 can then be rewritten as Equation 33:

$$\frac{{V}_{Icpl} ( s )}{{I}_{o u t} ( s )} = \frac{s \times \frac{{R}_{1} {M}_{i n d}}{{L}_{cpl} {C}_{1} {R}_{1}}}{{s}^{2} + 2 {ζω}_{I} s + {ω}_{I}^{2}} , \qquad ( Eq . 33 )$$

where the pole ω₁ and damping factor ζ are defined per Equation 34.

$${ω}_{I} = \frac{1}{\sqrt{{L}_{c p l} {C}_{1}}} , ζ = \frac{\sqrt{{L}_{c p l} {C}_{1}}}{2 {C}_{1} {R}_{1}} = \frac{1}{2 {R}_{1}} \sqrt{\frac{{L}_{c p l}}{{C}_{1}}} , \qquad ( Eq . 34 )$$

Therefore, it can be observed that the current sensing loop can act as a second-order system whose phase profile over frequency can be determined by the damping factor ζ, which is, in turn, can by controlled by the resistive termination R₁. For the capacitive coupling network with no resistive termination, it can be viewed as equivalent to a capacitive divider whose transfer function can be defined per Equation 35:

$$\frac{{V}_{c p l} ( s )}{{V}_{o u t} ( s )} = \frac{{C}_{2}}{{C}_{2} + {C}_{3}} \qquad ( Eq . 35 )$$

where C₂ is the capacitance between the two conductors, and C₃ is the capacitance between the conductor and ground and the parasitic capacitance of the active post-processing circuitry. Because the voltage sensing phase profile with pure capacitive termination can be flat across various frequencies the two sensed signals may not be phase-aligned except at a single frequency. When adding a resistive termination R₂, the transfer function can be expressed per Equations 36, 37, and 38:

$$\frac{{V}_{c p l} ( s )}{{V}_{o u t} ( s )} = \frac{s \times \frac{( {C}_{2} )}{( {C}_{2} + {C}_{3} )}}{( s + \frac{1}{{R}_{2} ( {C}_{2} + {C}_{3} )} )} . \qquad ( Eq . 36 )$$

$$\frac{{V}_{c p l} ( s )}{{V}_{o u t} ( s )} = \frac{s \times \frac{( {C}_{2} )}{( {C}_{2} + {C}_{3} )}}{( s + {ω}_{V} )} . \qquad ( Eq . 37 )$$

$${ω}_{V} = \frac{1}{{R}_{2} ( {C}_{2} + {C}_{3} )} , \qquad ( Eq . 38 )$$

With the voltage sensing profile acting as a first order system which has a linear phase profile (45°/decade) over frequency, the pole location coy may be controlled by the resistive termination R₂. Both the sensing loops may have a varying phase over frequency profile and can be aligned. Because the current sensing loop may be a 2^{nd} order system while the voltage sensing loop is a 1st order system, the phase response over frequency may not be the same between the sensing loops. But because the desired 22-42 GHz bandwidth may be only a 2:1 BW, so the slope difference is minimal, and the slope difference within the band of interest can be controlled through ζ.

To account for the absolute phase difference, the pole of the capacitive coupling path ωv may be set at a lower frequency than the inductive coupling pole ω₁ through a careful choice of R₂ to accommodate for the difference in slope.

In addition, the slope of the inductive coupling path may be carefully chosen by modifying R₁. Both poles ω_{V} and ω_{I} may be much higher than the sensor operating frequency for broadband phase alignment.

Validation.

To validate this operation and configuration, the simulated results was compared with the theoretical results using Equations 32-38. In the Equations, the parameters may be fixed in which R₁=20Ω, R₂=50Ω, C₁=10 fF, C₂=20 fF, C₃=8 fF, and L_{cpl}=25 pH. FIG. 2E shows simulated/theoretical sensor phase/phase difference plots for subplots (a)-(b) R1=20Ω and R₂=50Ω, subplots (c)-(d) R₂=50Ω and swept R1, subplots (e)-(f) R1=20Ω and swept R2. Subplots (g)-(h) show the top system level sensor phase/phase difference plots.

The deviation between simulation and theory may be attributed to imperfections in the sensing loop implementations. The coupling mechanisms are imperfectly implemented such that traces of both inductive coupling and capacitive coupling are both present even though only one of the coupling mechanisms is dominant per sensing loop. There are also other 2^{nd} order phenomena, such as self-resonance, where around the self-resonant frequency, the current sensing loop is no longer acting as a magnetically coupled inductor.

FIG. 2E, subplots (c) and (f) show V_{cpl}, I_{cpl}, and phase difference between sweeping R₁ and R₂ separately to see their impact on the phase over the frequency profile of V_{cpl}, I_{cpl}, and phase difference. While there is some deviation between the simulation and theoretical outcomes, the overall trend is observed and validates the choice of the resistive termination values, R₁=20Ω and R₂=50Ω.

FIG. 2E, subplots (g) and (h) show the overall phase over frequency response of the signals and the corresponding phase difference for the full chip top. It can be observed that a phase difference within ±5° is maintained over a 24-40 GHz bandwidth, thus validating the broadband phase alignment being supported by the resistive termination-based configuration without the need for an integrated phase shifter.

Sources of Error In Power Sensing

The accuracy of the power sensing circuit (e.g., 118) may be dependent on the accuracy of the generation of the sensed current and voltage as well as on the subsequent analog multiplication. Other limitations, such as noise and swing, may limit the dynamic range in which the power sensing is accurate. To evaluate, the power sensing error (PSE) over VSWR was defined per Equations 39 and 40

$$P {F}_{50 Ω} = avg ( \frac{{V}_{P s ense 50 Ω}}{{P}_{out 50 Ω}} ) , \qquad ( Eq . 39 )$$

$$P {F}_{V S W R} = a v g ( \frac{{V}_{P s ense VSWR}}{{P}_{out VSWR}} ) , \qquad ( Eq . 40 )$$

where V_{Psense 50Ω} and V_{Psense} VSWR correspond to the power sensing output for the nominal 50Ω and VSWR mismatched load scenario, respectively, P_{out 50Ω}and P_{out VSWR} correspond to the true power delivered to the antenna load under 50Ω and antenna VSWR. As mentioned above in relation to Equation 7, the sensor output may be a voltage that is proportional to the true power delivered to the antenna load. To have direct one-to-one correspondence, a one-time proportionality factor is required. This proportionality factor is the average instantaneous ratio of the sensor output and the true power delivered. For proper use during operation, this proportionality factor should hold regardless of the antenna load. To this end, for the evaluation, a proportionality factor for 50Ω was generated for each mismatched load scenario, PF_{50Ω}, and PF_{VSWR}. For ideal sensing, PF_{5Ω}=PF_{VSWR} under any load. To evaluate the accuracy of the one-time 50Ω factor, the power sensing error (PSE) may be defined per Equation 41:

$$P S E = 10 {log}_{10} ( \frac{P {F}_{VSWR}}{P {F}_{50 Ω}} ) , \qquad ( Eq . 41 )$$

where the PSE is essentially the ratio of the two proportionality factors on a dB scale. A close-to-zero PSE verifies the accuracy of the power sensor so that the sensor can be used in practice for unknown VSWR after its one-time 50Ω calibration.

Magnitude Sensing.

As noted above, the NCSR and NVSR may not be perfectly “1” under 3:1 VSWR, so some error may be introduced as the sensed current and voltage do not perfectly reflect the output voltage and current that are meant to be multiplied. Because the NCSR and NVSR have an inverse trend over VSWR (e.g., when the NCSR peaks above “1”, the NVSR lags below 1), their product is kept closer to 1. Note that an NCSR and NVSR of 1 correspond to perfect magnitude tracking for the sensing loops, so an NVSR/NCSR product of 1 corresponds to perfect apparent power tracking. FIG. 2F shows the corresponding error due to this imperfect current-voltage product. At 33 GHz, it can be observed that the PSE is kept within ±0.75 dB for 3:1 VSWR and ±0.34 dB for 2:1 VSWR.

Phase Alignment.

Another aspect of operations for power sensing is phase alignment. Ideally, the sensing loops are configured such that for 50Ω, the phases are aligned, thus tracking the phase difference of the true output voltage and current. However, due to non-idealities and the broadband nature of the exemplary design, some undesired phase shift may be present as shown in Equation 42:

V_{Psense}=0.5×|V_{cpl}∥I_{cpl}|cos(θ_{Z}+β) (Eq. 42)

where β is the undesired phase offset of the two sensed signals. The introduced PSE can become a function of the antenna phase and phase offset, as shown in Equations 43 and 44.

$$P S E = 10 {log}_{10} ( \frac{0 \text{.5} \times \vert {V}_{o u t} \vert \vert {I}_{o u t} \vert cos ( {θ}_{Z} + β )}{0 \text{.5} \times \vert {V}_{o u t} \vert \vert {I}_{o u t} \vert cos ( {θ}_{Z} ) cos ( β )} ) , \qquad ( Eq . 43 )$$

$$PSE ( β , {θ}_{Z} ) = 10 {log}_{10} ( \frac{cos ( {θ}_{Z} + β )}{cos ( {θ}_{Z} ) \times cos ( β )} ) , \qquad ( Eq . 44 )$$

This phase offset can introduce error asymmetrically, affecting complex loads differently based on the phase of the impedance. As an example of this, the case: β=5° can be considered for a θ_{z}=10° and θ_{z}=45°. The PSE for both load scenarios is shown below per Equations 45 and 46:

$$PSE ( 5 , 10 ) = 10 {log}_{10} ( \frac{cos ( 10 ° + 5 ° )}{cos ( 10 ° ) cos ( 5 ° )} ) = - 0.068 dB , \qquad ( Eq . 45 )$$

$$PSE ( 5 , 45 ) = 10 {log}_{10} ( \frac{cos ( 45 ° + 5 ° )}{cos ( 45 ° ) cos ( 5 ° )} ) = - 0.397 dB , \qquad ( Eq . 46 )$$

From Equations 43-44, it can be observed that the more reactive the load is, the more error can be introduced by the phase offset of the two sensed signals. When the VSWR mismatch increases, the complex load becomes more reactive, increasing the PSE due to phase mismatch.

FIG. 2G shows simulation results that highlight this relationship. FIG. 2B, subplots (a)-(b) show a mathematical calculation of the PSE over 3:1 VSWR and 2:1 VSWR due to phase misalignment, and subplots (c)-(d) show EM simulation of the same. From FIG. 2G, the error introduced by a phase offset for 3:1 VSWR and 2:1 VSWR mathematically, as well as when integrated with the EM coupling mechanisms and a complementary multiplier, can be observed. While an ideal phase shifter was used to simulate the arbitrary phase difference for the EM/circuit results, it can be observed that the PSE values and trends over VSWR are well aligned. Therefore, proper phase alignment over frequency was achieved to ensure broadband VSWR resilient true power sensing.

Example Impedance Sensing Operation

Impedance Sensing.

As noted above, dual amplitude detectors may be implemented to determine the amplitude of the current and voltage to provide for the sensed impedance measurement. FIG. 2H shows an exemplary impedance sensing operation for the built-in-self-test circuitries (e.g., 106) using sensed current and voltage measurements in accordance with an illustrative embodiment.

In the example shown in FIG. 2H, the sensed impedance may be extracted in the polar form to remove the need for performing analog division on the RF/RADAR/mm-Wave signals and utilizing bulky IQ generation networks [34]-[35]. Rather, the dual amplitude detectors, as an efficient hardware approach, employs straightforward amplitude detectors to extract the magnitude of the impedance and use the amplitude detector outputs in conjunction with the power sensing output, e.g., described in relation to FIGS. 2A-2E, to extract the magnitude and phase of the impedance through digital post-data processing [32]. The sensed impedance may be defined per Equations 39 and 40:

$$\vert {Z}_{sense} \vert = \frac{\vert {V}_{cpl} \vert}{\vert {I}_{cpl} \vert} , \qquad ( Eq . 39 )$$

$${θ}_{Z \_ sense} = {cos ( \frac{{V}_{Psense}}{\sqrt{\vert {V}_{ED} \vert \vert {I}_{ED} \vert}} )}^{- 1} , \qquad ( Eq . 40 )$$

where V_{ED} and I_{ED} are the amplitude detector outputs for the sensed current and voltage signals, respectively.

The sensed current I_{cpl} and voltage V_{cpl} may be acquired using the same sensor or sensing structure 122 and 124 (shown as 122″ and 124″) and coupling structures described in relation to FIGS. 2B, 2C, 2D, and 2E.

Coupler Sensor Example Implementation

Coupler EM Implementation.

FIG. 3A shows an example electromagnetic (EM) structure 300 of the exemplary λ/4 impedance/power coupler sensor. The first transmission line is composed of the top and bottom metal layers 302, 304 while the second line is composed of the middle metal layer 306. The quadrature coupler utilizes vertical capacitive coupling from both the top and bottom routing 302, 304 to maximize vertical coupling. At the design frequency, the quadrature coupler achieves a C=0.957. The simulated passive efficiency of the coupler sensor EM structure is ≥87%.

FIG. 3B shows schematic and mathematically derived equations for the exemplary coupler impedance/power sensor when a source impedance is introduced. From this result, it can be observed that the sensed current I_{cpl} has gained a dependence on the antenna load and is no longer a fixed value for a fixed input voltage. This dependence may occur whether Zₐ (also referred to as Z_{source}) is complex or real and is purely defined by (5-61). Since the sensed current I_{cpl} is not constant for a fixed input voltage, the sensed voltage V_{cpl} can no longer be solely/accurately relied on to measure the antenna impedance under antenna load variation. FIG. 3C shows simulation results of the sensed current I_{cpl} and the corresponding coupler sensor's power/impedance sensing results using only V_{cpl} for a fixed input power and varying source resistances. From the simulation results, the variance in the sensed current I_{cpl} as a function of VSWR increases as the source impedance increases, power sensing is unaffected by the addition of source resistance, and the impedance sensing error increases when only using V_{cpl} but is unaffected when both signals are used.

Open Circuit Port Termination.

To ensure the exemplary impedance/power coupler sensor operation, open and short terminations are included for Ports 3 and 4 (308, 310) respectively. For both sensed ports, each port is connected to a separate small-sized (21.28 μm/40 nm) common source (CS) buffer. Minimizing the CS buffer allows us to maximize the CS input impedance to satisfy the open circuit loading condition, mitigate the capacitive loading, which can misalign the phases of the two sensed signals, and still allow for sufficient voltage gain. The simulated effect of the open circuit loading is shown in FIG. 3C, subpanel (a) and FIG. 3C, subpanel (b). In particular, FIG. 3C depicts simulated power sensing error (PSE) and normalized impedance ratio (NIR) for various (a-b) open circuit and (c-d) short circuit port terminations.

Short Circuit Port Implementation.

For the short termination, a low impedance termination can be provided to perform current sensing by transforming it to a voltage for large dynamic range power sensing and fulfilling amplitude detector driving requirements. The simulated effect of the short circuit loading on only the passive 90° coupler's sensing performance is shown in FIG. 3C, subpanel (c) and FIG. 3C, subpanel (d).

It can be observed the coupler sensor's performance degrades as the short circuit loading is increased, which can increase the current-to-voltage conversion ratio. In addition, the reactive parasitics due to routing/vias can be minimized to avoid extra phase misalignment and performance degradation. Therefore, a loading of ˜1Ω may be employed and shown in this example.

In FIG. 3A, EM routing-based low impedance termination is shown, which can maximize the capacitive overlap and negative mutual inductance to minimize the net inductance. There can be process variations as the resistor is solely implemented through routing/vias. This variation has been calculated based on the design kit information, and the corresponding simulation results are shown in FIG. 3D, subpanel (a) and FIG. 3D, subpanel (b).

FIG. 3D shows simulated (a) NIR and (b) PSE under process variation for the EM short. (c) NIR using both sensed signals, (d) NIR using only V_{cpl}, (e) I_{cpl} normalized, and (f) PSE under varying source loading conditions.

Input Port Implementation.

A feature of the exemplary coupler sensor is that for a fixed input voltage swing, the I_{cpl} signal's value remains constant, independent of the mismatched antenna load. This allows the device to only monitor the change in the V_{cpl} signal to characterize the mismatched antenna impedance. However, this property degrades when the PA no longer acts as an ideal voltage source and source impedance is introduced. With source impedance, the 90° coupler's input port voltage is no longer equal to the input source voltage and gains a dependence on the current flowing into Port “1” 316 multiplied by the source impedance. The current flowing through Port “1” 316 has a dependence on the antenna load impedance and will transfer that dependence to I_{cpl}. The net effect of introducing source impedance, as shown in FIG. 3B, is that I_{cpl} should be defined to be the following:

$${I}_{cpl} = \frac{{j V}_{in} \sqrt{1 - {C}^{2}}}{{k}_{1} ( C + \frac{{Z}_{source}}{{Z}_{ant}} )} ,$$

where Z_{source} is the Thevenin's equivalent impedance presented by the PA and OMN.

From this result, it can be observed that the sensed current Icpl has gained a dependence on the antenna load and is no longer a fixed value for a fixed input voltage. This dependence occurs whether Z_{source} is complex or real and is purely defined by the above equation. Since Icpl is no longer a constant value for a fixed input voltage, we can no longer accurately rely on only the sensed voltage Vcpl to measure the antenna impedance under antenna load variation. Simulation results of Icpl and the corresponding coupler sensor's power/impedance sensing results using only Vcpl for a fixed input power and varying source resistances is shown in FIG. 3D, subpanel (c)-FIG. 3D subpanel (f). From these results, the variance in Icpl as a function of VSWR increases as the source impedance increases, power sensing is unaffected by the addition of source resistance, and the impedance sensing error increases when only using Vcpl but is unaffected when both signals are used.

Although the undesired effects of large source impedance can be de-embedded out, to preserve the simplicity in practical implementation, low PA output impedance after its OMN is desired. On the other hand, many mm-Wave/RF PAs adopt differential operations and on-chip transformer-/coupler-based baluns as their OMNs. It can be shown that these baluns are often, in fact, impedance inverting networks [64′], [65′], [66′], which naturally lower the output impedance after the OMNs. Hence, in this example, an impedance inverting balun is introduced to ensure low PA output impedance after the balun while still providing the desired load-pull impedance to the PA core. A compact coupler-based balun is used as it supports broadband impedance transformation, low loss, and design simplicity [67′].

Coupler Sensor Architecture Comparison.

Conventionally, a quarter-wavelength (λ/4) directional coupler sensor has been used for VSWR power/impedance sensing. The generic Z-matrix of a λ/4 directional coupler governs the terminal current/voltage relationships at its four ports. By imposing specific termination conditions at these ports, mathematical relationships between the antenna impedance/power and the sensed signals can be achieved. The exemplary joint impedance/power coupling-based sensor can assign the coupler ports with completely different terminations (see diagram 314) compared to the traditional implementation to ensure its high accuracy over VSWR variations and ease its practical implementation.

Traditional Coupler Sensor.

The conventional coupler sensor Under the most conventional use, a fixed load impedance (Z₁) and power detector (Z₂) is connected to both ports, respectively. By subtracting the power of the ports, the corresponding magnitude of the reflection coefficient, |Γ| [24′], [62′], [63′] can be calculated. This method, however, neither gives information about the phase of the complex F nor the real power delivered to the antenna load.

Exemplary Coupler-Based Sensor.

The exemplary coupler sensor is defined as an equivalent λ/4 coupled line with the following configuration: the input, i.e., PA output, is connected to Port “1” 316, the antenna load is connected to Port “2” 318, and Ports 3 and 4 (308, 310) are used for the sensed signals. This coupler configuration is very beneficial as Port “3” 308 and Port “4” 310 are in the same location compared to the conventionally used sensor ports, Port 2 and Port 4, which are λ/4 spaced away. This mitigates the need for excessively long routing which adds additional loss and phase misalignment for integrating the sensing ports with the required active circuitry. For the exemplary coupler-based sensor, the sensor ports are terminated with a short and open circuit impedance, respectively.

From the 90° length and port termination conditions, power sensing and impedance sensing can be defined as follows:

$${V}_{Psense} = {V}_{cpl} \times {I}_{cpl} = \frac{( {C}^{2} - 1 ) {V}_{out}^{2}}{{CZ}_{ant}} = \frac{( {C}^{2} - 1 ) {P}_{out}}{C}$$

$${Z}_{sense} = \frac{{V}_{cpl}}{{I}_{cpl}} = \frac{{CZ}_{0}^{2}}{{Z}_{ant}}$$

where V_{cpl} and I_{cpi} are the sensed signals for the proposed coupler sensor for the open and shorted ports, respectively. The product of the two sensed signals is proportional to the true power delivered to the antenna, while the ratio is inversely proportional to Zₐₙₜ. The input impedance can also be defined presented by the 90° coupler to be the following

$${Z}_{in} = \frac{{Z}_{ant}}{{C}^{2}} .$$

Since the coupling coefficient C is kept close to one, the input impedance of the 90° coupler is equivalent to the antenna impedance. This allows the sensor to be independent of the PA output matching network. This means that the proposed coupler sensor can be a standalone sensor structure that does not have to be codesigned with the matching network, making it PA architecture and matching network agnostic. Lastly, the sensed signal, I_{cpl}, has the following relations:

$${V}_{out} = {C V}_{in}$$

$${I}_{cpl} = \frac{{k}_{2} {V}_{out}}{{Z}_{0}}$$

$${V}_{cpl} = \frac{{k}_{1} {V}_{out}}{{Z}_{ant}}$$

where Vₘ is the coupler sensor's input voltage, Zₒ is the 90° coupler's characteristic impedance, and k₁/k₂ are proportionality factors. For a fixed input power, Vₘ is fixed and hence Vₒᵤₜ is also fixed. Moreover, as observed from

$${I}_{cpl} = \frac{{k}_{2} {V}_{out}}{{Z}_{0}} ,$$

the sensed current is independent of the antenna impedance, allowing impedance sensing with only one signal V_{cpl}.

Coupler Sensor Parameter Derivations.

Below, the derivation of the exemplary and traditional coupler sensors are analyzed to better understand the loading requirements/sensing relationships and inspire additional coupler sensor-based architectures in the future. All derived equations come from the 90° coupler's Z matrix and the required termination conditions to achieve the desired mathematical sensing relationships.

Quadrature Coupler Z-Matrix.

The Z-matrix for a 90° coupled line coupler is defined below as the following:

$$[ \begin{matrix}{V}_{1} \\ {V}_{2} \\ {V}_{3} \\ {V}_{4}\end{matrix} ] = k [ \begin{matrix}0 & 0 & - j & - jC \\ 0 & 0 & - jC & - j \\ - j & - jC & 0 & 0 \\ - jC & - j & 0 & 0\end{matrix} ] [ \begin{matrix}{I}_{1} \\ {I}_{2} \\ {I}_{3} \\ {I}_{4}\end{matrix} ]$$

$$k = \frac{{Z}_{0}}{\sqrt{1 - {C}^{2}}} ,$$

where V₁-V₄ are the port voltages and I₁-I₄ are the currents entering the coupler's ports. From this Z-matrix, the following set of equations is obtained whose sensing characteristics depend on the port terminations:

V₁=(−jI₃−jCI₄)k

V₂=(−jCI₃−jI₄)k

V₃=(−jI₁−jCI₂)k

V₄=(−jCI₁−jI₂)

Exemplary Coupler Sensor.

For the exemplary coupler sensor, Port “1” 316 is connected to the input source, Port “2” 318 is connected to the antenna load, and Port “3” 308 and Port “4” 310 are used as the sensed ports. For the two sensed ports, one is connected to an open circuit termination while the other is connected to a short circuit termination. Therefore, this results in two possible cases, which are detailed below.

Case 1: In the first case, Port “3” 308 is connected to an open circuit termination, and Port “4” 310 is connected to a short circuit termination. Therefore, the termination conditions imposed are the following:

V₁=Vᵢₙ, V₂=Vₒᵤₜ, I₃=0, V₄=0,

Therefore V₁, V₂, and V₄ can be defined as:

V₁=k(−jI₃−jCI₄)=−jkCI₄

V₂=k(−jIC₃−jI₄)=−jkI₄

V₄=(−jI₁−jI₂)=0→I₂=−CI₁

To ensure the variables are only in terms of the antenna impedance and sensed signals, the relation above is used to derive the following:

$${I}_{2} = - {CI}_{1} \to {I}_{1} = \frac{- {I}_{2}}{C} .$$

To solve for the impedance sensing relationship, the ratio of the sensed voltage and output voltage, V₃ and V₂, are evaluated to define:

$${V}_{3} {V}_{2} = k ( - j ) ( {I}_{1} + {CI}_{2} ) ( - j ) {kI}_{4} = {k}^{2} ( - 1 ) ( {I}_{1} + {CI}_{2} ) {I}_{4}$$

$${V}_{3} {V}_{2} = {k}^{2} ( - 1 ) ( \frac{- {I}_{2}}{C} + {CI}_{2} ) {I}_{4} = - {k}^{2} ( {I}_{2} ) ( \frac{{C}^{2} - 1}{C} ) {I}_{4}$$

The antenna impedance can then be defined as the following using Ohm's law:

$${V}_{2} = - {I}_{2} {Z}_{ant} \to {I}_{2} = \frac{- {V}_{2}}{{Z}_{ant}}$$

where I₂ is the current entering the coupler's Port “2” 318. The sensed impedance can then solved to be the following:

$$\frac{{V}_{3}}{{I}_{4}} = \frac{{k}^{2} ( - 1 ) ( {I}_{2} )}{{V}_{2}} ( \frac{{C}^{2} - 1}{C} ) = \frac{{k}^{2}}{{Z}_{ant}} ( \frac{{C}^{2} - 1}{C} )$$

$$\frac{{V}_{cpl}}{{I}_{cpl}} = \frac{{V}_{3}}{{I}_{4}} = \frac{( \frac{{{Z}_{0}}^{2}}{1 - {C}^{2}} )}{{Z}_{ant}} ( \frac{{C}^{2} - 1}{C} ) = \frac{- {{Z}_{0}}^{2}}{{CZ}_{ant}}$$

Here, the ratio of the two sensed signals can be inversely proportional to the antenna impedance where only the polarity flip needs to be de-embedded in the data post-processing.

To solve for the true power sensing relationship, the product of the two sensed signals, V₃ and V₂, are analyzed to provide:

$$\frac{{V}_{3}}{{V}_{2}} = \frac{k ( - j ) ( {I}_{1} + {CI}_{2} )}{{ijkI}_{4}} = \frac{( {I}_{1} + {CI}_{2} )}{{I}_{4}} = \frac{{I}_{2}}{{I}_{4}} ( \frac{{C}^{2} - 1}{C} )$$

$$\frac{{V}_{3}}{{V}_{2}} = \frac{- {V}_{2}}{{I}_{4} {Z}_{ant}} ( \frac{{C}^{2} - 1}{C} ) = \frac{{{V}_{out}}^{2}}{{Z}_{ant}} ( \frac{1 - {C}^{2}}{C} )$$

The product of the two sensed signals can be made proportional to the antenna's true power with no undesired j terms so no additional phase shift through hardware is required for proper power tracking. Lastly, the input impedance presented by the coupler sensor is investigated. To do so, the input/output voltage behavior of the proposed design is analyzed by dividing V₁ and V₂ to provide:

$$\frac{{V}_{2}}{{V}_{1}} = \frac{- {jkI}_{4}}{- {jkCI}_{4}} = \frac{1}{C} \to {V}_{2} = \frac{{V}_{1}}{C} \to {V}_{out} = \frac{{V}_{in}}{C}$$

Then, the ratio of V₂ and I₂ can be calculated as:

$$\frac{{V}_{2}}{{I}_{2}} = - {Z}_{ant} = \frac{( \frac{{V}_{1}}{C} )}{- {CI}_{1}} = \frac{{V}_{1}}{- {C}^{2} {I}_{1}}$$

$${Z}_{ant} = \frac{{V}_{1}}{{C}^{2} {I}_{1}} = \frac{{Z}_{in}}{{C}^{2}} \to {Z}_{in} = {C}^{2} {Z}_{ant}$$

If C is close to 1, the impedance presented to the PA OMN is approximately the same as the antenna impedance. Therefore, this coupler architecture can be added in series to any PA OMN.

Case 2: In the second case, Port “3” 308 is connected to a short circuit termination and Port “4” 310 is connected to an open circuit termination. Therefore, the termination conditions imposed are the following:

V₁=Vᵢₙ, V₂=Vₒᵤₜ, V₃=0, I₄=0

Therefore the above can be expressed as:

$${V}_{1} = k ( - {jI}_{3} - {jCI}_{4} ) = - {jkI}_{3}$$

$${V}_{2} = k ( - {jIC}_{3} - {jI}_{4} ) = - {jkCI}_{3}$$

$${V}_{3} = k ( - {jI}_{1} - {jCI}_{2} ) = 0 \to {I}_{2} = \frac{- {I}_{1}}{C}$$

To solve for the impedance sensing relationship, the ratio of the sensed voltage and output voltage, V4 and V2, are examined to provide:

V₄V₂=−jk(CI₁+I₂)(−j)kCI₃=k²(CI₁+I₂)CI₃

To ensure the variables are only in terms of the antenna impedance and sensed signals, the above relation is used to derive the following:

$${I}_{2} = \frac{- {I}_{1}}{C} \to {I}_{1} = {CI}_{2}$$

$${V}_{4} {V}_{2} = - {k}^{2} ( - {C}^{2} {I}_{2} + {I}_{2} ) {CI}_{3} = - {k}^{2} ( {I}_{2} ) ( 1 - {C}^{2} ) {CI}_{3}$$

$$\frac{{V}_{4}}{{I}_{3}} = \frac{{k}^{2} ( - 1 ) ( {I}_{2} ) ( 1 - {C}^{2} ) C}{{V}_{2}}$$

The antenna impedance can then be defined as the following using Ohm's law:

$${V}_{2} = - {I}_{2} {Z}_{ant} \to {I}_{2} = \frac{- {V}_{2}}{{Z}_{ant}}$$

Where I₂ is the current entering the coupler's Port “2” 318. The sensed impedance can then be solved to be the following:

$$\frac{{V}_{cpl}}{{I}_{cpl}} = \frac{{V}_{4}}{{I}_{3}} = \frac{{k}^{2} ( 1 - {C}^{2} ) C}{{Z}_{ant}} = \frac{( \frac{{{Z}_{0}}^{2}}{Z - {C}^{2}} ) ( 1 - {C}^{2} ) C}{{Z}_{ant}} = \frac{{{CZ}_{0}}^{2}}{{Z}_{ant}}$$

From the above, it can be observed that the ratio of the two sensed signals is inversely proportional to the antenna impedance. To solve for the true power sensing relationship, the product of the two sensed signals, V₄ and V₂, are assessed to provide:

$$\frac{{V}_{4}}{{V}_{2}} = \frac{- kj ( {CI}_{1} - {jI}_{2} )}{- {jkCI}_{3}} = \frac{( {I}_{2} ) ( 1 - {C}^{2} )}{{CI}_{3}} = \frac{( \frac{- {V}_{2}}{{Z}_{ant}} ) ( 1 - {C}^{2} )}{{CI}_{3}}$$

$${V}_{cpl} {I}_{cpl} = {V}_{4} {I}_{3} = \frac{{{V}_{2}}^{2} ( {C}^{2} - 1 )}{{Z}_{ant} C} = \frac{{{V}_{out}}^{2}}{{Z}_{ant}} ( \frac{{C}^{2} - 1}{C} )$$

Here, it can be observed that the product of the two sensed signals is proportional to the antenna true power with no undesired j terms, so no additional phase shift through hardware is required for proper power tracking. Lastly, the input impedance presented by the coupler sensor can be examined to validate the design agnostic property of the proposed architecture. To do so, the input/output voltage behavior of the proposed design is assessed by dividing V₁ and V₂ using to provide:

$$\frac{{V}_{2}}{{V}_{1}} = \frac{- {jkCI}_{3}}{- {jkI}_{3}} = C \to {V}_{2} = {C V}_{1} \to {V}_{out} = {C V}_{in}$$

Then, the ratio of V₂ and I₂ can be examined to provide:

$$\frac{{V}_{2}}{{I}_{2}} = - {Z}_{ant} = \frac{{C V}_{1}}{\frac{- {I}_{1}}{C}} = \frac{- {C}^{2} {V}_{1}}{{I}_{1}}$$

$${Z}_{ant} = \frac{{C}^{2} {V}_{1}}{{I}_{1}} = {C}^{2} {Z}_{in} \to {Z}_{in} = \frac{{Z}_{ant}}{C}$$

It can be observed that if C is close to 1, the impedance presented to the PA OMN is approximately the same as the antenna impedance. Therefore, the exemplary coupler architecture can be added in series to any PA OMN.

Example Coupled-Based Detector Circuit Implementation

FIG. 3E shows an exemplary antenna module system 100 (e.g., 100a, 100b, 100c, 100g, now shown as 320) configured for broadband-capable coupler sensing-based VSWR resilient true power/impedance detection in accordance with an illustrative embodiment.

The quadrature coupling 322 (shown as 322′) provides sensed current and sensed voltage to the BIST circuit (e.g., 110). The BIST circuit of FIG. 3E includes a set of buffers 324, amplitude detectors 326, phase shifters 328, and an analog multiplier 330.

The buffers 324 are connected to the current sensor or sensing structure and voltage sensor or sensing structure to receive the sensed current I_{sensing} and V_{sensing}. The buffers are configured to provide reverse isolation capabilities and include compatibility with the termination conditions.

Amplitude detector 326 is connected to the buffer 324 and is configured to provide the sensed amplitude signal outputs for the sensed voltage and sensed current.

The phase shifter 328 is connected to the amplitude detector 326 and is configured to compensate for any undesired phase mismatch between the two sensing paths.

The analog multiplier 330 is connected to the output of the phase shifter 328 to generate a combined signal using, e.g., transconductance multipliers. Examples of analog multipliers 412 that may be used include single-balanced Gilbert multiplier (SBGM), double-balanced Gilbert multiplier (DBGM), and complementary multiplier, among other circuits described herein.

Example Coupler Circuit Implementation.

FIGS. 3F and 3G show an example circuit implementation of the coupled-based detector. In the example shown in FIG. 3F, the coupled-based detector includes two-stage PA (332, 334) integrated with the coupler-based sensor 336 and corresponding sensing circuitry 338. The two sensed signals V_{cpl} and I_{cpl} 340, 342 are connected to two stages (332, 334) of CS buffers 344 in which the 1st stage CS buffer is utilized to maximize the voltage gain to the output amplitude detectors for |Zₐₙₜ| sensing. The 2nd stage CS buffer 344 connects to a CLC phase shifter 346 to compensate for any undesired phase mismatch between the two sensing paths. It is then followed by a balun 348, analog amplifier 350, and operational amplifier 352 for power sensing. The balun 348 can provide bandpass filter operation and gain for the predefined frequency.

Analog Multiplier.

FIG. 3H shows a symmetric double-balanced active Gilbert multiplier topology that may be used for the analog multiplication block. In particular, FIG. 3G depicts the analog multiplier, and FIG. 3I shows a 3-stage Dickson rectifier. The conventional double balanced active Gilbert multiplier provides asymmetric loading to each input and has an inherent input phase difference at mm-Wave frequencies due to the asymmetric capacitive path seen only by the CS input. In the proposed multiplier architecture, the sensed voltage output and the sensed current output drive both the CS stages and the current commutating stages, thus removing any asymmetry due to the signal paths into and within the multiplier.

Operational Amplifier.

The operational amplifier (op-amp) 352 block may include a single stage differential pair with PMOS inputs. PMOS inputs may be employed to minimize noise and to accommodate for the multiplier DC output common mode. A single stage amplifier may be employed to minimize power, minimize noise, and ensure loop stability. The open-loop op-amp gain is tunable by the bias current that is controlled by an external control voltage, V_{ctrl}.

Amplitude Detector.

FIG. 3I shows an example three-stage Dickson rectifier that may be implemented as the amplitude detector topology for the exemplary coupled-based sensor. The RF to DC conversion gain for the N-stage Dickson rectifier may be defined as the following [68]:

V_{DC}=2N(\sqrt{2}V_{RF}−Vₜₕ)

where Vₜₕ is the transistor threshold voltage, V_{RF} is the RF input voltage, and V_{DC} is the DC output voltage. This allows us to easily control the RF to DC conversion gain based on the number of stages. This rectifier may be employed for its high linearity, fully passive implementation, controllable conversion gain, and moderate input impedance to minimize the impedance conversion required for the 1st stage buffer [69].

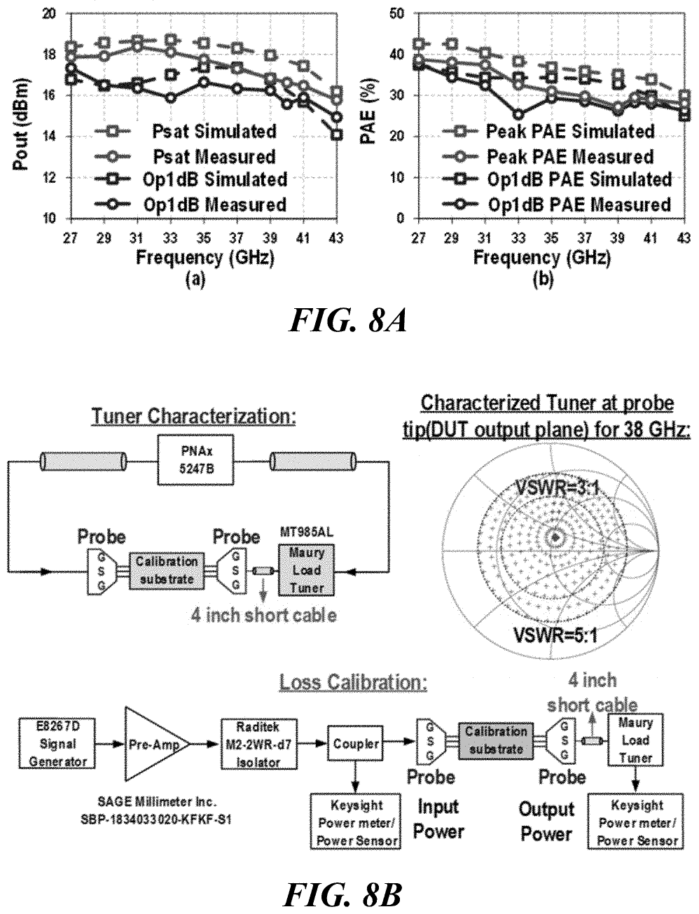

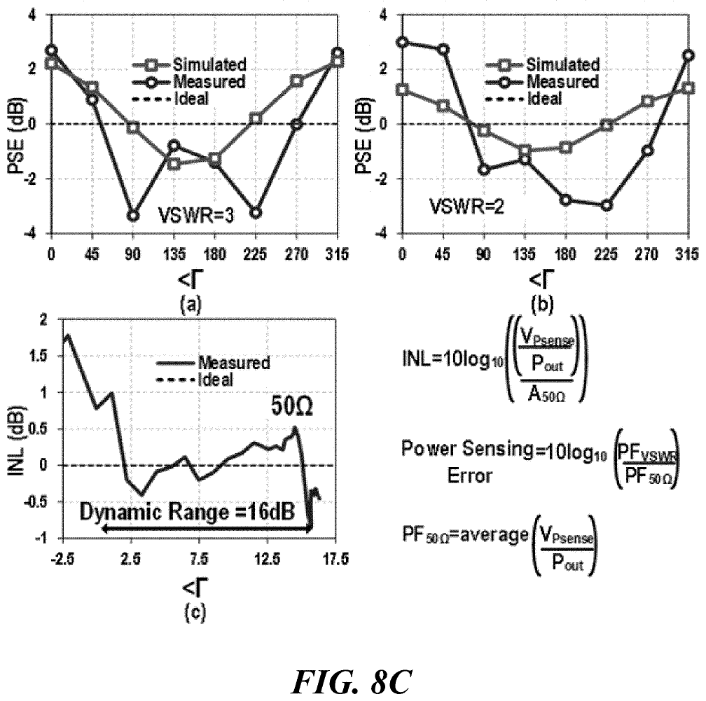

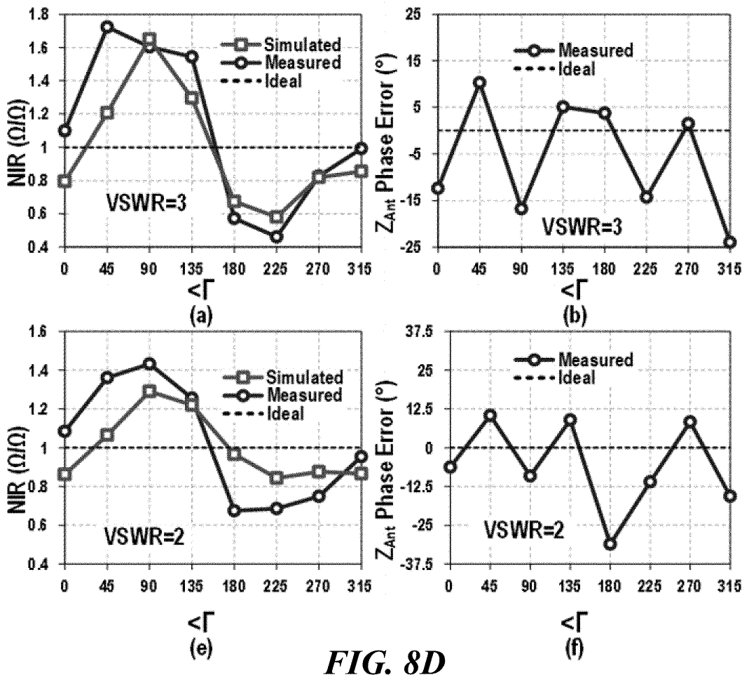

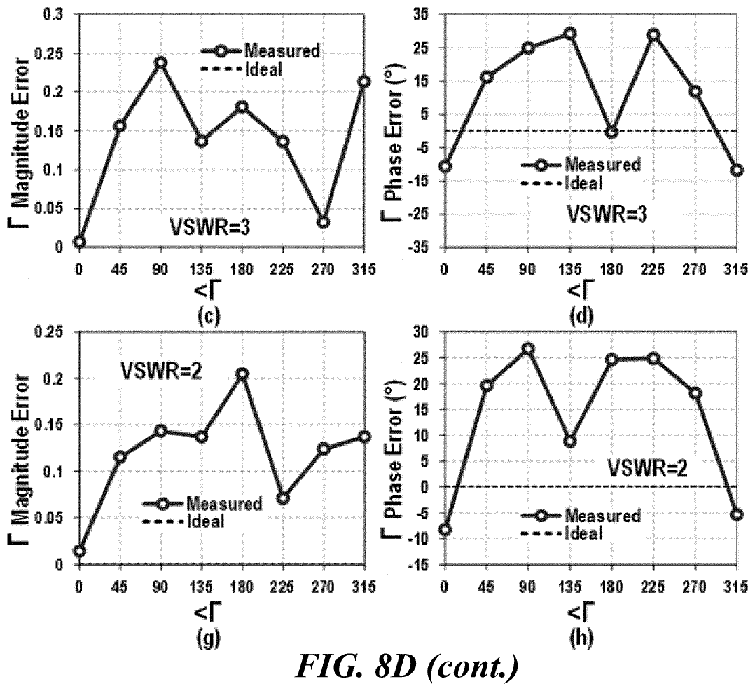

Experimental results for the coupler-based power-impedance detector is provided is FIGS. 8A-8E.

Example Broadband-Capable Current/Voltage Sensing-Based VSWR Resilient True Power/Impedance Detector #1

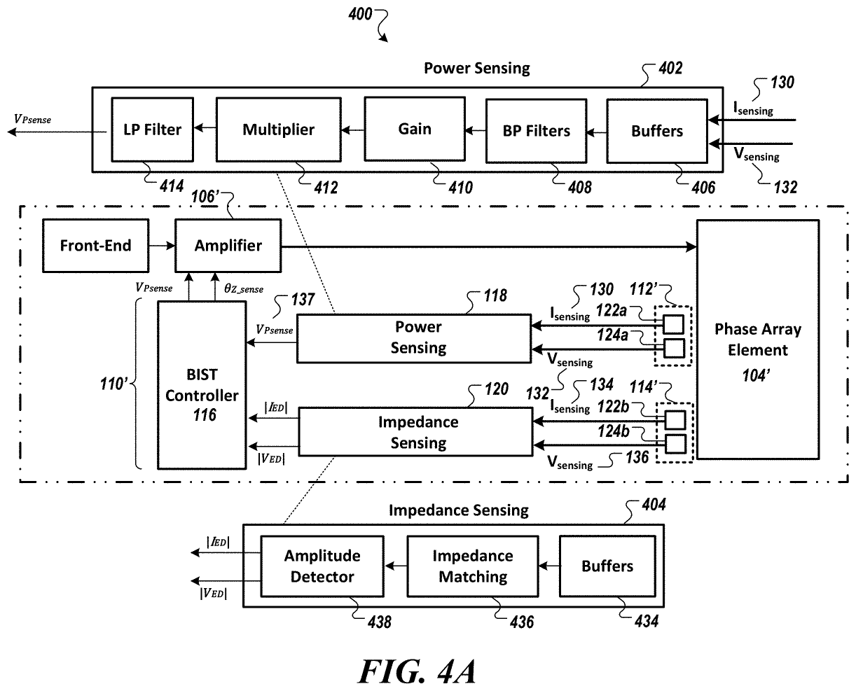

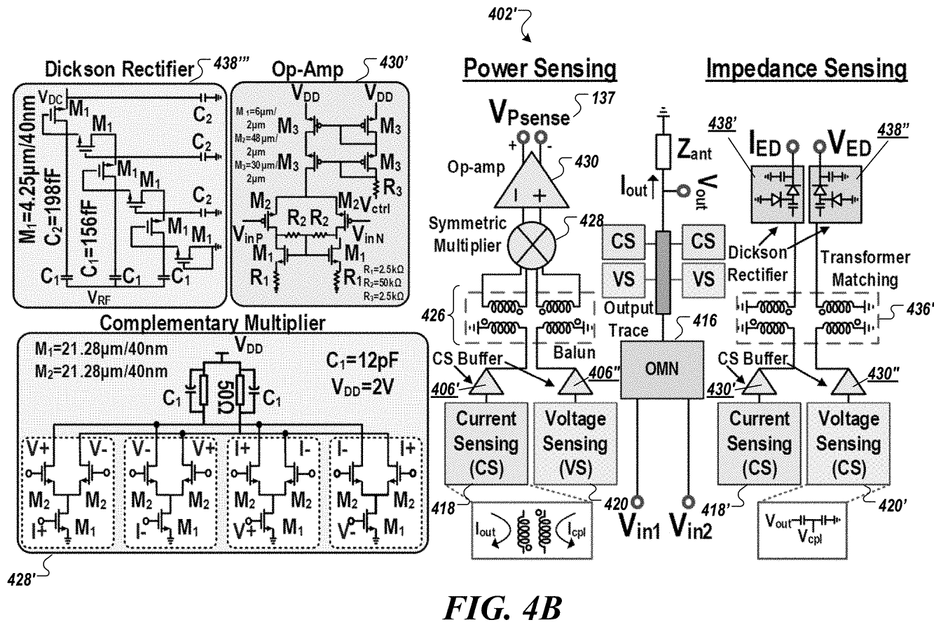

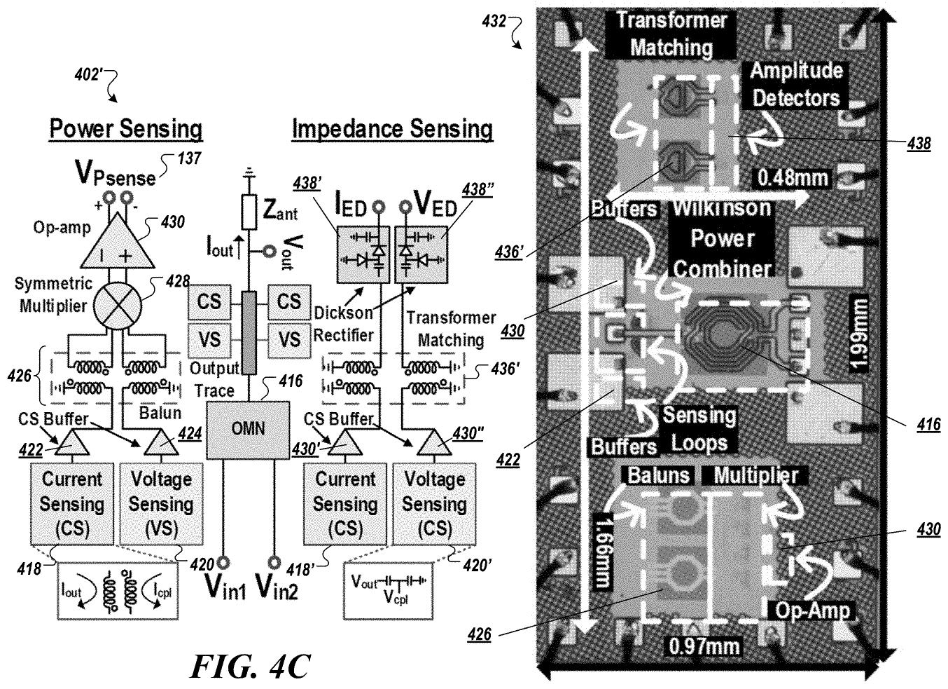

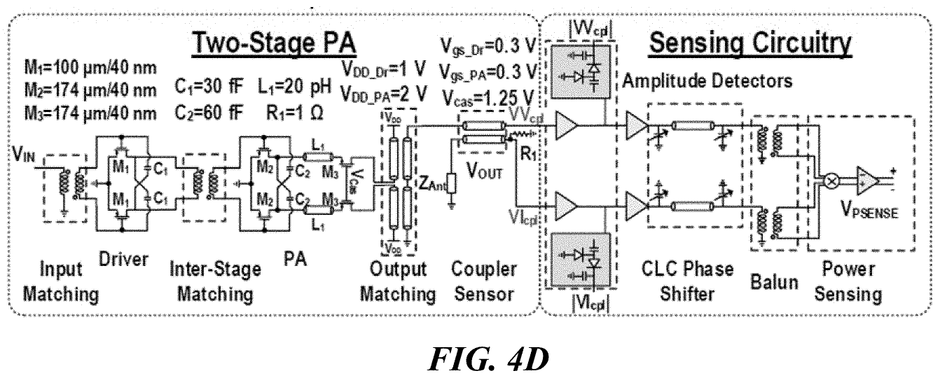

FIG. 4A shows an exemplary antenna module system 100 (e.g., 100a, 100b, 100c, 100g, now shown as 400) configured for broadband-capable current/voltage sensing-based VSWR resilient true power/impedance detection in accordance with an illustrative embodiment.

Power Sensing Circuit.

In the example shown in FIG. 4A, the power sensing circuit 118 (shown as 402) includes a symmetric configuration of a set of buffers 406, bandpass filters 408, gains 410, an analog multiplier 410 (shown as multiplier 410), and a low-pass filter 412.

The buffers 406 are connected to the current sensor or sensing structure 122a and voltage sensor or sensing structure 124a to receive the sensed current I_{sensing} 130 and V_{sensing} 132. The buffers are configured to provide reverse isolation capabilities and include compatible with the termination conditions, e.g., described in relation to FIG. 2B.

The bandpass filter 408 may be connected to the buffers 406 to ensure balanced signals over the frequency bandwidth of interest (e.g., between 22-41 GHz for 5G, mmWave, or other frequencies described herein) prior to the signals being amplified, e.g., via gain 410, to be provided to the analog multiplier 412. In some embodiments, the bandpass filter 408 and gain 410 may be implemented in a single component, e.g., a Balun.

The analog multiplier 412 is connected to the output of the bandpass filter 408 and/or gain 410 to generate a combined signal using, e.g., transconductance multipliers. Examples of analog multipliers 412 that may be used include single-balanced Gilbert multiplier (SBGM), double-balanced Gilbert multiplier (DBGM), and complementary multiplier, among other circuits described herein.

The low pass filter 414 is connected to the output of the analog multiplier 412, e.g., to remove any 2^{nd} harmonics generated from the multiplication. The output of the low pass filter 414 may be provided to the BIST controller (e.g., 116) or to an output matching network (OMN) or other impedance matching circuitries, e.g., of a reconfigurable power amplifier or front-end component.

Impedance Sensing.

In the example shown in FIG. 4A, the impedance sensing circuit 120 (shown as 404) includes a symmetric configuration of a set of buffers 434, impedance matching circuit 436, and amplitude detector 438.

The buffers 434 are connected to the current sensor or sensing structure 122b and voltage sensor or sensing structure 124b to receive the sensed current I_{sensing} 134 and V_{sensing} 136. The buffers are configured to provide reverse isolation capabilities and include compatible with the termination conditions, e.g., described in relation to FIG. 2B.

The impedance matching circuit 436 is configured to broadband voltage gain for the frequency range of interest for the subsequent amplitude detection.

The amplitude detector is connected to the impedance matching circuit 436 and is configured to provide the sensed amplitude signal outputs for the sensed voltage and sensed current.

Example Circuit Implementation for Compact VSMR Detector

FIG. 4B shows an example circuit implementation of the power sensing circuit 402 (shown as 402′).

Power Sensing Implementation.

The example power sensing circuit 402′ is shown in combination with an output matching network 416, e.g., implemented in a power amplifier (e.g., 106). The power sensing circuit 402′ may be connected to a pair of current/voltage sensing loops that are placed on each side of the output trace connecting to the ground-signal-ground (GSG) output pads.

In the example shown in FIG. 4B, the current/voltage sensing loops 418, 420 (previously referenced as sensor 122a and sensor 124a) are connected to a set of common-source (CS) buffers 405 (shown as 406′, 406″), respectively. The buffers (406′, 406″) are configured to ensure there is sufficient reverse isolation to the current and voltage sensing (418, 420), and that the phase difference of the two loops is driven entirely by the termination conditions. The outputs of the common-source buffers 406′, 406″ are connected to a balun 426 configured to provide single-ended-to-differential conversion that can operate in combination with a complementary analog multiplier 428 (shown as “Symmetric Multiplier” 428). The balun network 426 could be carefully designed to ensure that it is balanced over a frequency bandwidth of interest, e.g., over the 22-41 GHz bandwidth, while still providing sufficient voltage gain. The Balun 426 can be considered to implement both the bandpass filter 408 and the gain 410.

The complementary analog multiplier 428 may multiply the two sensed signals outputted from the Balun 426 while providing low-pass filtering to remove the 2nd harmonic term [24]. The complementary analog multiplier 428 can be considered to implement both the multiplier 412 and low pass filter 414. The power sensing circuit 402′, in this example, is terminated with a PMOS input single-stage op-amp 430 configured to enhance the dynamic range of the power sensing output [41]-[42], and that provides the output power sensed signal 136. Circuit 430′ shows an example implementation of the PMOS input single-stage op-amp 430. Other configurations may be employed.

Analog Multiplication.

Conventional analog multiplier architectures based on the single-balanced Gilbert multiplier (SBGM) and double-balanced Gilbert multiplier (DBGM) support analog multiplication but can exhibit input asymmetry at mm-Wave frequencies [43]-[45]. This asymmetry may be due to the unequal loadings of the CS buffer (e.g., 422, 424) and cascode input paths, resulting in amplitude and phase offsets of the two inputs and the multiplier block itself. To resolve or mitigate these effects, the complementary multiplier (PCM) 428 may employ two parallel pairs of double-balanced Gilbert multiplier cells whose inputs for the sensed current and voltage signals are flipped or inverted. The inherent symmetry of the architecture can provide symmetric input loading and a symmetric signal path for the multiplier while removing any amplitude/phase mismatch to the sensor inputs and the multiplier block itself. Circuit 428′ shows an example implementation of the complementary multiplier 428.

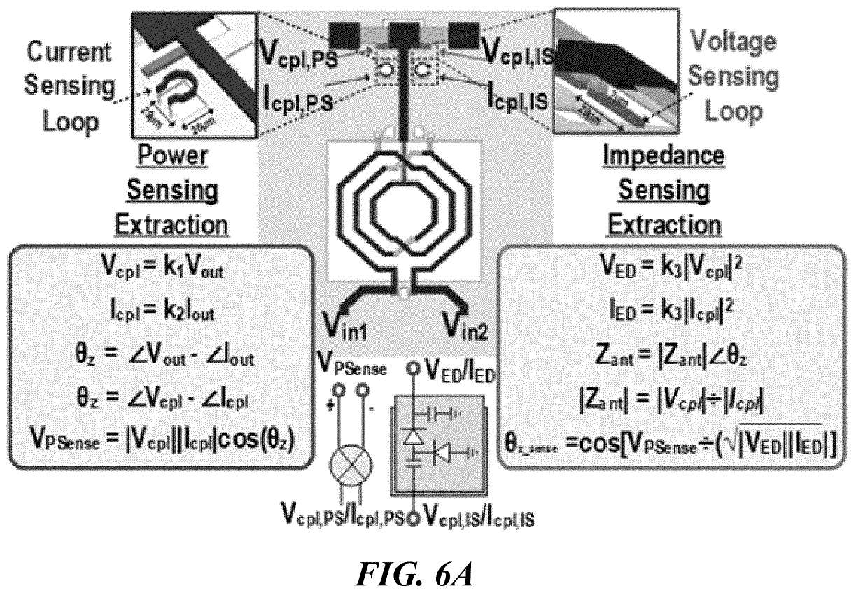

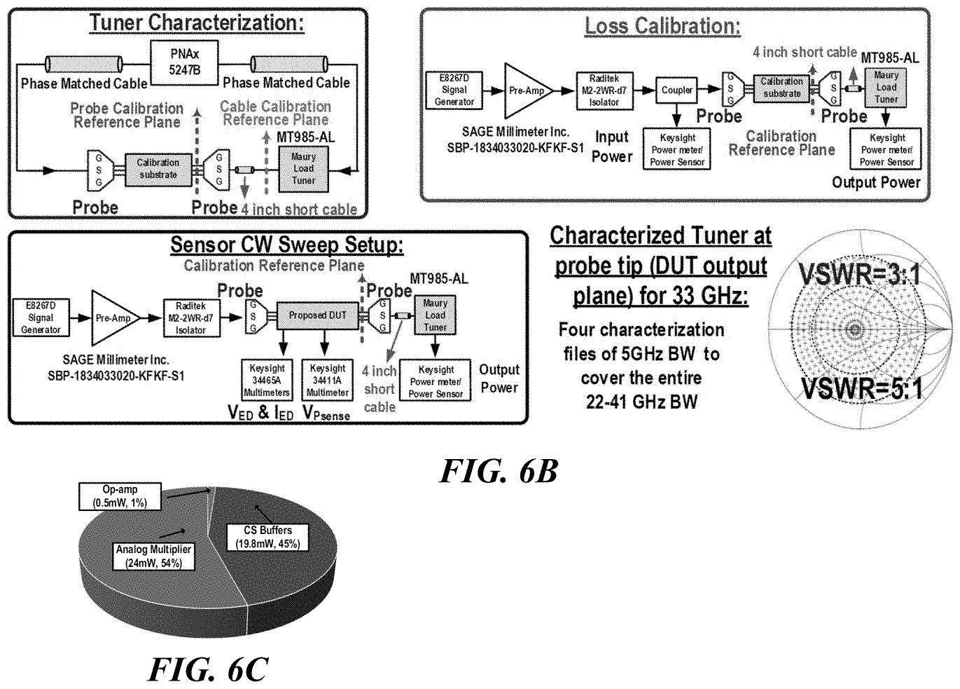

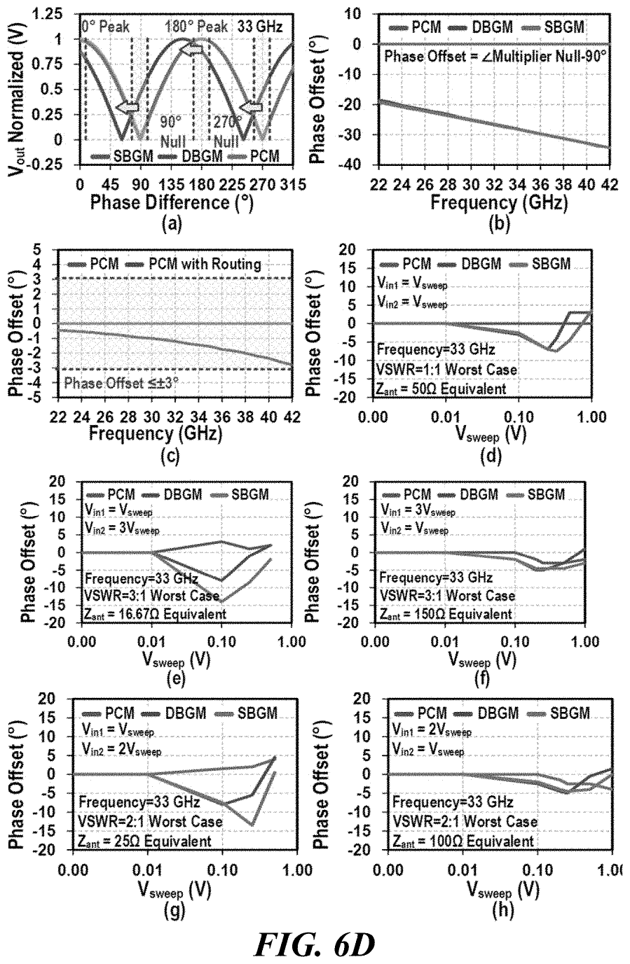

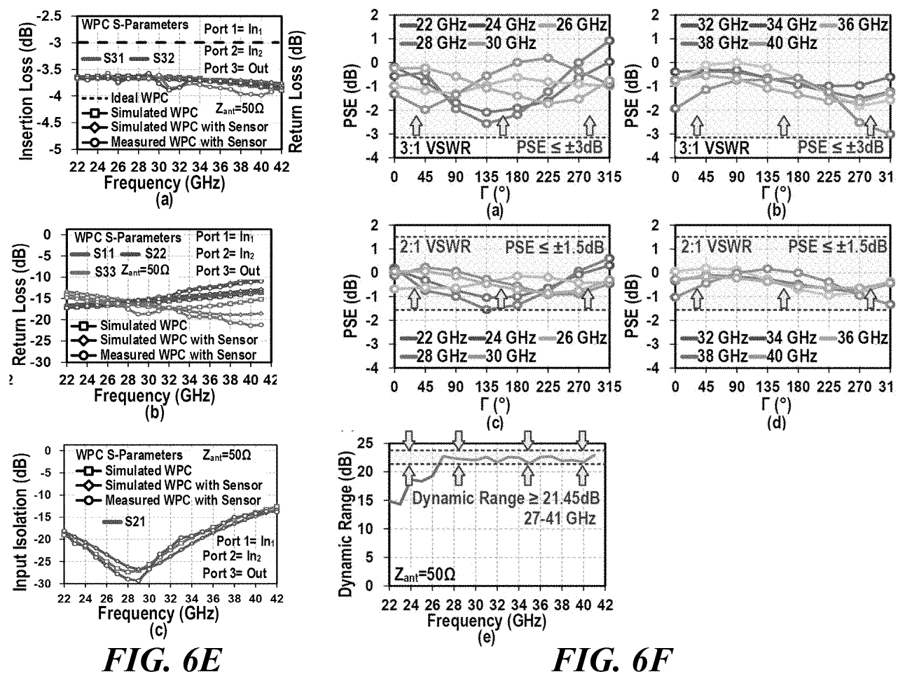

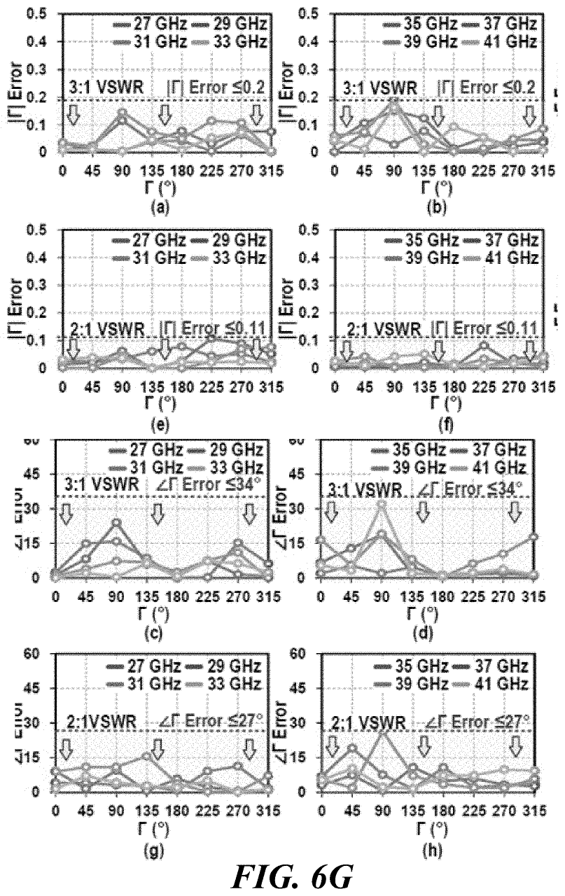

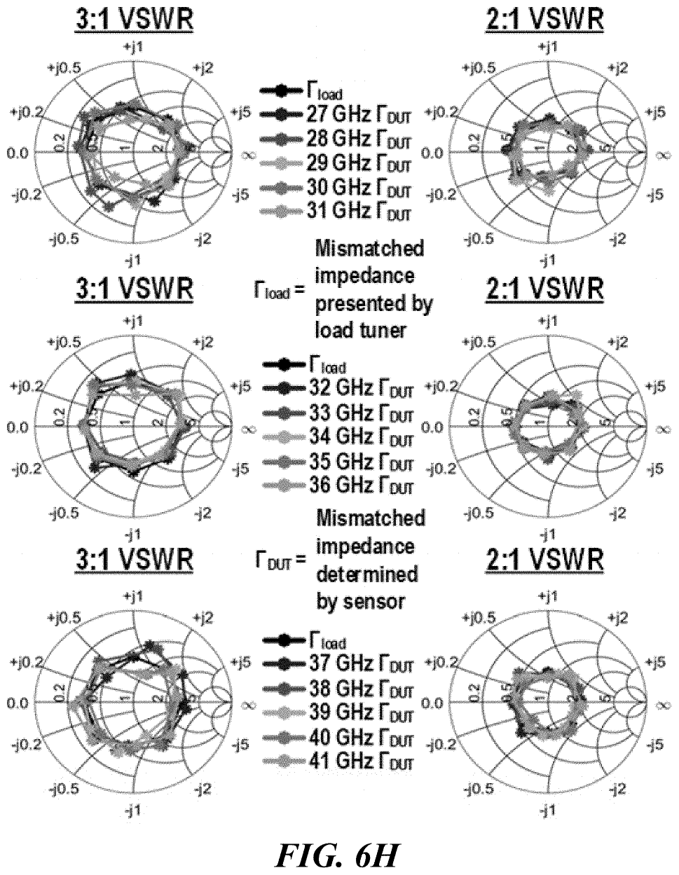

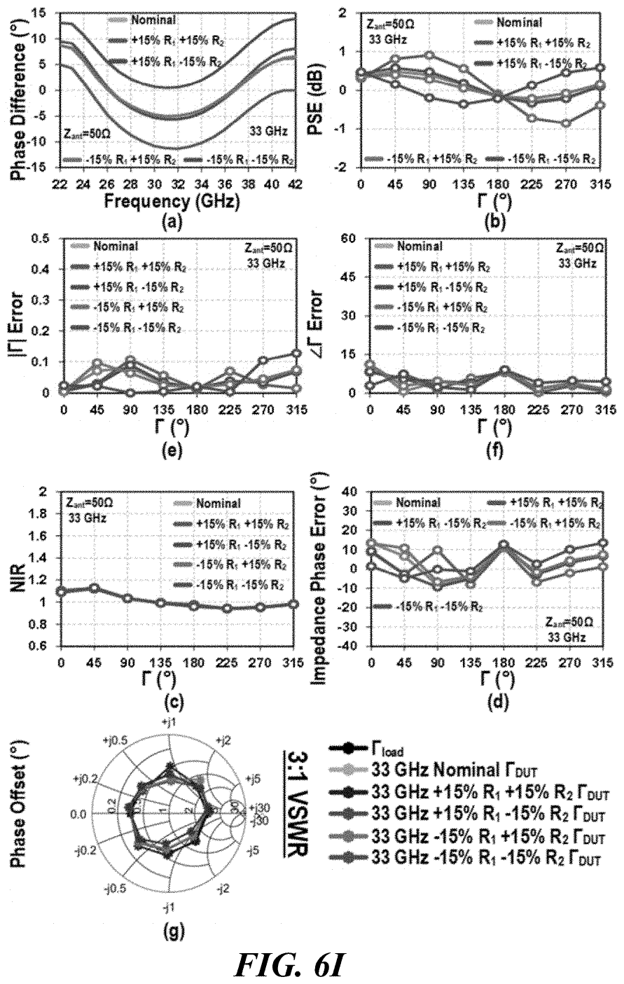

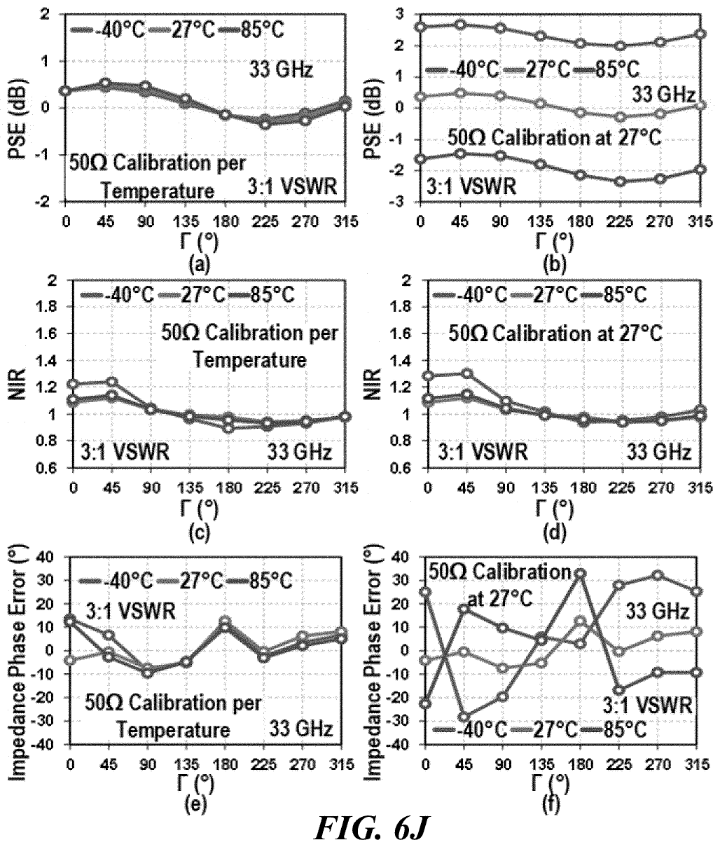

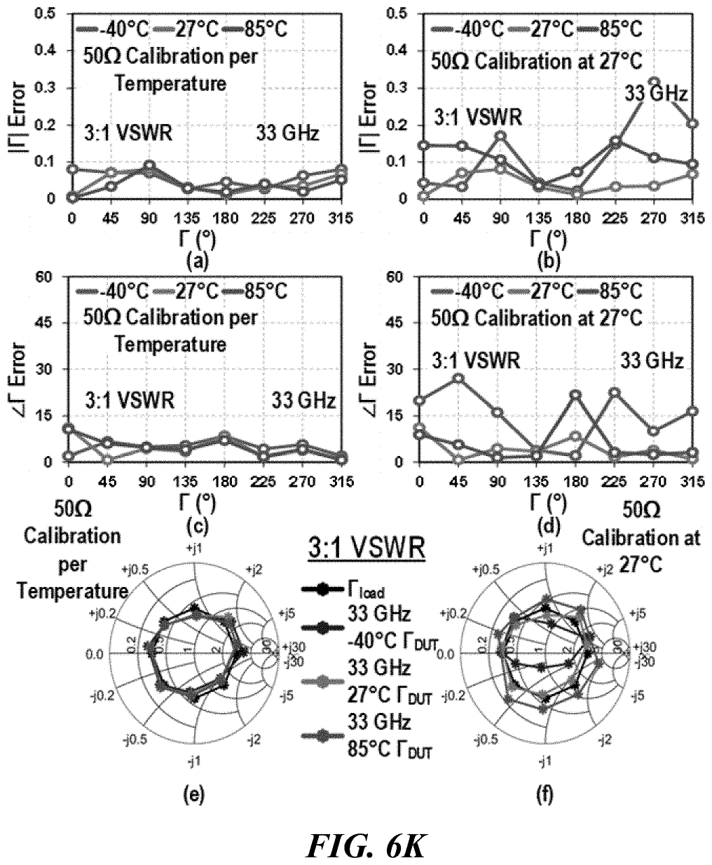

The simulated phase offset of the SBGM, DBGM, and complementary multiplier with/without routing non-idealities are shown in FIG. 6D. Because the phase difference discussed previously may be a small signal phenomenon due to large signal AM/PM, the analog multipliers may experience varying phase offset as a function of output voltage and large signal phase offset due to the asymmetric CS and cascode paths becoming more asymmetric as one transistor falls out of saturation earlier due to one input having a larger voltage swing. FIG. 6D shows the simulated large signal offset for the varying multiplier architectures, where the relative strengths of the two multiplier inputs were swept from having the same amplitude to having an amplitude ratio of 3/2 to simulate the worst-case scenario for 3:1/2:1 VSWR. It was observed that the complementary multiplier could maintain a zero-degree phase offset over power when the inputs are the same strength, as the circuit is perfectly symmetric. Therefore, it was desirable to have the multiplier inputs be of the same magnitude to mitigate large signal phase offsets. Having the input amplitude be the same also maximized the multiplier's dynamic range. When the input amplitudes were asymmetric, it still maintained a much lower large-signal phase offset compared to the SBGM and DBGM. Therefore, the complementary multiplier achieved broadband small signal and large signal phase alignment for accurate VSWR resilient power sensing/phase extraction.

Example Impedance Sensing.

The sensing loops (418′ and 420′) are connected to CS buffers 430 (shown as 430′, 430″) to provide sufficient reverse isolation. The CS buffers (430′, 430″) are also used in conjunction with the following transformer matching component 436 (shown as 436′) to provide broadband voltage gain. The voltage gain is to ensure a sufficient driving strength to terminate the amplitude detectors 438 (shown as 438′ and 438″) over the 22-41 GHz bandwidth. The detectors 438′, 438″ may be implemented as a fully passive amplitude detector approach which ensures sufficient RF-DC gain [45]-[46]. In FIG. 4B, the passive amplitude detector 438′, 438″ is implemented as a three-stage Dickson rectifier (shown as 438″).

Example Die Design.

FIG. 4C shows an example die design 432 for the circuit implementation of the power sensing circuit 402 (shown as 402′) and the impedance sensing circuit 404′. FIG. 4D shows another configuration/design of the power sensing circuit and amplitude detectors to provide impedance sensing.

Example Broadband-Capable Current/Voltage Sensing-Based VSWR Resilient True Power/Impedance Detector #3

As noted above, in another implementation, the exemplary VSWR current/voltage sensing-based sensor/detector may be employed that replaces the balun and symmetric multiplier of the power detector, e.g., as described in relation to FIGS. 4A-4C, with a space-and-power-optimized parallel power detector comprising (i) a differential current/voltage sensor and (ii) a single-ended voltage passive sensing circuit that employs a differential voltage sensing in combination with an error cancellation circuit. With respect to space, rather than employing two sets of differential signals via the above-noted symmetric multiplier, the space-and-power-optimized-differential-current/voltage-and-single-ended-voltage sensing circuit employs a multiplier that (i) operates on a paired differential current and a voltage signal set and (ii) replaced the other differential signal set with a single-end voltage signal. The noted error cancellation circuit generates an intentional offset or error that is employed in the circuit to cancel out undesired error resulting from the loss of accuracy in employing the single-end voltage signal.

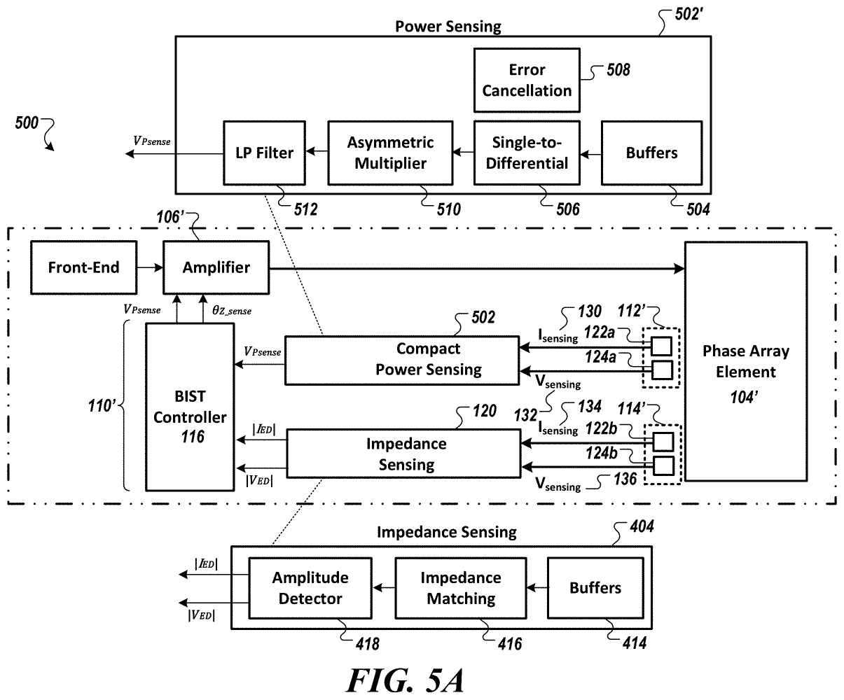

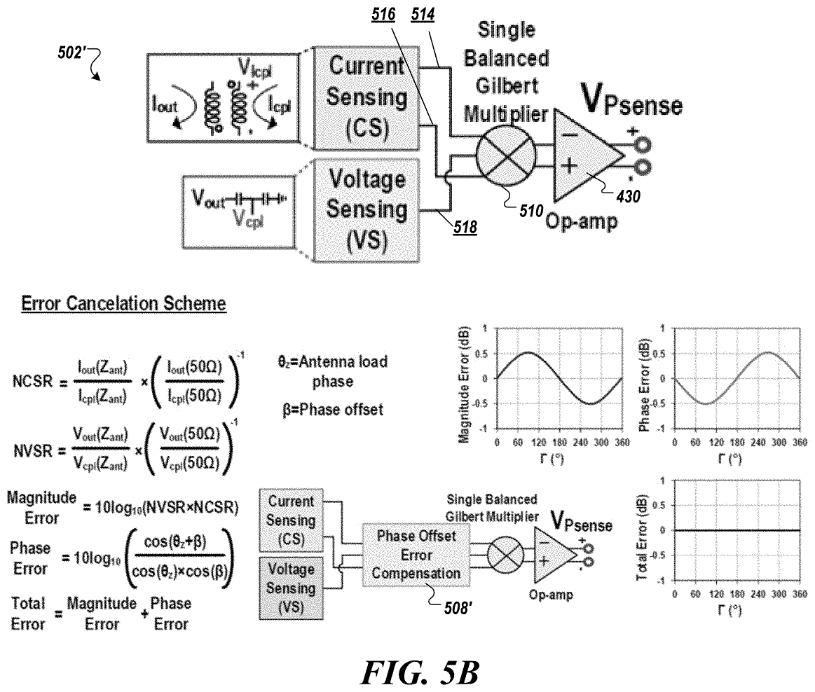

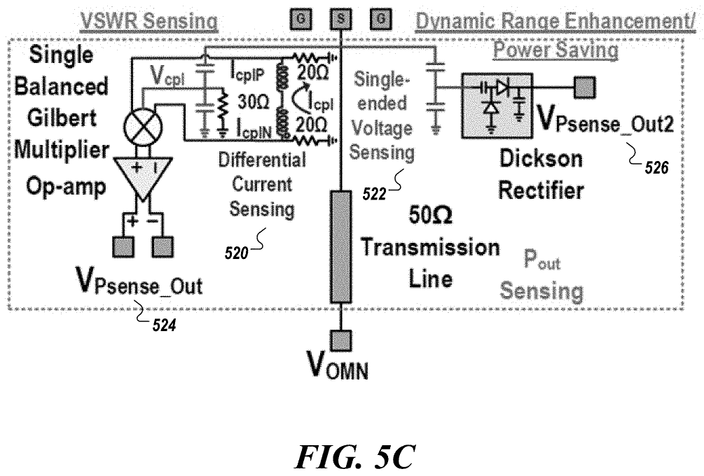

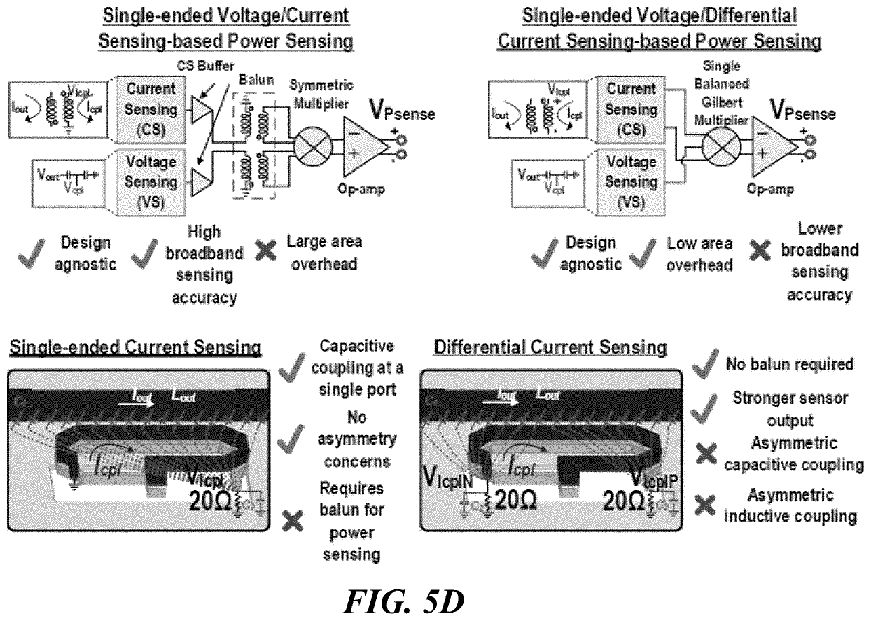

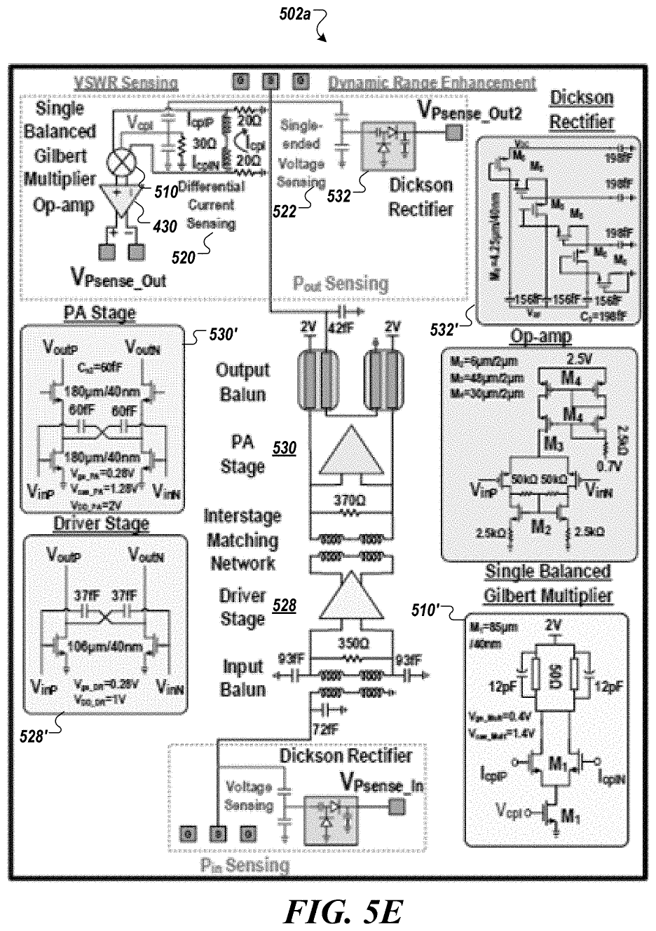

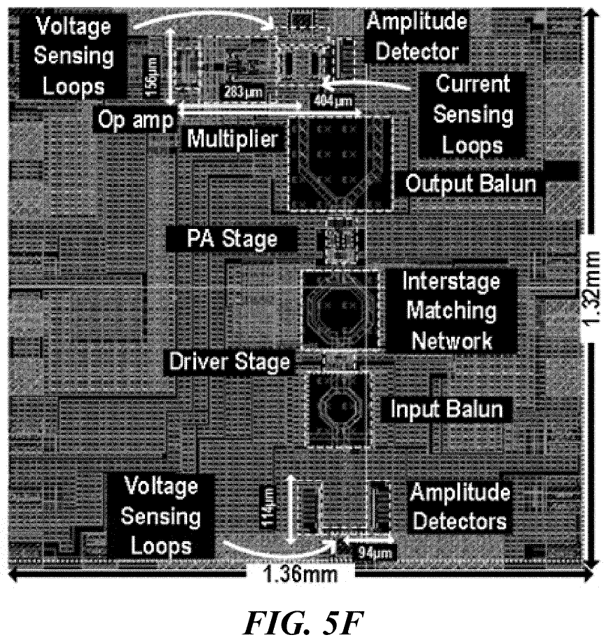

FIG. 5A shows an example circuit or antenna system 500 comprising a compact VSWR power sensing sensor/detector 502 (shown as “Compact Power Sensing” 502) that employs (i) a differential current/voltage sensor and (ii) a single-ended voltage passive sensing circuit that operates in combination with an error cancellation circuit in accordance with an illustrative embodiment. In the example shown in FIG. 5A, the compact VSWR power sensing sensor/detector 502 (shown as 502′) includes a set of buffers 504, a single-to-differential converter 506, an error cancellation circuit 508, an asymmetric analog multiplier 510, and a low-pass filter 512.

Rather than employing two pairs of differential input, e.g., as shown in FIG. 4B or 4C, the compact VSWR power sensing sensor/detector 502 employs an asymmetric analog multiplier 510 that uses a single-ended voltage passive sensing circuit to generate a differential signal via the single-to-differential converters 506. That reduces the size of the sensing structure and associated front-end circuitries. By employing an error cancellation circuit (e.g., active error cancellation circuit) to generate an intentional offset or error, the circuit can cancel out undesired errors resulting from the loss of accuracy using the differential current sensing.

The buffers 504 are connected to the current sensor or sensing structure 122a and voltage sensor or sensing structure 124a to receive the sensed current I_{sensing} 130 and V_{sensing} 132. The buffers are configured to provide reverse isolation capabilities and include compatible with the termination conditions, e.g., described in relation to FIG. 2B.

The low pass filter 512 is connected to the output of the analog multiplier 510, e.g., to remove any 2^{nd} harmonics generated from the multiplication. The output of the low pass filter 512 may be provided to the BIST controller (e.g., 116) or to an output matching network (OMN) or other impedance matching circuitries, e.g., of a reconfigurable power amplifier or front-end component.

FIG. 5B shows an example implementation of the compact VSWR power sensing sensor/detector 502 in accordance with an illustrative embodiment. The asymmetric analog multiplier 510 is shown implemented using a single balanced Gilbert Multiplier (SBGM) configured to take one differential current and voltage pair signals (514 and 516) and a single sensed voltage signal 518.

Error Cancelation Operation.

The use of the SBGM and differential current sensing offers large power detector area savings due to the ability to remove the previously-used on-chip baluns at a trade-off of accuracy due to the imperfections of differential current sensing. To compensate for the trade-off in current accuracy, the compact VSWR power sensing sensor/detector 502 employs the error cancelation circuit 508 (shown as 508′)

In the example shown in FIG. 5B, the error cancelation circuit 508′ is configured to add an intentional phase error between the two sensing loops to generate an additional load-dependent error, Phase Error. The phase error with an inverse error over the load mismatch profile can then be used to cancel the Magnitude Error and achieve an overall accurate power detector over VSWR within a compact form factor.

FIG. 5C shows an example implementation of the compact VSWR power sensing sensor/detector 502. In the example shown in FIG. 5C, the compact VSWR power sensing sensor/detector 502 includes two parallel power detectors that include (i) a current/voltage sensing-based detector (520) and (ii) a voltage sensing-based detector (522).

For the sensed current and voltage-based power detector, the sensed signals I_{cpl} and V_{cpl} are proportional to the output voltage and current Iₒᵤₜ and Vₒᵤₜ as previously discussed in relation to Equations 3-4, reproduced as Equations 41 and 42:

V_{cpl}=k₁Vₒᵤₜ (Eq. 41)

I_{cpl}=k₂Iₒᵤₜ, (Eq. 42)

where k1 and k2 are proportionality factors. The sensing loops are aligned such that their phase difference is the same as the output voltage and current. Therefore, the power detector output VPsense_Out, which includes the multiplication of the sensed current and voltage, can be defined as Equation 43 (previously shown as Equation 1) and Equation 44.

V_{Psense_Out}=0.5k₁k₂×|Vₒᵤₜ∥Iₒᵤₜ|cos(θ_{Z}), (Eq. 43)

V_{Psense_Out}=k₃×Pₒᵤₜ, (Eq. 44)

where k₃ is a proportionality factor. Therefore, the power detector output can employ a single proportionality factor PF_{VSWR} for a one-to-one correspondence with the true power delivered to the antenna load. To obtain this proportionality factor, a one-time calibration may be performed at 50Ω and comparing the average of the instantaneous ratio of the power detector output and true output power per Equation 45 (previously shown as Equation 8).

$$PF = avg ( \frac{{V}_{Psense \_ out}}{{P}_{out}} ) , \qquad ( Eq . 45 )$$

For the voltage-only-based power detector, the output voltage can be sensed and fed to a square law-based amplitude detector. The amplitude detector output V_{ED} can be determined per Equation 46.

$${V}_{Psense \_ Out 2} = {k}_{4} \times \frac{\vert {Z}_{ant} \vert}{cos ( {θ}_{z} )} \times {P}_{out} , \qquad ( Eq . 46 )$$

where k₄ is a proportionality factor. Even with a one-time proportionality factor at 50Ω, the amplitude detector output still has a dependence on the antenna load for one-to-one correspondence. However, to address this feature, the detector (e.g., 502) can compare the current/voltage sensing-based output 524 and voltage sensing-only output 526 with respect to one another. The ratio of the two outputs can be defined per Equation 47.

$$\frac{{V}_{Psense \_ Out 2}}{{V}_{Psense \_ Out}} = \frac{{k}_{4} \times \frac{\vert {Z}_{ant} \vert}{cos ( {θ}_{z} )} \times {P}_{out}}{{k}_{3} \times {P}_{out}} = \frac{{k}_{4}}{{k}_{3}} \times \frac{\vert {Z}_{ant} \vert}{cos ( {θ}_{z} )} \qquad ( Eq . 47 )$$

From Equation 47, it can be deduced that the ratio of the voltage sensing-only-based detector (e.g., 526) and current/voltage sensing-based power detector (e.g., 524) changes by the same factor that the output power changes with respect to the voltage only-sensing power detector. This is expected from Equation 44. The result in Equation 47 can be used to derive the following relationships in Equations 48-51 where k₅ is a proportionality factor.

$$\frac{\vert {Z}_{ant} \vert}{cos ( {θ}_{z} )} = \frac{{k}_{3}}{{k}_{4}} \times \frac{{V}_{Psense \_ Out 2}}{{V}_{Psense \_ Out}} \qquad ( Eq . 48 )$$

$${V}_{Psense \_ Out 2} = {k}_{4} \times \frac{{k}_{3}}{{k}_{4}} \times \frac{{V}_{Psense \_ Out 2}}{{V}_{Psense \_ Out}} \times {P}_{out} = {k}_{3} \times \frac{{V}_{Psense \_ Out 2}}{{V}_{Psense \_ Out}} \times {P}_{out} \qquad ( Eq . 49 )$$

$${V}_{Psense \_ Out 2} = {k}_{3} \times \frac{{V}_{Psense \_ Out 2} ( 50 Ω )}{{V}_{Psense \_ Out} ( 50 Ω )} \times \frac{{V}_{Psense \_ Out 2} ( {Z}_{ant} )}{{V}_{Psense \_ Out} ( {Z}_{ant} )} \times {P}_{out} . \qquad ( Eq . 50 )$$

$${V}_{Psense \_ Out 2} = {k}_{5} \times \frac{{V}_{Psense \_ Out 2} ( {Z}_{ant} )}{{V}_{Psense \_ Out} ( {Z}_{ant} )} \times {P}_{out} . \qquad ( Eq . 51 )$$

Comparison of Single-Ended Voltage/Differential Current Sensing Power Sensing to Paired Differential Voltage/Current Sensing

Fig. DC shows a comparison between the power sensing scheme used in FIGS. 4B and 4C for a paired differential voltage/current sensing and that used for FIGS. 5A and 5B. In FIGS. 4B and 4C, single-ended current/voltage sensing was followed by buffers for reverse isolation and baluns for single-ended to differential conversion. The weak coupling of the two sensing paths ensures that their scheme is nonintrusive to the PA output matching network (OMN). The termination conditions ensure the desired coupling mechanism is dominant per loop for high-performance power sensing over a broadband frequency spectrum. However, the baluns (e.g., 426) used to support the complementary analog multiplier are bulky and require sufficient spacing from the OMN to minimize undesired power coupling. This can place a large area overhead on the overall PA front-end, making it a design constraint to fit within the λ/2 form-factor for phased array per element integration.

To mitigate this, in FIGS. 5B, 5C, the Single Balanced Gilbert Multiplier (SBGM) was employed, and error compensation was employed such that only one differential input was employed, removing one balun network from the design. By removing the on-chip baluns and replacing them with the exemplary differential current/voltage sensor and a single-ended voltage passive sensing circuit, it was observed that a 10× area reduction was achieved.

Small resistive terminations of 20Ω may be used on both ports of the sense coil to ensure that inductive coupling is dominant. Since the same current must flow through the loop, the port voltages generated are out of phase, generating a differential current to voltage signal. This mitigates any need for baluns in the design.

As the inductive coupling strength is not modified, the nonintrusive behavior is maintained. Since out-of-phase-current-to-voltage conversion was achieved for the same current sensing ratio, the equivalent sensing loop output voltage was doubled at a trade-off of current sensing accuracy.

From Equation 50, it can be observed that comparing the two power detector outputs and updating the amplitude detector's proportionality factor based on their relative ratio when the antenna load is mismatched would allow for VSWR resilient power tracking when operating with an appropriate calibration operation.

In some embodiments, a 50Ω calibration may be performed that compares the amplitude detector output to the true output power to generate a proportionality factor-k₅ for one-to-one correspondence for power tracking. To obtain

$$\frac{{V}_{Psense \_ Out 2}}{{V}_{Psense \_ Out}}$$

in a measurement environment where noise and compression effects are present, the average of the instantaneous ratio can be determined per Equation 52.

$$PF = avg ( \frac{{V}_{Psense \_ Out 2}}{{V}_{Psense \_ Out}} ) , \qquad ( Eq . 52 )$$

From this calibration operation, the passive voltage-only sensing-based detector can be used for VSWR resilient power tracking with no power consumption and could be periodically updated via the proportionality factor with respect to the amplitude detector and analog power detector. The calibration and update operation can provide dynamic range enhancement over VSWR.

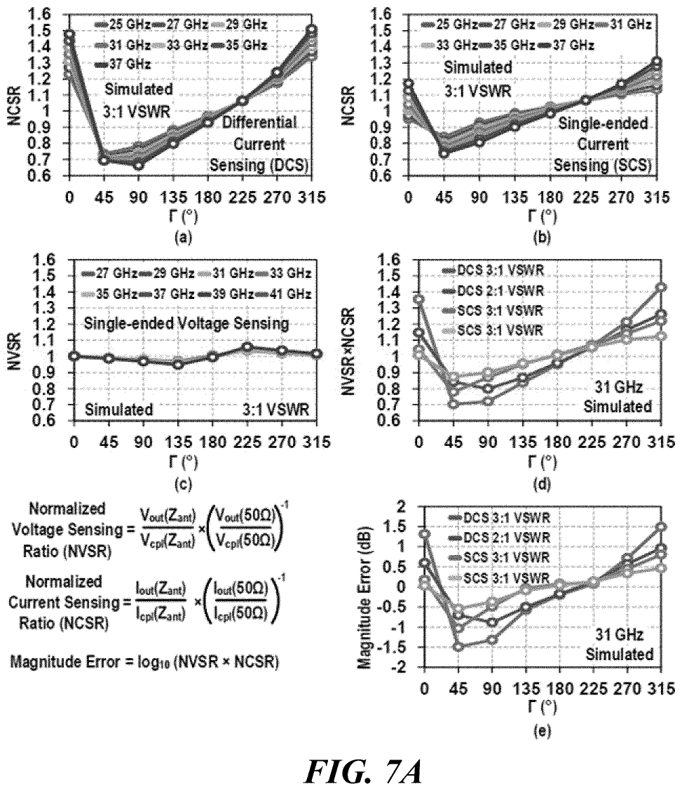

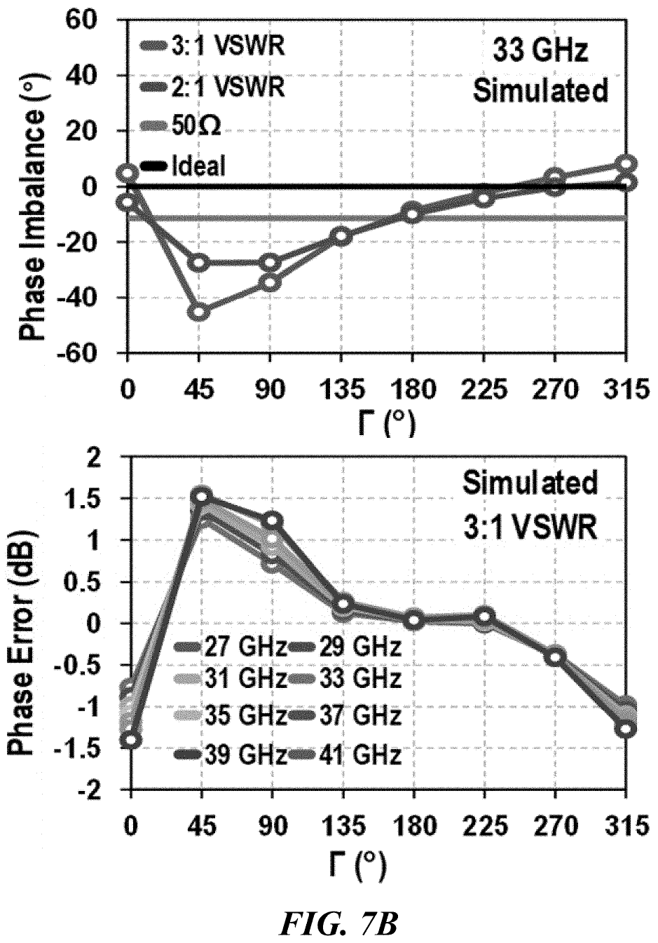

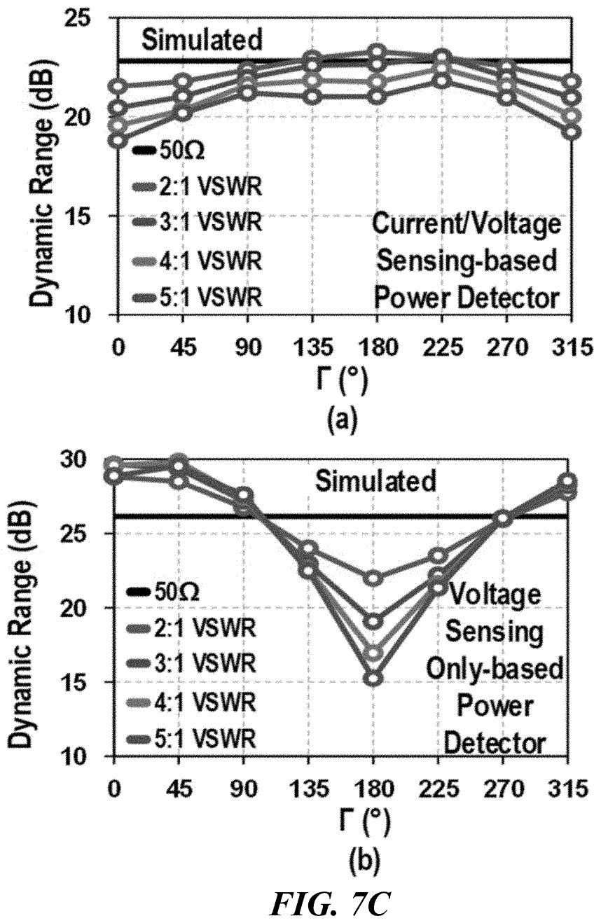

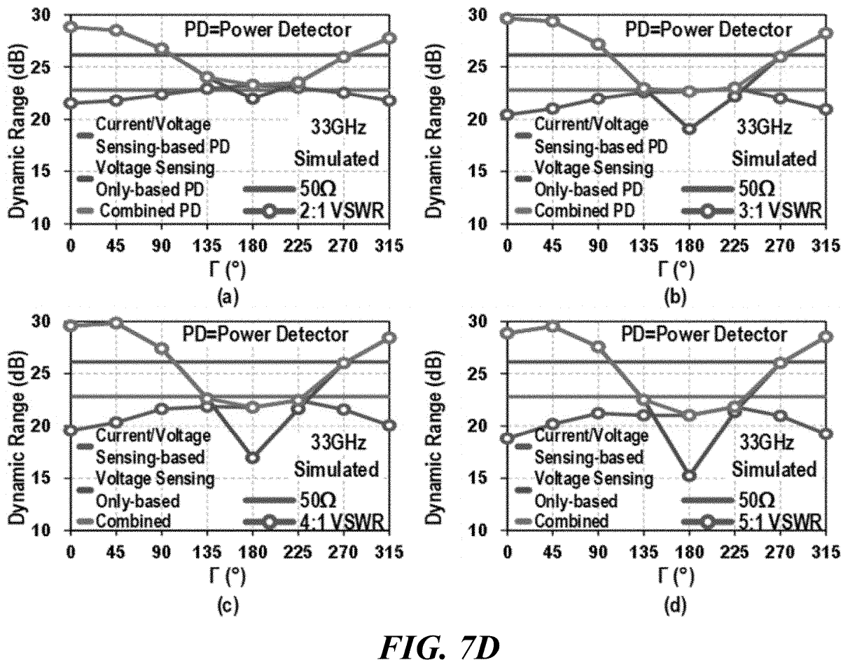

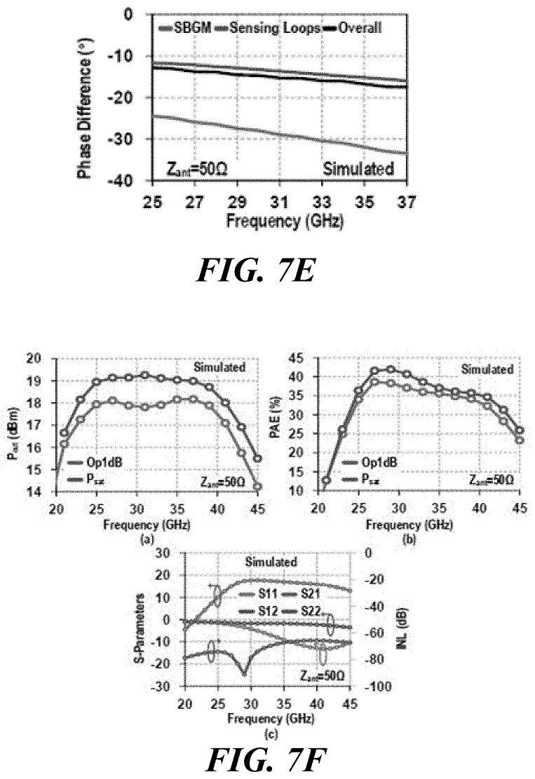

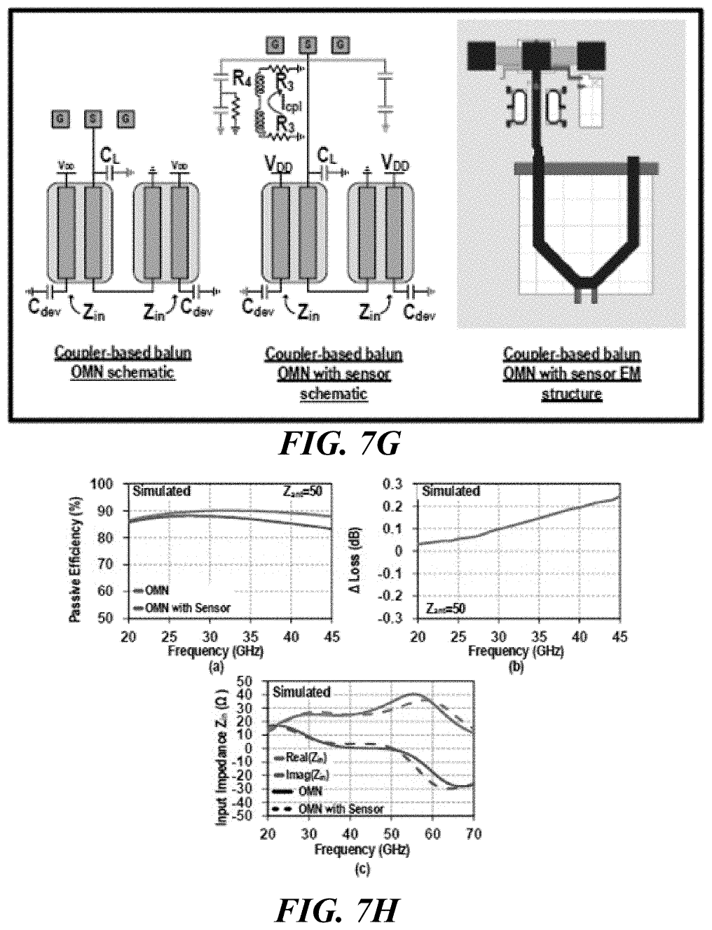

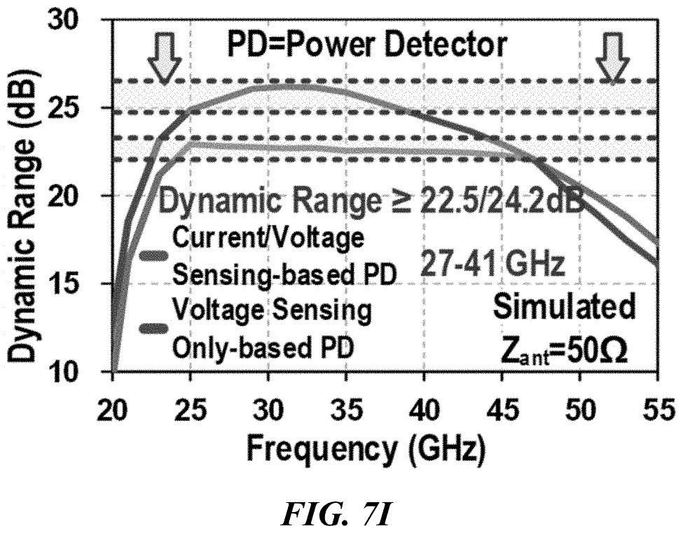

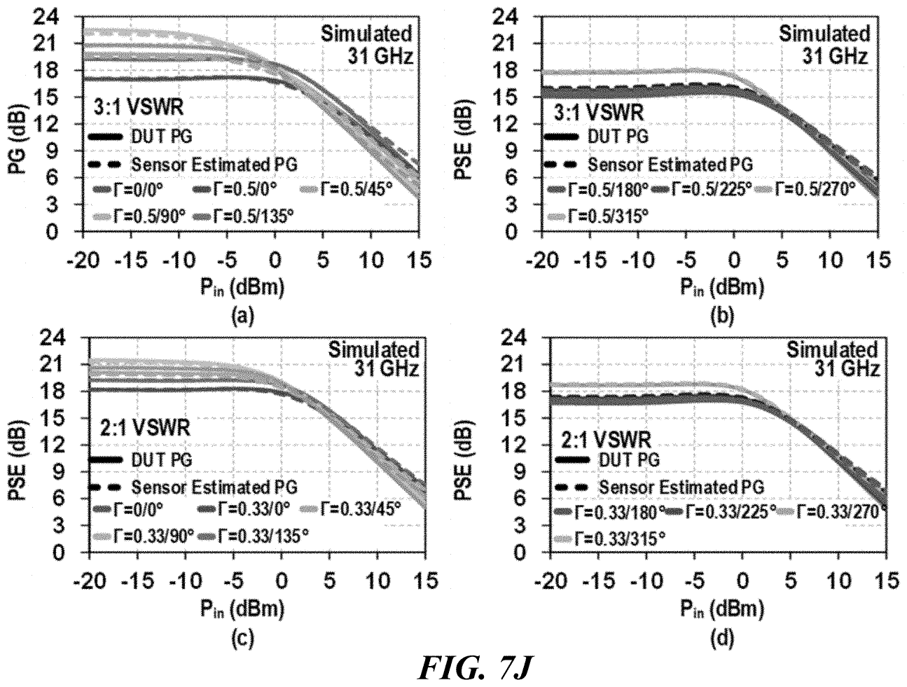

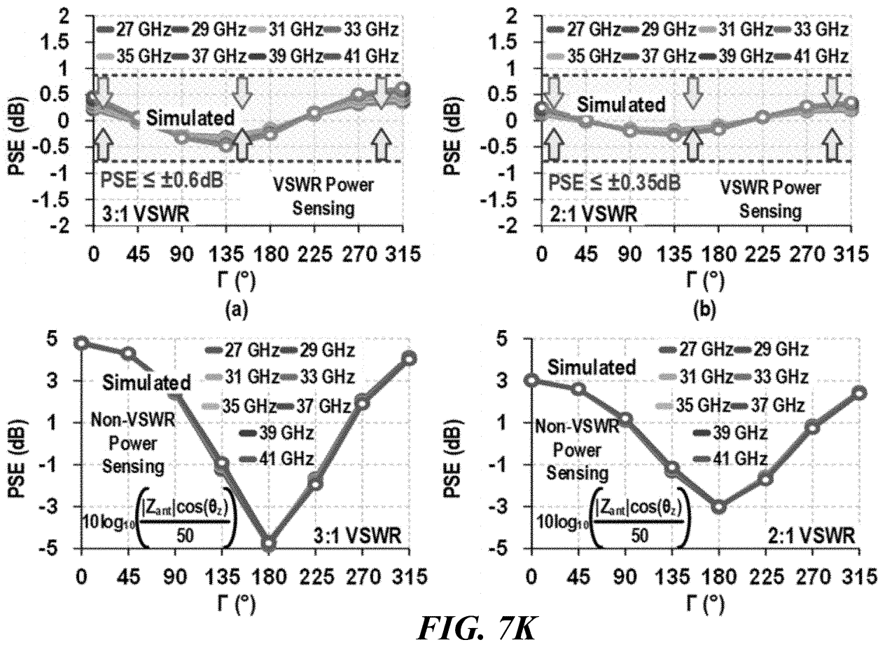

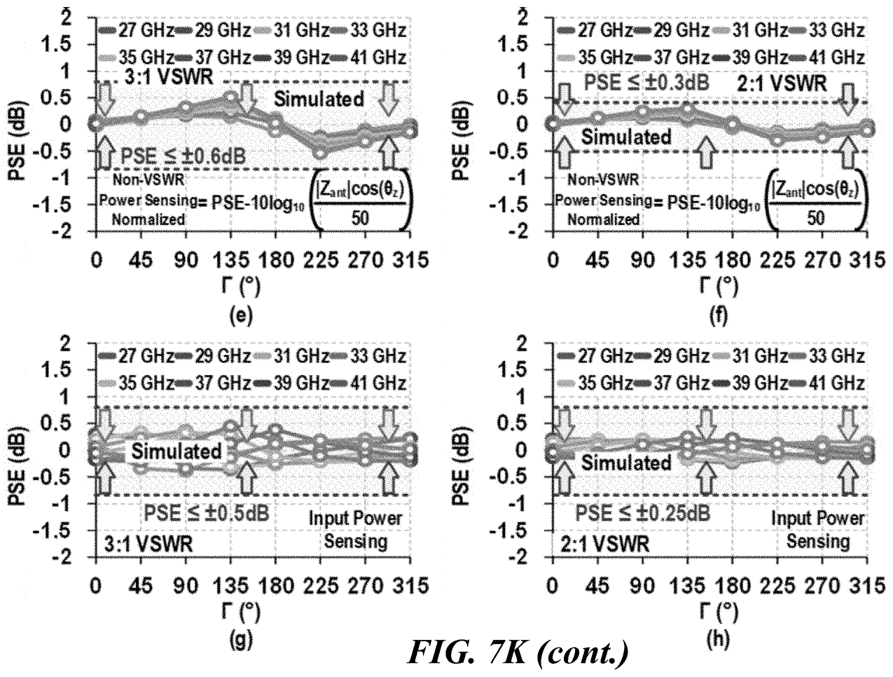

As shown in FIG. 7C, the passive power detector has a larger nominal dynamic range but has a degraded dynamic range for low-impedance loads. In contrast, the VSWR resilient power detector has a relatively flat dynamic range over VSWR but a lower nominal dynamic range. By using the passive power detector for moderate and high impedance loads while using the VSWR resilient power detector for low impedance loads, a larger dynamic range over VSWR can be maintained. The corresponding simulation results up to 5:1 VSWR are shown in FIG. 7D.

In FIG. 7D, the following trends may be observed. The nominal 50Ω dynamic range of the voltage-sensing-only-based power detector is higher. In addition, this passive power detector's dynamic range is greater than the current/voltage sensing-based power detector across all of LF except for between 135° and 225°, where the antenna load is low impedance. Depending on the |Γ|, the analog multiplier-based power detector's dynamic range is higher and should be used instead. This leads to a flatter and more resilient dynamic range over VSWR. By utilizing the best dynamic range sensor response per VSWR point, the detector (e.g., 502) can maintain a dynamic range >21 dB/21.7 dB/22.6 dB/23.3 dB for 5:1/4:1/3:1/2:1 VSWR compared to the original dynamic range >15.2 dB/16.9 dB/19.1 dB/21.9 dB for 5:1/4:1/3:1/2:1 and with just using the passive rectifier power detector output.

To this end, the use of two parallel power detectors can offer major power savings and dynamic range resilience. An additional calibration step is required between the two power detector outputs to support this. However, as both outputs are DC and specific to the sensor, it only adds additional latency and no additional measurement setup to perform this calibration.

Example Circuit Implementation.

FIG. 5E shows an example circuit implementation 502 (shown as 502a) of the system architecture of the compact VSWR power sensing sensor/detector 502 of FIG. 5C as a power gain estimator. In the example shown in FIG. 5E, the compact VSWR power sensing sensor/detector 502a includes a two-stage differential PA (shown as Driver Stage 528 and PA Stage 530) with input power and output power sensing for power gain curve generation. The output power sensing circuit includes two paths to ensure VSWR resilient power tracking and dynamic range performance, as previously described in relation to FIG. 5C, including the differential current sensing circuit 520 and the single-ended voltage sensing circuit 522, for compact VSWR resilient power tracking. The compact VSWR power sensing sensor/detector 502a includes resistive terminations of 20Ω and 30Ω, respectively, in conjunction with the inherent phase offset of the single balanced Gilbert multiplier (SBGM) to generate the required phase offset over the frequency profile to cancel the increased magnitude error due to differential current sensing [60]. The voltage sensing circuit employs capacitive coupling connected to a Dickson rectifier-based passive amplitude detector 532 for low power and high dynamic range power detection. An example of the Dickson rectifier-based passive amplitude detector 532 is shown as 532′. The same passive power detector scheme is used for the input power sensing.

PA Circuit/Testbed.

The PA circuit/testbed includes a 2-stage amplifier utilizing a common source (CS) driver stage 528 (shown as 528′) and cascode PA stage 530 (shown as 530′). Capacitive neutralization is used, in this example, to enhance gain, stability, and reverse isolation over a broadband frequency range. Since the two-stage PA testbed provides sufficient reverse isolation, the input impedance and hence input power detector is unaffected by antenna VSWR. Therefore, the input power sensing scheme includes only the voltage sensing loop and a Dickson rectifier-based amplitude detector 532. Transformer-based and coupled line-based networks are used to provide broadband input/inter-stage/output matching.

Dickson Rectifier.

The three-stage Dickson rectifier 532′ is employed in the example as the amplitude detector. The rectifier has high linearity, has a fully passive implementation, and has a controllable conversion gain based on the number of stages [68-69]. As the Dickson rectifier is a passive rectifier, there is no power or pad overhead, supporting an extremely compact form factor. The three-stage Dickson rectifier may be used for both the input power detection and voltage sensing only-based output power detection.

Analog Multiplier.

The analog multiplier 510 includes a single-balanced Gilbert multiplier (SBGM) cell (shown as 510′). As only a single differential input is employed, which is provided by the differential current sensing scheme, the use of the SBGM architecture mitigates any need for baluns in the sensor core, enabling major area savings. To support the error cancelation scheme over frequency, a linear phase offset over frequency may be applied to the analog multiplier 510 to accommodate for the increasing magnitude error over frequency. The phase alignment network can provide a relatively flat phase over frequency profile [79]. However, as shown in FIG. 7E, the SCGM can provide a linear input referred to the phase offset as a function of frequency. FIG. 7E shows the simulated phase offset of the SBGM, the sensor loops, and the corresponding net phase offset over frequency. Therefore, the SBGM can be used in the error cancelation scheme over broadband. Lastly, the SGBM is the most compact Gilbert multiplier cell-based analog multiplier, so it provides the greatest amount of active area savings.

Op-Amp.

The operational amplifier 430 includes a single-stage differential pair with PMOS inputs. PMOS inputs can minimize noise and can accommodate the multiplier DC output common mode. A single-stage amplifier may be implemented to minimize power, minimize noise, and ensure loop stability. The op-amp can also enhance the output signal strength and provide sufficient filtering of the multiplier's harmonic content.

Simulation Results.

FIG. 5F shows a schematic diagram of a chip micrograph of a prototyped compact VSWR power sensing sensor/detector 502 of FIG. 5E. The prototyped VSWR power sensing sensor/detector 502 is implemented in a 45 nm CMOS SOI process. The input/output sensing occupies a compact sensor core area of chip area of 0.011 mm²/0.055 mm², respectively, while the overall chip occupies an area of 1.8 mm².

Experimental Results and Additional Examples for Voltage/Current-based Sensing

A study was conducted that evaluated VSWR power/impedance sensing via voltage and current sensing and other schemes. The developed sensor/detector supports the accurate broadband operation and can be added to any power amplifier architecture (or other circuitries as described herein) as the coupling mechanisms are weak. The study developed a 22-41 GHz sensor prototype that demonstrated a PSE within ±3.4 dB for 3:1 VSWR and ±1.5 dB for 2:1 VSWR and a dynamic range >21.46 dB over 27-41 GHz. The prototype also demonstrated |Γ| and LF errors of ≤0.2/34° for 3:1 VSWR and ≤0.11/27° for 2:1 VSWR over 27-41 GHz. To the inventor's knowledge, this study was the first work to develop a broadband demonstration of mm-Wave joint power/impedance sensing up to 3:1 VSWR, covering the entire Ka-band and the 5G FR2 24/28/39 GHz bands.

FIG. 6A shows an electromagnetic diagram of the power and impedance sensing scheme for the exemplary current/voltage sensing-based architecture.

Wilkinson Power Combiner Test Setup.

The study employed a WPC OMN measurement test setup to characterize the performance and intrusiveness of the exemplary VSWR power/impedance sensor architecture. The study evaluated the change in the return loss as the sensor's impact on the OMN impedance transformation ratio and bandwidth. By looking at the insertion loss, the study determined the amount of additional loss the exemplary VSWR power/impedance sensor architecture incurred. The study employed a straightforward S-Parameter measurement to quantify the intrusiveness of the current/voltage sensing loop architecture. FIG. 6E shows the simulated return loss and insertion loss of the WPC OMN with/without the current/voltage sensing loops.

From FIG. 6E, it can be observed that the WPC demonstrated an insertion loss between 3.64-3.89 dB over 22-41 GHz compared to the ideal 3 dB loss, demonstrating a broadband low loss. In addition, the study observed the return loss was <−13 dB for all three ports across 22-41 GHz, demonstrating its broadband input/output matching. The minimal difference between the simulated results with/without the exemplary VSWR power/impedance sensing loops was verified for the sensor's minimal impact on the WPC's insertion loss (Δ loss<0.06 dB) and matching due to its low-coupling nature. The maximum 0.89 loss compared to the ideal 3 dB was employed as the loss of the WPC OMN. The study observed a maximum 0.06 dB additional loss attributable to the introduction of the exemplary VSWR power/impedance sensing circuit. These results showed that the VSWR power/impedance sensing via voltage and current sensor/detector was nonintrusive and power-amplifier agnostic.

Analog Multiplication Simulation.

The study conducted a number of simulations in the development of the VSWR power/impedance sensing via voltage and current sensing schemes. In the development of the analog multiplier, e.g., the complementary multiplier (PCM) described in relation to FIG. 4B, the study simulated phase offset of the single-balanced Gilbert multiplier (SBGM), double-balanced Gilbert multiplier (DBGM), and complementary multiplier with/without routing non-idealities. Results are shown in FIG. 6D.

In FIG. 6D, it was observed that ideally, the complementary multiplier could maintain a zero-degree phase offset across frequency and has a worst-case 3° phase offset across the 22-41 GHz bandwidth when routing non-idealities are taken into account compared to the SBGM and DBGM topologies. To extract this phase offset, the voltage amplitude of the two inputs to be multiplied was fixed, and the phase difference between the two inputs was then swept. In FIG. 6D, the phase of the peak and nulls of the output were compared to the ideal 0°/180° and 90°/270° to evaluate the phase offset of the multiplier block.

Measurement Setup.

Several prototypes of the exemplary current/voltage sensing-based sensor were implemented in a 45 nm CMOS SOI process, including that shown and described in relation to FIGS. 4A, 4B, and 4C.

FIG. 6B shows a measurement setup for the GSG probe-based sensor CW characterization and for a Maury MT985AL load tuner impedance/loss characterization. The chip occupies a chip area of 1.92 mm2 and a sensor core area of 0.8 mm2. The Maury MT985AL impedance tuner was used to provide the VSWR mismatches for proper characterization of the prototyped VSWR current/voltage sensing sensor over 22-41 GHz. The sensor measurement setup and cable/probe characterization procedure are shown in FIG. 6B. The evaluation performed four narrowband tuner characterizations to evaluate the full 22-41 GHz broadband tuner characterization.

When performing the CW power sweeps to characterize the small and large signal behavior of the exemplary VSWR current/voltage sensing-based sensor, the study employed an N1914 power sensor to capture the output power while an Agilent 34411A multimeter was employed to capture the differential DC power sensing output VPsense. During the same power sweep, Agilent 34465 multimeters were employed to capture outputs of the two Dickson rectifiers for impedance sensing VED, IED. The study used the same data post-processing scheme as described in [41].

FIG. 6C shows the chip DUT DC power breakdown in a pie graph. Because the amplitude detector was implemented in a purely passive manner, the three active components of the sensor DUT were the common source (CS) buffers, the complementary analog multiplier, and the operational amplifier. The two heavy power-usage components were observed to be the buffers and analog multiplier, consuming 19.8 mW (45%) and 24 mW (54%), respectively. Because the VSWR scenarios would occur on the μs level and the modulated signals would occur on the ns-ps level, it was contemplated that the BiST circuitry could be heavily duty-cycled to enable major power savings for real-world deployment, as described herein.

Power/Impedance Sensing.

The study characterized all the losses of the cables, attenuators, connectors, and probes as a function of load over frequency for accurate VSWR power sensing. The study performed a probe-based Thru measurement with an input isolator to characterize the tuner loss variation as a function of VSWR. The Power Sensing Error (PSE) was the ratio of 10 log₁₀(PFVSWR/PF50Ω). The study used a close-to-zero PSE to verify the accuracy of the power sensor over VSWR, such that the sensor can be used for unknown VSWR loads after performing its one-time 50Ω calibration. To simulate the 3:1 and 2:1 VSWR circles, the study fixed the magnitude of the gamma presented by the load tuner, |Γload|=0.5 and |Γload|=0.333, while the phase of the gamma was swept 360 degrees, ∠Γload=0:45:360°.

FIG. 6F shows the measured power sensing results for both 50Ω and VSWR. In particular, FIG. 6F shows power sensing measurement results for (a)-(b) 3:1 VSWR, (c)-(d) 2:1 VSWR, and 50Ω. At 34 GHz, the measured PSE was ≤±1 dB for VSWR=3:1 and ±0.5 dB for 2:1 VSWR. The power sensing error decreased as a function of mismatch, demonstrating the exemplary VSWR power/impedance sensor's monotonicity. Over the 22-41 GHz bandwidth, the measured PSE was ±3.4 dB for 3:1 VSWR and ±1.5 dB for 2:1 VSWR. This demonstrated the reliable VSWR resilience over broadband. In addition, the study demonstrated a maximum 50Ω dynamic range of 22.89 dB at 42 GHz and a dynamic range >21.46 dB over 27-41 GHz. This further verified the broadband power sensing performance of the exemplary VSWR power/impedance sensor.

The study extracted the impedance in polar form using both the amplitude detector outputs and power sensing output. After extracting this, the effect of the chip's GSG pad capacitance was de-embedded to place the VSWR load reference plane at the end of the output signal trace. The study defined the impedance sensing magnitude/phase errors as the difference in the magnitude/phase of the reflection coefficient presented by the Maury load tuner, Load, and the reflection coefficient determined by the sensor device under test (DUT), Γ_{DUT}. The definition of these error metrics is shown below:

$${Γ}_{\frac{load}{sense}} = \frac{{Z}_{\frac{load}{sense}} - 50}{{Z}_{\frac{load}{sense}} + 50}$$

$$\vert Γ \vert Error = ‖ {Γ}_{load} \vert - \vert {Γ}_{sense} ‖$$

$$∠Γ Error = {∠Γ}_{load} - {∠Γ}_{sense}$$

FIG. 6G shows the measured impedance sensing magnitude/phase errors, which depicts measured |Γ| and ∠Γ error across the 27-41 GHz bandwidth for (a)-(d) 3:1 VSWR and (e)-(h) 2:1 VSWR.

At 33 GHz, the study demonstrated |Γ|/∠Γ errors of ≤0.072/7.3° for 3:1 VSWR and ≤0.04/7.13° for 2:1 VSWR, while demonstrating |Γ|/∠Γ errors of ≤0.2/34° for 3:1 VSWR and ≤0.11/27° for 2:1 VSWR over the entire 27-41 GHz BW. The impedance sensing magnitude and phase errors decreased as a function of mismatch, demonstrating the VSWR power/impedance sensor's monotonicity.

FIG. 6H shows the Smith chart mappings to graphically illustrate the accuracy of the impedance mapping of the sensor DUT. In particular, FIG. 6H shows the measured Smith chart impedance mapping comparison of Γload compared to ΓDUT over the 27-41 GHz bandwidth for 3:1 VSWR and 2:1 VSWR. In FIG. 6H, the black circle is the VSWR circle presented by the Maury tuner to the sensor DUT, and the other circles are the detected impedance values by the sensor DUT over 27-41 GHz. It can be observed that the sensor DUT maps the mismatched antenna load up to 3:1 VSWR across the 41.2% bandwidth, verifying the VSWR power/impedance sensor's broadband yet accurate detection of complex loads.

Table 1 and Table 2, respectively show a comparison between the state-of-the-art for impedance sensors and power sensors.

TABLE 1

| | | TMTT | SSCC | JSSC | ISSCC |
|---|---|---|---|---|---|
| | This Work | 2022 [32] | 2021 [2]5 | 2014 [26] | 2017 [31] |
| Technology | 45 nm CMOS SOI | 45 nm | 22 nm FDSOI | 0.13 μm CMOS | 40 nm CMOS |
| Detector | Voltage & Current | Quadrature | Complex | Mag & Phase | Mag & Phase |
| Principle | | Coupler | Voltage | Weak Coupling | Hybrid XFM |
| DC Power | 44.32 | 44.5 | 13 | 30 | 0.83 |
| Consumption | | | | | |
| Area(mm²) | 0.8 (Core) | 0.456 (Core) | 0.024 (Core) | 3.52 | 1.21 |
| Center | 33 | 38 | 28 | 1.95 | 2.4 |
| Frequency (GHz) | | | | | |

Impedance Sensing Results

| Impedance | Yes | | | | Yes | Yes | Yes | Yes |
|---|---|---|---|---|---|---|---|---|
| Sensing | | | | | | | | |
| Over VSWR | | | | | | | | |
| Impedance | *27-41 | | | | Single | Single | Single | Single |
| Sensing | | | | | Frequency | Frequency | Frequency | Frequency |
| \|Γ\| Detection | ≤0.5 | | | | ≤0.5 | ≤0.7 | ≤0.7 | ≤0.5 |
| Frequency (GHz) | 28 | 33 | 37 | 39 | 38 | 28 | 1.95 | 2.4 |
| VSWR | 3 | 3 | 3 | 3 | 3 | 3 | 3 | 3 |
| Γ Detection | 0.14 | 0.07 | 0.15 | 0.19 | 0.238 | *0.14 | 0.12 | 0.1 |
| Max Mag Error | | | | | | | | |
| Γ Detection | 19.8° | 7.3° | 18.7° | 19.2° | 28.9° | *33° | — | 18° |
| Max Phase Error | | | | | | | | |

TABLE 2

| | | TMTT | SSCC | JSSC | ISSCC |
|---|---|---|---|---|---|
| | This Work | 2022 [32] | 2021 [2]5 | 2014 [26] | 2017 [31] |
| Technology | 45 nm CMOS SOI | 45 nm | 22 nm FDSOI | 0.13 μm CMOS | 40 nm CMOS |
| Detector | Voltage & Current | Quadrature | Complex | Mag & Phase | Mag & Phase |
| Principle | | Coupler | Voltage | Weak Coupling | Hybrid XFM |
| DC Power | 44.32 | 44.5 | 13 | 30 | 0.83 |
| Consumption | | | | | |
| Area(mm²) | 0.8 (Core) | 0.456 (Core) | 0.024 (Core) | 3.52 | 1.21 |
| Center | 33 | 38 | 28 | 1.95 | 2.4 |
| Frequency (GHz) | | | | | |

Impedance Sensing Results

| Impedance | Yes | | | | Yes | Yes | Yes | Yes |
|---|---|---|---|---|---|---|---|---|
| Sensing | | | | | | | | |
| Over VSWR | | | | | | | | |
| Impedance | *27-41 | | | | Single | Single | Single | Single |
| Sensing | | | | | Frequency | Frequency | Frequency | Frequency |
| \|Γ\| Detection | ≤0.5 | | | | ≤0.5 | ≤0.7 | ≤0.7 | ≤0.5 |
| Frequency (GHz) | 28 | 33 | 37 | 39 | 38 | 28 | 1.95 | 2.4 |
| VSWR | 3 | 3 | 3 | 3 | 3 | 3 | 3 | 3 |
| Γ Detection | 0.14 | 0.07 | 0.15 | 0.19 | 0.238 | *0.14 | 0.12 | 0.1 |
| Max Mag Error | | | | | | | | |
| Γ Detection | 19.5° | 7.3° | 18.7° | 19.2º | 28.9º | *33º | — | 18º |
| Max Phase Error | | | | | | | | |

From Tables 1 and 2, it can be observed that the study demonstrated competitive power and impedance sensing accuracy and range while supporting a direct interface with the single-ended antenna load and agnostic integration with mm-Wave PAs. At the cost of area overhead, this work is also the first to show on-chip VSWR-resilient mm-Wave joint true-power/impedance sensing over 27-41 GHz, covering the entire Ka-band and the 5G FR2 24/28/39 GHz bands.

Additional characterization of the system performance, e.g., in relation to process variation may be found at Munzer, David et al. “Broadband mm-Wave Current/Voltage Sensing-Based VSWR-Resilient True Power/Impedance Sensor Supporting Single-Ended Antenna Interfaces.” IEEE Journal of Solid-State Circuits (2022), which is hereby incorporated by reference herein in its entirety.

A Compact and Broadband VSWR-Resilient Power Gain Estimator

The study also designed and fabricated a compact VSWR-Resilient Power Gain Estimator, e.g., as described in relation to FIGS. 5E and 5F. The study performed an evaluation for the compact VSWR-Resilient Power Gain Estimator.

FIG. 7A shows the simulation results corresponding to the evaluation metrics for both the single-ended and differential current sensing over both frequency and VSWR. Specifically, FIG. 7A shows the NCSR, NVSR, and magnitude error over VSWR and frequency for single-ended and differential current sensing loops used in the current/voltage sensing-based power detector. From FIG. 7A, it can be observed that there is a noticeable increase in current sensing error over VSWR/frequency, which corresponds to at least a ±1 dB increase in error for power sensing accuracy due to the increased magnitude tracking error. The error compensation was introduced to compensate for the reduced power sensing accuracy introduced by the differential current sensing.

While the error cancelation scheme is valid, special considerations were considered to support broadband operation. The phase error was implemented as an inverse function of the magnitude error. As shown in FIG. 7A, because the magnitude error was not fixed over frequency, the error may increase as the capacitive coupling contribution becomes more significant towards the current sensing accuracy and phase balance of the differential output. In addition, FIG. 7A shows the peak phase error is a function of the phase offset. Therefore, the phase offset was selected to increase over frequency to compensate for the magnitude error's frequency dependence. Advantageously, as mentioned in [60′], the SBGM has a varying input-referred phase offset over frequency. Therefore, the SBGM supports broadband error cancelation.

Phase Imbalance Nonidealities.

The error cancelation scheme employs the error introduced by the phase offset to be the inverse of the magnitude error. However, as demonstrated in [79′], the error introduced by phase offset has a sinusoidal dependence on LF for a fixed |Γ| and the simulated magnitude error. In contrast, as shown in FIG. 7A, the phase offset does not have a sinusoidal dependence on ∠Γ for a fixed |Γ|. Therefore, perfect error cancelation cannot be achieved. However, this assumes that both analog multiplier inputs are phase balanced. The sensed voltage is single-ended and hence is guaranteed to be phase balanced. The sensed current, however is not guaranteed due to its differential nature.

The differential voltage of the current sensing loop is meant to be phase-balanced due to the opposite current flow direction through each termination resistance. However, there is an undesired equivalent capacitive coupled voltage from the output transmission line. The coupled voltage from the output transmission line is also at a different point on the transmission line. Under a 50Ω antenna load, there is no reflection and hence no standing wave ratio. Therefore, the voltage contribution should be common mode, and the current sensing loop should be properly phase balanced. However, as load mismatch is applied, the input voltage applied to the capacitive coupling network per current sensing port varies due to the increased standing wave ratio. The asymmetric capacitive coupling will unbalance the current sensing loop and cause a load dependence on the phase imbalance as demonstrated in FIG. 7B. FIG. 7B are graphs depicting (i) a simulated phase imbalance of differential current sensing at 33 GHz (left), and (ii) a simulated phase error over 27-41 GHz including the effects of phase imbalance (right).

FIG. 7B (left) demonstrates that the phase imbalance waveform follows the trend as the magnitude error of the differential current sensing. In accordance with the embodiments described herein, one consideration was to generate a phase error that is inverse not proportional to the magnitude error for differential current sensing. However, it is noted from [79′] that a negative phase offset corresponds to a positive power-sensing error. Therefore, the phase imbalance response does cause an inverse error over VSWR due to phase error. To validate this, the corresponding phase error, including the phase imbalance nonidealities, is depicted in FIG. 7B (left).

It can be observed that the phase error is inverse to the magnitude error in FIG. 7B (right), and it increases over frequency to accommodate for the increasing magnitude error. Therefore, the phase imbalance created by the imperfect differential current sensing helps accommodate for the increased magnitude error if an intentional phase offset is introduced.

FIG. 7C shows graphs depicting a simulated dynamic range over VSWR for (a) current/voltage sensing-based power detectors (left) and (b) voltage sensing-only based power detectors (right). The current/voltage sensing-based power detector scheme's accuracy is resilient to VSWR. Its dynamic range is also resilient as the current and voltage have inverse trends over impedance variation, causing the net input power presented to the analog multiplier to be relatively flat over VSWR (FIG. 7C, subpanel (a)). Any reduction in dynamic range can be attributed purely to one input signal becoming too strong and causing a branch in the Gilbert multiplier cell to compress early. However, the current sensing also suffered from a reduced nominal dynamic range due to the high flicker noise contribution of the analog multiplier and op-amp. In addition, the current sensing input was typically weaker, leading to a reduced maximum output signal compared to a voltage sensing-only approach. Lastly, the analog multiplier is relatively power hungry (12 mW) which can degrade the integrated PA's overall system efficiency. This was mitigated by performing duty cycling of the power detector as the VSWR scenarios occur on the μs level when the modulated input/output signals are on the ns-ps level.

In contrast, a passive voltage sensing-based power detector approach, as employed in conjunction with the current/voltage sensing-based power detectors, is more efficient as it consumes no DC power. The passive voltage sensing-based power detector can support a high dynamic range due to the lower number of transistors contributing to flicker noise, a higher convergence gain and hence a larger output signal, and a stronger sensed input signal. Its dynamic range can be mainly determined by the maximum output of the detector, as it only needs to overcome the minimum threshold voltage for rectification and is less sensitive to compression. Therefore, the passive voltage sensing-based power detector can support a high nominal dynamic range, and its dynamic range can be reduced only for low impedance antenna loads where the output voltage is reduced, as shown in FIG. 7C, subpanel (b). However, it is not resilient to VSWR as the required proportionality factor has a dependence on the antenna load, and thus could operate with the current/voltage sensing-based power detectors to offset this deficiency.

PA 50Ω Results.

FIG. 7F shows a 50Ω PA simulation results. In particular, FIG. 7F, subpanel (a) shows simulated CW, and FIG. 7F, subpanels (b)-(c) show S-Parameter results of the integrated PA for the power gain estimator. The PA realizes a 3 dB bandwidth (BW) of 37.5% (27-39 GHz), a peak small signal gain of 17.6 dB at 31 GHz, and an OP1 dB BW of 36.3% (27-39 GHz). The two-stage amplifier achieves a Psat/OP1 dB of 18.99 dBm/18 dBm and peak/OP1 dB PAE of 36.1%/33.8% at 37 GHz.

Sensor Intrusiveness.

Due to the weak coupling of the current/voltage sensing mechanisms, the exemplary voltage/current sensing and resulting impedance/power sensing scheme should have minimal impact on the integrated PA. As the PA's output matching network (OMN) impacts the output power and efficiency and has more embedded sensing loops, we evaluate the sensor network's impact on the OMN to evaluate its intrusiveness. FIG. 7G is a schematic diagram depicting a schematic/layout of the coupled-line-based OMN with and without the integrated current/voltage sensing network. The OMN's performance is evaluated with and without the sensor network as shown in FIG. 7G.

The study evaluated the parameters for additional loss and any modification of the OMN's impedance transformation over frequency. To assess the loss added by the sensor network, the study considered the OMN's passive efficiency/loss with and without the sensing network. To evaluate the sensor's impact on the OMN's impedance transformation, the study compared the complex impedance presented by the OMN for a 50Ω antenna load. FIG. 7H shows the simulated results. In particular, FIG. 7H, subpanel (a) shows passive efficiency, FIG. 7H, subpanel (b) shows a change in loss, and FIG. 7H, subpanel (c) shows impedance presented by the OMN with and without the exemplary VSWR resilient output power detection scheme.

As depicted, the sensor introduced an additional loss of 0.06 dB at the low-frequency band edge and an additional loss of 0.2 dB at the high-frequency band edge. Therefore, the sensor added minimal loss. It was contemplated that the loss could be further reduced for higher power integrated PA testbeds as lower coupling was required from the sensing loops to support the same dynamic range. For impedance transformation, the real and imaginary impedance can be varied by a maximum of ±2Ω and ±3Ω respectively. Therefore, the sensor would minimally impact the impedance transformation of the OMN. The impact on matching can also be further reduced when integrated with a high-power PA as lower coupling is required from the sensing loops.

50Ω Power Detector Results.

To evaluate the exemplary VSWR power gain estimator's nominal and broadband performance, the study first evaluated the estimator under son. FIG. 7I shows the corresponding measurement results, which show the simulated dynamic range of output power detectors over frequency for an antenna load of 50Ω. The study defined the power sensing coefficient (PF) as the average ratio of the power sensor readout voltage and the real RF power delivered to the load to achieve a one-to-one correspondence between the power detector output and true output power. The study then compared the PF with the instantaneous ratio of the power sensor readout voltage and the real RF power delivered to the load on a dB scale (INL). The usable power region within ±0.5 dB INL was defined as the dynamic range. This was done for both the current/voltage sensing-based and voltage sensing-only-based power detectors. Only the output power detector dynamic range was evaluated as it varied substantially over frequency due to variations in the output power, integrated PA power gain, and input matching. In addition, the input power sensor was observed to be resilient to VSWR due to the PA's high reverse isolation, so a lookup table (LUT) approach was used to accommodate for any compression effects as it is consistent over VSWR. The output power detector achieves a 50Ω dynamic range >22.5 dB/24.2 dB for the current/voltage sensing-based output and voltage sensing-based output over 27-41 GHz.

VSWR Power Detector Results.

A Maury MT985AL impedance tuner is used to characterize the exemplary impedance/power sensing sensor over VSWR. All of the cables, attenuators, connectors, and probes losses are characterized across load and frequency to ensure accurate VSWR power sensing. To characterize the input/output power detector performance under VSWR, the input/output PFs for the 50Ω load (PF_{50Ω}) and VSWR load (PF_{VSWR}) were measured. A perfect true power detector should have PF_{50Ω}=PF_{VSWR}. Hence, the Power Sensing Error (PSE) was defined as the ratio of 10 log 10(PF_{VSWR}/PF_{50Ω}). A close-to-zero PSE verifies the accuracy of the power sensor, such that the sensor can be used in practice for unknown VSWR after its one-time 50Ω calibration.

FIG. 7K shows the simulated results of the simulated PSE over 3:1 VSWR and 2:1 VSWR for (a)-(b) the current/voltage sensing-based output power detector, (c)-(d) the output voltage sensing only-based power detector, (e)-(f) the output voltage sensing only-based power detector normalized with respect to 10 log₁₀((|Zₐₙₜ|cos(θ_{Z}))/50), and (g)-(h) the input voltage sensing only-based power detector. At 31 GHz, the simulated input/output PSE is ≤±0.34 dB/±0.4 dB for VSWR=3:1 and ±0.21 dB/±0.23 dB for VSWR=2:1. Over 27-41 GHz, the measured input/output PSE is ≤±0.5 dB/±0.6 dB for VSWR=3:1 and ±0.25 dB/±0.35 dB for VSWR=2:1. The simulated PSE for the voltage only sensing-based power detector with and without respect to the theoretical 10 log₁₀((|Zₐₙₜ|cos(θ_{Z}))/50) trend is shown in FIG. 7K(c)-(f). The measured PSE with respect to the nominal voltage sensing relationship, 10 log₁₀((|Zₐₙₜ|cos(θ_{Z}))/50) is ≤±0.6 dB for VSWR=3:1 and ±0.3 dB for VSWR=2:1 over 27-41 GHz. Any deviation from the expected trend is due to imperfect voltage sensing.

Gain Curve Estimation.

After evaluating the individual power detector's functionality, the study used the gain curve estimation for real-time PA reconfiguration evaluation. The measured PA power gain curves were compared using external power powers, and the power gain curves estimated from the sensor DUT for 3:1 and 2:1 VSWR to fully characterize the VSWR performance as shown in FIG. 7J which depicts simulated power gain curves of the actual PA and the estimated power gain curves of the sensor DUT at 31 GHz for (a)-(b) 3:1 VSWR and (c)-(d) 2:1 VSWR. FIG. 7J demonstrates accurate power gain estimation over a wide power range for varying VSWR loads and multiple frequencies. This validated the dynamic range VSWR resilience.

Table 3 shows a comparison with the state-of-the-art power detectors.

TABLE 3

| | | | | | | | | | RFIC | JSSC | TMTT |
|---|---|---|---|---|---|---|---|---|---|---|---|
| | This Work | | | | ISSCC 2022 | | | | 2019 | 2015 | 2022 |
| Technology | 45 mm CMOS SOI | | | | 45 nm CMOS SOI | | | | 28 nm | 40 nm | 45 nm |
| | | | | | | | | | CMOS | CMOS | CMOS |
| | | | | | | | | | | | SOI |
| Detector | Voltage & Current | | | | Voltage & Current | | | | Voltage & | Voltage & | Quadrature |
| Principle | | | | | | | | | Current | Current | Coupler |
| Area(mm²) | 0.044 (VSWR Pₒᵤₜ Core) | | | | 0.8 (Sensor Core) | | | | 0.007 | 1.08 | *0.456 |
| | | | | | | | | | (Core) | | (Core) |
| | 0.011 (Pₒᵤₜ Core) | | | | *0.417 (Pₒᵤₜ Core) | | | | | | |
| | 0.011 (Pᵢₙ Core) | | | | | | | | | | |
| DC Power | 12 | | | | 44.32 | | | | 0.066 | 0.31 | 44.5 |
| Consumption | | | | | | | | | | | |
| (mW) | | | | | | | | | | | |
| Center | 34 | | | | 33 | | | | 76 | 5 | 38 |
| Frequency | | | | | | | | | | | |
| (GHz) | | | | | | | | | | | |
| Input | Yes | | | | No | | | | No | No | No |
| Power | | | | | | | | | | | |
| Sensing | | | | | | | | | | | |
| Power | *27-41 | | | | *22-41 | | | | 69-83 | Single | Single |
| Sensing | | | | | | | | | | Fre- | Fre- |
| BW (GHz) | | | | | | | | | | quency | quency |
| INL(dB) | ±0.5 | | | | ±0.5 | | | | ±0.5 | ±0.5 | ±0.5 |
| Frequency | 27 | 33 | 37 | 38 | 28 | 33 | 37 | 39 | 75 | 5 | 38 |
| (GHz) | | | | | | | | | | | |
| Dynamic | \hat{ }22.8/25.5 | \hat{ }22.7/28.2 | \hat{ }22.6/25.3 | \hat{ }22.5/24.8 | 22.35 | 22.55 | 22.66 | 22.02 | 27.2 | 32.5 | 16 |
| Range (dB) | | | | | | | | | | | |
| VSWR | 3 | 3 | 3 | 3 | 3 | 3 | 3 | 3 | — | 2.8 | 3 |
| Max Power | *±0.33 | *±0.46 | *±0.55 | *±0.60 | ±2 | ±1.01 | ±2.75 | ±3.36 | — | ±1 | ±3.35 |
| Sensing | | | | | | | | | | | |
| Error(dB) | | | | | | | | | | | |

Per Table 3, it can be observed that the exemplary compact VSWR power estimator provides competitive broadband power detector accuracy and range while supporting a direct interface with the single-ended antenna load and agnostic integration with mm-Wave PAs. Due to the removal of buffers and baluns, the exemplary compact VSWR power estimator can achieve one of the most compact sensor core areas for VSWR resilient power detection, particularly with a 10× area reduction from the broadband power detector presented in [60′]. The exemplary compact VSWR power estimator is understood to be the first of its kind to utilize differential current sensing with phase error compensation for accurate power sensing with substantial area savings and an auxiliary voltage-sensing-based power detector output for enhancing dynamic range resilience over VSWR.

Indeed, the exemplary compact VSWR power estimator can support accurate broadband operation and can be added to any PA architecture as the coupling mechanisms are weak. The 27-41 GHz sensor prototype demonstrates an input/output PSE of ≤±0.5 dB/±0.6 dB for VSWR=3:1 and ±0.25 dB/±0.35 dB for VSWR=2:1 and 50Ω dynamic range >22.5 dB/24.2 dB for the current/voltage sensing-based output and voltage sensing-based output over 27-41 GHz. To the inventor's knowledge, the exemplary compact VSWR power estimator is the most compact broadband demonstration of mm-Wave power sensing up to 3:1 VSWR, covering the entire Ka-band and the 5G FR2 24/28/39 GHz bands. In addition, the exemplary compact VSWR power estimator employs an auxiliary passive power detector path for dynamic range enhancement and power savings and provides the first demonstration of VSWR resilient power gain estimation at mm-Wave.

Experimental Results and Additional Examples for Coupler-based Sensing

The study also conducted an evaluation of VSWR power/impedance sensing via coupler sensing. A prototype was designed and fabricated in a 45 nm CMOS SOI process. At 38 GHz, the coupler-based sensor measured the antenna impedance for VSWR=3:1 with a maximum |Γ| and ∠Γ error of 0.238 and 28.9°, respectively. The 90° coupler network demonstrated a 16 dB dynamic range with an error within ±0.5 dB for 50Ω power sensing, as well as sensing the real power delivered to a complex antenna load for VSWR=3:1 with less than ±3.35 dB power sensing error. The chip dies occupied an area of 1.31×1.36 mm², while the sensor alone occupied an area of 0.47×0.971 mm².

Measurement Results. Embodiments of the exemplary coupler-based sensor provide power/impedance sensing over 3:1 antenna VSWR. The exemplary coupler-based sensor removed the need for any 90° phase shift by placing the sensor ports next to one another for easy integration with active post-processing circuitry and can be added to any PA architecture due to its input impedance being the same as that of the antenna as demonstrated by the prototype integrated with an mm-Wave class AB PA.

The study developed a power amplifier (PA) testbed. The PA driver uses a CS amplifier topology with a 1V Vdd supply, and the PA core utilized a cascode amplifier topology with a 2V Vdd supply. Capacitive neutralization is used to maximize gain and stability over the 27-40 GHz broadband design bandwidth. Transformer-based matching is used for the input balun and inter-stage matching due to its dual-resonance broadband performance. A coupler-based low-loss wideband impedance inverting balun is utilized for the PA output balun.

Power Amplifier Measurement Results.

FIG. 8A shows the measured PA results. The PA realized a 3 dB bandwidth (BW) of 37.5% (26-38 GHz), a peak small signal gain of 18.87 dB at 31 GHz, and an OP1 dB BW of 36.3% (27-39 GHz). The two-stage amplifier achieves a Pₛₐₜ/OP1 dB of 17.29 dBm/16.33 dBm and peak/OP1 dB PAE of 29.77%/28.51% at 37 GHz.

Power/Impedance Sensor Measurement Results.

To properly characterize the proposed sensor design, a Maury MT985AL load tuner was utilized. The Maury tuner was used to sweep the desired reflection coefficient, F, to properly characterize the coupler-based power/impedance sensor under the desired VSWR load conditions while performing CW power sweeps using an Agilent E8267D signal generator. To compensate for the PA gain variation due to VSWR and ensure the prototype can be sufficiently saturated, an external amplifier was added after the input signal source. FIG. 8B shows the tuner characterization/loss calibration.

The Maury tuner was characterized using a PNAX 5247B, a 1.85 mm calibration kit, and an MPI calibration substrate. Although the Maury ATS software provided S-Parameter-based loss calculations of the tuner as it varies through its mechanical settings, a measurement-based loss calibration was performed using an isolator on the input probe to isolate any additional losses due to input reflections. When performing the CW power sweep, the output power was captured through an N1914 power sensor, while the differential DC signal, V_{Psense}, was captured through an Agilent 34411A multimeter for power sensing. During the same power sweep, the two Dickson rectifier outputs for impedance sensing, |V_{cpl} and |I_{cpl}, were fed to Agilent 34465 multimeters. A one-time 50Ω calibration was performed to set the required fixed proportionality constants for impedance and power sensing, respectively. When testing a VSWR of 3:1, the tuner was swept with a fixed |Γ| of 0.5 and ∠Γ steps of 45°. For power sensing, we demonstrate ±0.5 dB error dynamic range of 16 dB for 50Ω, and an error within ±3.35 dB for a VSWR of 3:1. FIG. 8C shows the measured PSE for (a) VSWR=3:1, b) VSWR=2:1, and (c) 50Ω.

For impedance sensing, the study first extracted the impedance information in polar notation, where the error metrics are defined below:

Impedance Phase Error=∠Zₛₑₙₛₑ−∠Z_{load}

where Zₛₑₙₛₑ is the impedance extracted from the sensor and Load is the impedance presented to the proposed design after taking into account the transformation due to the GSG pad capacitance. The study detected a normalized impedance ratio varying from 0.5-1.7× and phase error within ±25°. The study then converted the sensed impedance to the corresponding sensed reflection coefficient and compared the presented reflection coefficient with the metrics defined below:

$${Γ}_{\frac{load}{sense}} = \frac{{Z}_{\frac{load}{sense}} - 50}{{Z}_{\frac{load}{sense}} + 50}$$

$$Γ Magnitude Error = ‖ {Γ}_{load} \vert - \vert {Γ}_{sense} ‖$$

$$Γ Phase Error = {∠Γ}_{load} - {∠Γ}_{sense}$$

Once converted to Γ, the study then detected the antenna load with a maximum |Γ| and ∠Γ error of 0.238 and 28.9° respectively, for VSWR of 3:1. FIG. 8D shows the measured normalized impedance Ratio, Zant phase error, Γ magnitude error, and Γ phase error for (subpanels (a)-(d)) VSWR=3:1 and (subpanels (e)-(g)) VSWR=2:1.

Table 4 shows a comparison of the exemplary coupler-based detector to the state-of-the-art.

TABLE 4

| | | RFIC | JSSC | ISCC | JSSC | ISCCC | TCAS1 |
|---|---|---|---|---|---|---|---|
| | This work | 2019 [30] | 2015 [31] | 2021 [20] | 2014 [21] | 2014 [26] | 2014 [25] |
| Technology | 45 nm | 28 nm | 40 nm | 22 nm | 0.13 μm | 40 nm | Hybrid GaN |
| | CMOS SOI | CMOS | CMOS | FDSOI | CMOS | CMOS | |
| Detector Principle | 90° Coupler | Voltage & | Voltage & | Complex | Mag & Phase | Mag & Phase | Multi-port |
| | | Current | Current | Voltage | Weak Coupling | Hybrid XFM | Reflectometer |
| Frequency(GHz) | 38 | 75 | 5 | 28 | 1.95 | 2.4 | 3 |
| Integration Level | with on | with on | with on | Purely | with on | with on | with on |
| | chip PA | chip PA | chip PA | Passive | chip PA | chip PA | PCB PA |
| Area(mm2) | 0.456 (Core) | 0.007 (Core) | 1.07 | 0.024 (Core) | 3.52 | 1.21 | ^{#}9240 |
| VSWR Resilient | Yes | No | Yes | No | No | No | No |
| Power Sensing | | | | | | | |
| Dynamic Range(dB) | 16 | 27.2 | 32.5 | — | — | — | — |
| INL(dB) | ±0.5 | ±0.5 | ±0.5 | — | — | — | — |
| Max Power Sensing | ±3.35 | — | ±1 | — | — | — | — |
| Error (dB) | (VSWR = 3) | | (VSWR = 2.8) | | | | |
| VSWR Resilient | Yes | No | No | Yes | Yes | Yes | Yes |
| Impedance Sensing | | | | | | | |
| \|Γ\| Detection Range | ≤0.5 | — | — | ≤0.7 | ≤0.7 | ≤0.5 | ≤0.8 |
| Γ Detection Accuracy | 0.238/28.9° | — | — | *0.14/33° | 0.12/- | 0.1/18° | 0.037/- |
| (Mag/Phase) | | | | | | | |

The table demonstrates competitive power and impedance sensing at mm-Wave frequencies for the exemplary coupler-based sensing, while prior work was only able to demonstrate a single sensing functionality.

### DISCUSSION

To compensate for the high path loss, mm-Wave wireless systems necessitate array-based frontends that boost the link budget and enhance the energy efficiency. However, due to near field couplings and substrate modes [2′], the antenna array elements coupled to each other, resulting in their driving impedance substantially deviating from the nominal 50Ω. This phenomenon is known as antenna Voltage Standing Wave Ratio (VSWR) variation or the antenna array's active impedance. This impedance mismatch in array systems is a function of the antenna element placement, array configuration, and most importantly the operation modes (e.g., MIMO beamforming)/beam steering angles, which in practice often exhibit rapid and substantial changes, such as 2:1-3:1 VSWR, even in well-designed low-coupling antenna arrays [58′]. Power amplifiers (PAs) are critical for the transmitter chain as they govern the overall system efficiency, linearity, and output power [3′]. The antenna load is transformed to the PA's optimum load through its output matching network (OMN) and is hence very susceptible to VSWR. This variation will shift the PA load impedance away from its optimum, significantly degrading the efficiency, output power, linearity, and ultimately the PA reliability. Active load-modulation PAs, e.g., Doherty PAs, are particularly sensitive to this VSWR effect [59′]. Despite some PAs having shown resilient device reliability under load variations [4′], [5′], [6′], [7′], restoring PA performance like output power and linearity requires the PA to be reconfigurable, either through passive OMN tuning [8′], [9′], [10], [11′], [12′] or active PA reconfiguration by enabling/disabling transistor slices and adjusting biasing [13′], [14′], [15′], [16′], [17′]. Nonetheless, these reconfigurable PAs all require knowledge of the antenna's impedance variation and true power delivered to the mismatched antenna loads, which necessitates on-chip sensor circuits for VSWR resilient power/impedance detection with high accuracy and rapid response [18].

Multiple works have been presented for VSWR resilient impedance sensing for single ended loads [23′], [25′], [26′], [31′], [32′], [33′], [43′], [60′]. However, VSWR resilient power sensing for single ended loads at mm-Wave has not been demonstrated, though most mm-Wave frontends mandate single-ended loads. Designs such as [19′], [20′] measure the output voltage for power detection; this topology only provides the true output power accurately for a single known real load. [21′], [22′] introduce a dual current/voltage detection scheme, allowing them to sense the true power delivered to the antenna over VSWR. However, their voltage sensing scheme loads the OMN, and the current sensing scheme is only applicable for differential PA outputs. To overcome the aforementioned issues, a new single-ended VSWR-resilient joint impedance/power sensor topology based on a single-ended compact on-chip quadrature coupler [61] is introduced.

Additional Discussion.

5G mm-Wave (24-40 GHz) is a major enabling technology to support future exponential data traffic growth [1]-[2]. With a wide available spectrum and spectrally efficient modulation schemes such as high order quadrature amplitude modulation (QAM) and orthogonal frequency-division multiplexing (OFDM), mm-Wave 5G wireless can readily support multi-Gb/s datalinks [3]-[5]. To overcome the mm-Wave free space path loss, phased arrays are widely employed. However, antenna element coupling within arrays is inevitable through near-field couplings and substrate modes, causing the antenna driving impedance to deviate from the nominal 50Ω [6]. This is known as antenna Voltage Standing Wave Ratio (VSWR) variation or the array's active impedance. In phased arrays, antenna VSWR is a dynamic phenomenon, varying with the beam steering angle, antenna element placement, array configuration, and operation modes (e.g., MIMO/beamforming). Even well-designed low-coupling arrays can experience up to 3:1 VSWR [7].

Power amplifiers (PAs) are the most critical block within the TX chain as they govern the overall system efficiency, linearity, and output power but are the most susceptible to antenna VSWR as they directly interface with the antenna load [3]. The PA output matching network (OMN) is designed to transform the standard 50Ω antenna impedance to the PA's load pull impedance to maximize performance. With the antenna driving impedance variations, the PA load impedance deviates away from its optimum, drastically degrading the PA efficiency, output power, and linearity. While reconfigurable PAs can restore PA performance by passive or active tuning [8]-[16], they often require accurate performance assessment, even under large antenna VSWR variations. Hence, in situ VSWR-resilient sensors have become necessary, particularly for power and impedance sensing at each array element [17]-[20].

The most conventional power sensing scheme is voltage-only sensing, where the sensed voltage is fed to a rectification circuit [21]-[22]. However, this technique only tracks the true RF power delivered to the antenna load for a known real antenna driving impedance. An alternative approach shown in [23] and [24] is to sense both the output voltage and current to measure the true RF power over the antenna VSWR. This technique works for both varying and complex antenna loads but has only been demonstrated on differential PAs when most mm-Wave front ends and antenna interfaces are single-ended.

Multiple designs have demonstrated VSWR resilient impedance sensing on single-ended loads [25]-[32]. However, they either add signal loss, limit the PA OMN bandwidth (BW), or modify the OMN's impedance transformation ratio. In addition, they have only been demonstrated at a single frequency, while broadband VSWR-resilient operation is required to support the entire band of interest. To overcome the aforementioned issues, a single-ended broadband VSWR resilient joint true power/impedance sensor based on a current/voltage sensing scheme was developed and employed herein [33]. The exemplary VSWR voltage and current sensor is agnostic to PA designs and can be integrated at the element level to mm-Wave frontends.

### CONCLUSION

Each and every feature described herein, and each and every combination of two or more of such features, is included within the scope of the present invention, provided that the features included in such a combination are not mutually inconsistent.

Although example embodiments of the disclosed technology are explained in detail herein, it is to be understood that other embodiments are contemplated. Accordingly, it is not intended that the disclosed technology be limited in its scope to the details of construction and arrangement of components set forth in the following description or illustrated in the drawings. The disclosed technology is capable of other embodiments and of being practiced or carried out in various ways.

It must also be noted that, as used in the specification and the appended claims, the singular forms “a,” “an” and “the” include plural referents unless the context clearly dictates otherwise. Ranges may be expressed herein as from “about” or “approximately” one particular value and/or to “about” or “approximately” another particular value. When such a range is expressed, other exemplary embodiments include from the one particular value and/or to the other particular value.

By “comprising” or “containing” or “including” is meant that at least the named compound, element, particle, or method step is present in the composition or article or method, but does not exclude the presence of other compounds, materials, particles, method steps, even if the other such compounds, material, particles, method steps have the same function as what is named.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; the number or type of embodiments described in the specification.

While the methods and systems have been described in connection with certain embodiments and specific examples, it is not intended that the scope be limited to the particular embodiments set forth, as the embodiments herein are intended in all respects to be illustrative rather than restrictive.

The following patents, applications and publications, as listed below and throughout this document, are hereby incorporated by reference in their entirety herein.

### References #1

[1] T. S. Rappaport et al., “Millimeter wave mobile communications for 5G cellular: It will work!” IEEE Access, vol. 1, pp. 335-349, May 2013.
[2] S. Rangan, T. S. Rappaport, and E. Erkip, “Millimeter-wave cellular wireless networks: Potentials and challenges,” Proc. IEEE, vol. 102, no. 3, pp. 366-385, March 2014.
[3] H. Wang, P. M. Asbeck, and C. Fager, “Millimeter-Wave Power Amplifier Integrated Circuits for High Dynamic Range Signals,” IEEE Journal of Microwaves (the inaugural issue), vol. 1, no. 1, pp. 299-316, January 2021.
[4] V. Camarchia, R. Quaglia, A. Piacibello, D. P. Nguyen, H. Wang, and A.-V. Pham, “A review of technologies and design techniques of millimeter-wave power amplifiers,” IEEE Trans. Microw. Theory Techn., vol. 68, no. 7, pp. 2957-2983, July 2020.
[5] 3GPP 5G-NR Specifications. Accessed: April 2020. [Online]. Available: http://www.3gpp.org/DynaReport/38-series.htm
[6] C. A. Balanis, Antenna Theory: Analysis and Design. Hoboken, N.J., USA: Wiley, 2016.
[7] C. Fager, T. Eriksson, F. Barradas, K. Hausmair, T. Cunha, and J. C. Pedro, “Linearity and Efficiency in 5G Transmitters: New Techniques for Analyzing Efficiency, Linearity, and Linearization in a 5G Active Antenna Transmitter Context,” IEEE Microw. Mag., vol. 20, no. 5, pp. 35-49, May 2019.
[8] S. Hu, S. Kousai and H. Wang, “Antenna Impedance Variation Compensation by Exploiting a Digital Doherty Power Amplifier Architecture,” IEEE Transactions on Microwave Theory and Techniques, vol. 63, no. 2, pp. 580-597, February 2015.
[9] H. Lyu and K. Chen, “Balanced-to-Doherty Mode-Reconfigurable Power Amplifier With High Efficiency and Linearity Against Load Mismatch,” IEEE Transactions on Microwave Theory and Techniques, vol. 68, no. 5, pp. 1717-1728, May 2020.
[10] D. Ji, J. Jeon and J. Kim, “A Novel Load Mismatch Detection and Correction Technique for 3G/4G Load Insensitive Power Amplifier Application,” IEEE Transactions on Microwave Theory and Techniques, vol. 63, no. 5, pp. 1530-1543, May 2015.
[11] C. Sanchez-Perez, D. Sardin, M. Roberg, J. de Mingo and Z. Popović, “Tunable outphasing for power amplifier efficiency improvement under load mismatch,” IEEE/MTT-S International Microwave Symposium Digest, 2012, pp. 1-3.
[12] S. M. Bowers, K. Sengupta, K. Dasgupta, B. D. Parker and A. Hajimiri, “Integrated Self-Healing for mm-Wave Power Amplifiers,” IEEE Transactions on Microwave Theory and Techniques, vol. 61, no. 3, pp. 1301-1315, March 2013.
[13] Y. Wu, M. Abu Khater, A. Semnani and D. Peroulis, “An S-band 3-W load-reconfigurable power amplifier with 50-76% efficiency for VSWR up to 4:1,” IEEE MTT-S International Microwave Symposium (IMS), 2017, pp. 2041-2044.
[14] A. Serhan, P. Ferris and A. Giry, “Broadband SOI PA with tunable matching network for improved LTE performances under high VSWR,” IEEE International Conference on Electronics, Circuits and Systems (ICECS), 2016, pp. 488-491.
[15] C. R. Chappidi and K. Sengupta, “A 26-42 GHz broadband, back-off efficient and vswr tolerant CMOS power amplifier architecture for 5G applications,” Proc. Symp. VLSI Circuits, June 2019, pp. 22-23.
[16] C. R. Chappidi, T. Sharma and K. Sengupta, “Multi-port Active Load Pulling for mm-Wave 5G Power Amplifiers: Bandwidth, Back-Off Efficiency, and VSWR Tolerance,” IEEE Transactions on Microwave Theory and Techniques, vol. 68, no. 7, pp. 2998-3016, July 2020.
[17] F. Wang, S. Xu, J. Romberg and H. Wang, “An Artificial-Intelligence (AI) Assisted Mm-Wave Doherty Power Amplifier with Rapid Mixed-Mode In-Field Performance Optimization,” IEEE MTT-S International Microwave Conference on Hardware and Systems for 5G and Beyond (IMC-5G), pp. 1-3, August 2019.
[18] S. Xu, F. Wang, H. Wang and J. Romberg, “In-Field Performance Optimization for mm-Wave Mixed-Signal Doherty Power Amplifiers: A Bandit Approach,” IEEE Transactions on Circuits and Systems I: Regular Papers, vol. 67, no. 12, pp. 5302-5315, December 2020.
[19] N. S. Mannem, M.-Y. Huang, T.-Y. Huang and H. Wang, “A Reconfigurable Hybrid Series/Parallel Doherty Power Amplifier With Antenna VSWR Resilient Performance for MIMO Arrays,” in IEEE Journal of Solid-State Circuits, vol. 55, no. 12, pp. 3335-3348, December 2020.
[20] J. W. Jeong, J. Kitchen and S. Ozev, “Process independent gain measurement with low overhead via BIST/DUT co-design,” 2016 IEEE 34th VLSI Test Symposium (VTS), 2016, pp. 1-6.
[21] U. R. Pfeiffer and D. Goren, “A 20 dBm Fully-Integrated 60 GHz SiGe Power Amplifier With Automatic Level Control,” IEEE Journal of Solid-State Circuits, vol. 42, no. 7, pp. 1455-1463, July 2007.
[22] T. Zhang, W. R. Eisenstadt, R. M. Fox and Q. Yin, “Bipolar Microwave RMS Power Detectors,” IEEE Journal of Solid-State Circuits, vol. 41, no. 9, pp. 2188-2192, September 2006.
[23] V. Qunaj and P. Reynaert, “An E-band Fully-Integrated True Power Detector in 28 nm CMOS,” IEEE Radio Frequency Integrated Circuits Symposium (RFIC), pp. 191-194, June 2019.
[24] B. Francois and P. Reynaert, “A Fully Integrated Transformer-Coupled Power Detector With 5 GHz RF PA for WLAN 802.11ac in 40 nm CMOS,” IEEE Journal of Solid-State Circuits, vol. 50, no. 5, pp. 1237-1250, May 2015.
[25] Y. Zhang, G. Mangraviti, J. Nguyen, Z. Zong and P. Wambacq, “26.4 A Reflection-Coefficient Sensor for 28 GHz Beamforming Transmitters in 22 nm FD-SOI CMOS,” IEEE International Solid-State Circuits Conference (ISSCC), 2021, pp. 360-362.
[26] S. Kousai, K. Onizuka, J. Wadatsumi, T. Yamaguchi, Y. Kuriyama and M. Nagaoka, “Polar Antenna Impedance Detection and Tuning for Efficiency Improvement in a 3G/4G CMOS Power Amplifier,” IEEE Journal of Solid-State Circuits, vol. 49, no. 12, pp. 2902-2914, December 2014.
[27] D. Donahue and T. Barton, “A 2-GHz Sampled Line Impedance Sensor for Power Amplifier Applications with Varying Load Impedance,” IEEE Topical Conference on RF/Microwave Power Amplifiers for Radio and Wireless Applications (PAWR), 2019, pp. 1-3.
[28] D. Donahue, P. de Falco and T. Barton, “Impedance Sensing Integrated Directly into a Power Amplifier Output Matching Network,” IEEE MTT-S International Microwave Symposium (IMS), 2019, pp. 983-986.
[29] D. T. Donahue and T. W. Barton, “Multi-port Reflectometry Applied to a Varactor-Tuned Sampled-Line,” 95th ARFTG Microwave Measurement Conference (ARFTG), 2020, pp. 1-4.
[30] D. T. Donahue, P. E. de Falco and T. W. Barton, “Power Amplifier With Load Impedance Sensing Incorporated Into the Output Matching Network,” in IEEE Transactions on Circuits and Systems I: Regular Papers, vol. 67, no. 12, pp. 5113-5124, December 2020.
[31] C. Lu, A. Ba, Y. Liu, X. Wang, C. Bachmann and K. Philips, “17.4 A sub-mW antenna-impedance detection using electrical balance for single-step on-chip tunable matching in wearable/implantable applications,” IEEE International Solid-State Circuits Conference (ISSCC), pp. 298-299, 2017.
[32] D. Munzer, N. S. Mannem, E. F. Garay and H. Wang, “Single-Ended Quadrature Coupler-Based VSWR Resilient Joint mm-Wave True Power Detector and Impedance Sensor,” IEEE Transactions on Microwave Theory and Techniques, March 2022.
[33] D. J. Munzer, N. S. Mannem, E. Garay and H. Wang, “A Broadband Mm-Wave VSWR-Resilient Joint True-Power Detector and Impedance Sensor Supporting Single-Ended Antenna Interfaces,” IEEE International Solid-State Circuits Conference (ISSCC), February 2022, pp. 1-3.
[34] J. S. Park, S. Kousai and H. Wang, “A fully differential ultra-compact broadband transformer based quadrature generation scheme,” Custom Integrated Circuits Conference (CICC), 2013, pp. 1-4.
[35] J. S. Park and H. Wang, “A Transformer-Based Poly-Phase Network for Ultra-Broadband Quadrature Signal Generation,” in IEEE Transactions on Microwave Theory and Techniques, vol. 63, no. 12, pp. 4444-4457.
[36] K. Koh and G. M. Rebeiz, “0.13-μm CMOS Phase Shifters for X-, Ku-, and K-Band Phased Arrays,” IEEE Journal of Solid-State Circuits, vol. 42, no. 11, pp. 2535-2546, November 2007.
[37] T.-W. Li, J. S. Park and H. Wang, “A 2-24-GHz 360° Full-Span Differential Vector Modulator Phase Rotator With Transformer-Based Poly-Phase Quadrature Network,” IEEE Transactions on Very Large Scale Integration (VLSI) Systems, vol. 28, no. 12, pp. 2623-2635, December 2020.
[38] F. Meng, K. Ma, K. S. Yeo and S. Xu, “A 57-to-64-GHz 0.094-mm2 5-bit Passive Phase Shifter in 65-nm CMOS,” IEEE Transactions on Very Large Scale Integration (VLSI) Systems, vol. 24, no. 5, pp. 1917-1925, May 2016.
[39] T. Li and H. Wang, “A Millimeter-Wave Fully Integrated Passive Reflection-Type Phase Shifter With Transformer-Based Multi-Resonance Loads for 360° Phase Shifting,” IEEE Transactions on Circuits and Systems I: Regular Papers, vol. 65, no. 4, pp. 1406-1419, April 2018.
[40] S. Lee, M. Huang, Y. Youn and H. Wang, “A 15-55 GHz Low-Loss Ultra-Compact Folded Inductor-Based Multi-Section Wilkinson Power Divider for Multi-Band 5G Applications,” IEEE MTT-S International Microwave Symposium (IMS), May 2019, pp. 432-435.
[41] U. Basumata, A. Mondal, S. Das and H. Rahaman, “Design of Two-Stage Fully-Differential Driver in SAR ADC with Indirect Feedback Compensation Technique,” International Symposium on Devices, Circuits and Systems (ISDCS), April 2021, pp. 1-5.
[42] O. H. Schade and E. J. Kramer, “A low-voltage BiMOS op amp,” IEEE Journal of Solid-State Circuits, vol. 16, no. 6, pp. 661-668, December 1981.
[43] M. Franciotta, G. Colli and R. Castello, “A 100-MHz 4-mW four-quadrant BiCMOS analog multiplier,” IEEE Journal of Solid-State Circuits, vol. 32, no. 10, pp. 1568-1572, October 1997.
[44] Bosen Tzeng, Chun-Hsien Lien, H. Wang, Yu-Chi Wang, Pane-Chane Chao and Chung-Hsu Chen, “A 1-17-GHz InGaP—GaAs HBT MMIC analog multiplier and mixer with broad-band input-matching networks,” IEEE Transactions on Microwave Theory and Techniques, vol. 50, no. 11, pp. 2564-2568, November 2002.
[45] M. Awad, P. Benech and J. Duchamp, “Design of Dickson rectifier for RF energy harvesting in 28 nm FD-SOI technology,” Joint International EUROSOI Workshop and International Conference on Ultimate Integration on Silicon (EUROSOI-ULIS), pp. 1-4, 2018.
[46] M. Huang, T. Chi, F. Wang and H. Wang, “An All-Passive Negative Feedback Network for Broadband and Wide Field-of-View Self-Steering Beam-Forming With Zero DC Power Consumption,” in IEEE Journal of Solid-State Circuits, vol. 52, no. 5, pp. 1260-1273, May 2017.

### Reference List #2

[1′]“Phased Array Antenna Patterns-Part 1.” https://www.analog.com/en/analog-dialogue/articles/phased-arrayantenna-patterns-part1.html (accessed October 2022).
[2′] Wiley, Antenna Theory: Analysis and Design. February 2016.
[3′] H. Wang, P. M. Asbeck and C. Fager, “Millimeter-Wave Power Amplifier Integrated Circuits for High Dynamic Range Signals,” IEEE Journal of Microwaves, vol. 1, no. 1, pp. 299-316, January 2021.
[4′] N. Rostomyan, M. Ozen and P. Asbeck, “Comparison of pMOS and nMOS 28 GHz high efficiency linear power amplifiers in 45 nm CMOS SOI,” IEEE Topical Conference on RF/Microwave Power Amplifiers for Radio and Wireless Applications, March 2018.
[5′] D. Thomas, N. Rostomyan and P. Asbeck, “A 45% PAE pMOS Power Amplifier for 28 GHz Applications in 45 nm SOI,” IEEE 61st International Midwest Symposium on Circuits and Systems, pp. 680-683, January 2019.
[6′] P. M. Asbeck, N. Rostomyan, M. Ozen, B. Rabet and J. A. Jayamon, “Power Amplifiers for mm-Wave 5G Applications: Technology Comparisons and CMOS-SOI Demonstration Circuits,” IEEE Transactions on Microwave Theory and Techniques, vol. 67, no. 7, pp. 3099-3109, July 2019.
[7′] H. Lyu and K. Chen, “Balanced-to-Doherty Mode-Reconfigurable Power Amplifier With High Efficiency and Linearity Against Load Mismatch,” IEEE Transactions on Microwave Theory and Techniques, vol. 68, no. 5, pp. 1717-1728, May 2020.
[8′] D. Ji, J. Jeon and J. Kim, “A Novel Load Mismatch Detection and Correction Technique for 3G/4G Load Insensitive Power Amplifier Application,” IEEE Transactions on Microwave Theory and Techniques, vol. 63, no. 5, pp. 1530-1543, May 2015.
[9′] C. Sanchez-Perez, D. Sardin, M. Roberg, J. de Mingo and Z. Popović, “Tunable outphasing for power amplifier efficiency improvement under load mismatch,” IEEE/MTT-S International Microwave Symposium Digest, pp. 1-3, August 2012.
[10′] S. M. Bowers, K. Sengupta, K. Dasgupta, B. D. Parker and A. Hajimiri, “Integrated Self-Healing for mm-Wave Power Amplifiers,” IEEE Transactions on Microwave Theory and Techniques, vol. 61, no. 3, pp. 1301-1315, March 2013.
[11′] Y. Wu, M. Abu Khater, A. Semnani and D. Peroulis, “An S-band 3-W load-reconfigurable power amplifier with 50-76% efficiency for VSWR up to 4:1,” IEEE MTT-S International Microwave Symposium, pp. 2041-2044, October 2017.
[12′] A. Serhan, P. Ferris and A. Giry, “Broadband SOI PA with tunable matching network for improved LTE performances under high VSWR,” IEEE International Conference on Electronics, Circuits and Systems, pp. 488-491, February 2017.
[13′] F. Wang, S. Xu, J. Romberg and H. Wang, “An Artificial-Intelligence (AI) Assisted Mm-Wave Doherty Power Amplifier with Rapid Mixed-Mode In-Field Performance Optimization,” IEEE MTT-S International Microwave Conference on Hardware and Systems for 5G and Beyond, pp. 1-3, August 2019.
[14′] S. Xu, F. Wang, H. Wang and J. Romberg, “In-Field Performance Optimization for mm-Wave Mixed-Signal Doherty Power Amplifiers: A Bandit Approach,” IEEE Transactions on Circuits and Systems I: Regular Papers, vol. 67, no. 12, pp. 5302-5315, December 2020.
[15′] N. S. Mannem, M.-Y. Huang, T.-Y. Huang and H. Wang, “A Reconfigurable Hybrid Series/Parallel Doherty Power Amplifier With Antenna VSWR Resilient Performance for MIMO Arrays,” IEEE Journal of Solid-State Circuits, vol. 55, no. 12, pp. 3335-3348, December 2020.
[16′] C. R. Chappidi and K. Sengupta, “A 26-42 GHz Broadband, Back-off Efficient and Vswr Tolerant CMOS Power Amplifier Architecture for 5G Applications,” Proc. Symp. VLSI Circuits, pp. 22-23, June 2019.
[17′] C. R. Chappidi, T. Sharma and K. Sengupta, “Multi-port Active Load Pulling for mm-Wave 5G Power Amplifiers: Bandwidth, Back-Off Efficiency, and VSWR Tolerance,” IEEE Transactions on Microwave Theory and Techniques, vol. 68, no. 7, pp. 2998-3016, July 2020.
[18′] J. W. Jeong, J. Kitchen and S. Ozev, “Process independent gain measurement with low overhead via BIST/DUT co-design,” IEEE 34th VLSI Test Symposium, pp. 1-6, May 2016.
[19′] U. R. Pfeiffer and D. Goren, “A 20 dBm Fully-Integrated 60 GHz SiGe Power Amplifier With Automatic Level Control,” IEEE Journal of Solid-State Circuits, vol. 42, no. 7, pp. 1455-1463, July 2007.
[20′] T. Zhang, W. R. Eisenstadt, R. M. Fox and Q. Yin, “Bipolar Microwave RMS Power Detectors,” IEEE Journal of Solid-State Circuits, vol. 41, no. 9, pp. 2188-2192, September 2006.
[21′] V. Qunaj and P. Reynaert, “An E-band Fully-Integrated True Power Detector in 28 nm CMOS,” IEEE Radio Frequency Integrated Circuits Symposium, pp. 191-194, June 2019.
[22′] B. Francois and P. Reynaert, “A Fully Integrated Transformer-Coupled Power Detector With 5 GHz RF PA for WLAN 802.11ac in 40 nm CMOS,” IEEE Journal of Solid-State Circuits, vol. 50, no. 5, pp. 1237-1250, May 2015.
[23′] Y. Zhang, G. Mangraviti, J. Nguyen, Z. Zong and P. Wambacq, “26.4 A Reflection-Coefficient Sensor for 28 GHz Beamforming Transmitters in 22 nm FD-SOI CMOS,” IEEE International Solid-State Circuits Conference, pp. 360-362, March 2021.
[24′] V. Solomko et al., “RF Impedance Sensor for Antenna-Tuning Front Ends,” IEEE Transactions on Microwave Theory and Techniques, vol. 68, no. 3, pp. 1095-1102, March 2020.
[25′] S. Kousai, K. Onizuka, J. Wadatsumi, T. Yamaguchi, Y. Kuriyama and M. Nagaoka, “Polar Antenna Impedance Detection and Tuning for Efficiency Improvement in a 3G/4G CMOS Power Amplifier,” IEEE Journal of Solid-State Circuits, vol. 49, no. 12, pp. 2902-2914, December 2014.
[26′] D. T. Donahue, P. E. de Falco and T. W. Barton, “Power Amplifier With Load Impedance Sensing Incorporated Into the Output Matching Network,” IEEE Transactions on Circuits and Systems I: Regular Papers, vol. 67, no. 12, pp. 5113-5124, December 2020.
[27′] T. S. Dang, A.-D. Tran, S.-J. Ham, H.-W. Park, L.-N.-D. Hien and S.-W. Yoon, “InGaP/GaAs WLAN power amplifier with detector using on-chip coupler,” Asia-Pacific Microwave Conference Proceedings, pp. 703-706, January 2014.
[28′] C. F. Gonçalves, F. M. Barradas, L. C. Nunes, P. M. Cabral and J. C. Pedro, “A Compact Impedance Measurement Solution for Systems Operating in Load Varying Scenarios,” IEEE Access, vol. 9, pp. 38757-38766, March 2021.
[29′] E. L. Firrao, A. J. Annema and B. Nauta, “An Automatic Antenna Tuning System Using Only RF Signal Amplitudes,” IEEE Transactions on Circuits and Systems II: Express Briefs, vol. 55, no. 9, pp. 833-837, September 2008.
[30′] de Lima, R. N., Huyart, B., Bergeault, E., & Jallet, L. (2000). “MMIC impedance matching system” Electronics Letters, Stevenage vol. 36, no. 16, https://www.proquest.com/scholarly-journals/mmic-impedance-matching-system/docview/1620850633/se-2, August 2020.
[31′] D. Donahue and T. Barton, “A 2-GHz Sampled Line Impedance Sensor for Power Amplifier Applications with Varying Load Impedance,” IEEE Topical Conference on RF/Microwave Power Amplifiers for Radio and Wireless Applications, pp. 1-3, May 2019.
[32′] D. Donahue, P. de Falco and T. Barton, “Impedance Sensing Integrated Directly into a Power Amplifier Output Matching Network,” IEEE MTT-S International Microwave Symposium, pp. 983-986, July 2019.
[33′] D. T. Donahue and T. W. Barton, “Multi-port Reflectometry Applied to a Varactor-Tuned Sampled-Line,” 95th ARFTG Microwave Measurement Conference, pp. 1-4, November 2020.
[34′] W. Aouimeur et al., “A Fully In-Situ Reflectometer in G band in 55 nm SiGe BiCMOS,” International Workshop on Integrated Nonlinear Microwave and Millimetre-wave Circuits, pp. 1-3, August 2018.
[35′] Williams, W. L, Computer-aided measurement of microwave circuits, California Institute of Technology ProQuest Dissertations Publishing, 1989.
[36′] G. F. Engen, “Calibrating the Six-Port Reflectometer by Means of Sliding Terminations,” IEEE Transactions on Microwave Theory and Techniques, vol. 26, no. 12, pp. 951-957, December 1978.
[37′] Y. Zhang et al., “A Low-Power Reflection-Coefficient Sensor for 28-GHz Beamforming Transmitters in 22-nm FD-SOI CMOS,” IEEE Journal of Solid-State Circuits, vol. 56, no. 12, pp. 3704-3714, December 2021.
[38′] Y. Yoon, H. Kim, H. Kim, K.-S. Lee, C.-H. Lee and J. S. Kenney, “A 2.4-GHz CMOS Power Amplifier With an Integrated Antenna Impedance Mismatch Correction System,” IEEE Journal of Solid-State Circuits, vol. 49, no. 3, pp. 608-621, March 2014.
[39′] D. Nicolas, A. Serhan, A. Giry, T. Parra and E. Mercier, “A fully-integrated SOI CMOS complex-impedance detector for matching network tuning in LTE power amplifier,” IEEE Radio Frequency Integrated Circuits Symposium, pp. 15-18, July 2017.
[40′] Q. Gu, J. R. De Luis, A. S. Morris and J. Hilbert, “An Analytical Algorithm for Pi-Network Impedance Tuners,” IEEE Transactions on Circuits and Systems I: Regular Papers, vol. 58, no. 12, pp. 2894-2905, December 2011.
[41′] D. Munzer, N. S. Mannem, E. F. Garay and H. Wang, “Single-Ended Quadrature Coupler-Based VSWR Resilient Joint mm-Wave True Power Detector and Impedance Sensor,” IEEE Transactions on Microwave Theory and Techniques, vol. 70, no. 5, pp. 2802-2814, May 2022.
[42′] F. Meng, A. van Bezooijen and R. Mahmoudi, “A Mismatch Detector for Adaptive Antenna Impedance Matching,” IEEE European Microwave Conference, Manchester, UK, pp. 1457-1460, January 2007.
[43′] C. Lu, A. Ba, Y. Liu, X. Wang, C. Bachmann and K. Philips, “17.4 A sub-mW antenna-impedance detection using electrical balance for single-step on-chip tunable matching in wearable/implantable applications,” IEEE International Solid-State Circuits Conference, pp. 298-299, March 2017.
[44′] K. Koh and G. M. Rebeiz, “0.13-μm CMOS Phase Shifters for X-, Ku-, and K-Band Phased Arrays,” IEEE Journal of Solid-State Circuits, vol. 42, no. 11, pp. 2535-2546, November 2007.
[45′] T.-W. Li, J. S. Park and H. Wang, “A 2-24-GHz 360° Full-Span Differential Vector Modulator Phase Rotator With Transformer-Based Poly-Phase Quadrature Network,” IEEE Transactions on Very Large Scale Integration Systems, vol. 28, no. 12, pp. 2623-2635, December 2020.
[46′] F. Meng, K. Ma, K. S. Yeo and S. Xu, “A 57-to-64-GHz 0.094-mm2 5-bit Passive Phase Shifter in 65-nm CMOS,” IEEE Transactions on Very Large Scale Integration Systems, vol. 24, no. 5, pp. 1917-1925, May 2016.
[47′] T. Li and H. Wang, “A Millimeter-Wave Fully Integrated Passive Reflection-Type Phase Shifter With Transformer-Based Multi-Resonance Loads for 360° Phase Shifting,” IEEE Transactions on Circuits and Systems I: Regular Papers, vol. 65, no. 4, pp. 1406-1419, April 2018.
[48′] Steve Knox and Peter Chyurlia. “Maury ATS—Load Pull Guide.” http://www.doe.carleton.ca/˜nagui/labequip/loadpull/loadpull_brief.html, July 2004 (accessed October. 2022).
[49′] R. Andrej, “7 Advantages of in-situ Calibration,” in On-Wafer Calibration Techniques Enabling Accurate Characterization of High-Performance Silicon Devices at the mm-Wave Range and Beyond: River Publishers, pp. 97-108, 2019.
[50′] Maury Microwave, “2.4 mm & 1.85 mm Automated Tuners”, 4T-050G04A Datasheet, https://www.maurymw.com/pdf/datasheets/4T-050G04A.pdf, July 2022, (accessed 2022).
[51′] M. Pierpoint, R. D. Pollard and J. R. Richardson, “The Design and Modelling of Automated Broadband Slide-Screw Tuners,” 29th ARFTG Conference Digest, pp. 218-228, June 1987.
[52′] A. E. Sanderson, “A New High-Precision Method for the Measurement of the VSWR of Coaxial Connectors,” IRE Transactions on Microwave Theory and Techniques, vol. 9, no. 6, pp. 524-528, November 1961.
[53′] G. Sloan, “An Algorithm for Using a Slide-Screw Tuner as a Computer-Controlled Impedance,” 35th ARFTG Conference Digest, pp. 19-28, May 1990.
[54′] J. Dunsmore, “Network analyzer including automatic port extension calibration and method of operation,” USA patent appl. U.S. Pat. No. 7,088,087B2, https://patents.google.com/patent/U.S. Pat. No. 7,088,087, 2004.
[55′] Agilent Technologies. “Advanced Calibration Techniques for Vector Network Analyzers.”, https://www.google.com/url?sa=t&rct=j&q=&esrc=s&source=web&cd=&cad=rja&uact=8&ved=2ahUKEwjStPy8z8H6AhV1h_0HHUh2CoAQFnoECAgQAQ&url=http%3A%2F%2Farpg-serv.ing2.uniromal.it %2Fmostacci %2Fdidattica %2Flab_meas_high_freq%2Fstore %2FAgilent% 2FAdvanced_VNA_calibration.pdf&usg=AOvVaw2bzKUsb77yuogLwJpGhyJ9, 2006 (accessed October 2022).
[56′] J. B. David Ballo. “Eliminate Fixture Effects On Device Measurements.” https://www.mwrf.com/technologies/test-measurement/article/21842522/eliminate-fixture-effects-on-device-measurements, May 2008 (accessed October 2022).
[57′] Alan Blankman. “Using 2nd Tier Calibration for Cable Fixture De-embedding.” https://cdn.teledynelecroy.com/files/appnotes/using_2nd-tier_calibration_for_cable_test_fixture_de-embedding_rev2.pdf, May 2011 (accessed October 2022).
[58′] C. Fager, T. Eriksson, F. Barradas, K. Hausmair, T. Cunha, and J. C. Pedro, “Linearity and Efficiency in 5G Transmitters: New Techniques for Analyzing Efficiency, Linearity, and Linearization in a 5G Active Antenna Transmitter Context,” IEEE Microwave Magazine., vol. 20, no. 5, pp. 35-49, May 2019.
[59′] S. Hu, S. Kousai and H. Wang, “Antenna Impedance Variation Compensation by Exploiting a Digital Doherty Power Amplifier Architecture,” IEEE Transactions on Microwave Theory and Techniques, vol. 63, no. 2, pp. 580-597, February 2015.
[60′] D. Munzer, N. S. Mannem, E. Garay, H. Wang, “A Broadband Mm-Wave VSWR Resilient Joint True Power Detector and Impedance Sensor Supporting Single-Ended Antenna Interfaces,” IEEE International Solid-State Circuits Conference, pp. 1-3, March 2022.
[61′] D. Munzer, N. S. Mannem and H. Wang, “A Single-Ended Coupler-Based VSWR Resilient Joint mm-Wave True Power Detector and Impedance Sensor,” IEEE Microwave and Wireless Components Letters, vol. 31, no. 6, pp. 812-815, June 2021.
[62′] R. Smith, K. Ansari, J. Rogers and C. Plett, “Tuning of the Relative Phases of a Rotary Travelling Wave Oscillator,” IEEE Microwave and Wireless Components Letters, vol. 26, no. 8, pp. 610-612, August 2016.
[63′] H. Song, B. Bakkaloglu and J. T. Aberle, “A CMOS adaptive antenna-impedance-tuning IC operating in the 850 MHz-to-2 GHz band,” IEEE International Solid-State Circuits Conference, pp. 384-385,385a, May 2009.
[64′] N. S. Mannem, T. Huang, and H. Wang, “Broadband Active Load-Modulation Power Amplification Using Coupled-Line Baluns: A Multi-Frequency Role-Exchange Coupler Doherty Amplifier Architecture,” IEEE Journal of Solid-State Circuits, October 2021.
[65′] H. Nguyen and H. Wang, “A Coupler-Based Differential Doherty Power Amplifier with Built-In Baluns for High Mm-Wave Linear-Yet-Efficient Gbit/s Amplifications,” Proc. IEEE Radio Frequency Integrated Circuits, June 2019.
[66′] H. Nguyen and H. Wang, “A Coupler-Based Differential Mm-Wave Doherty Power Amplifier with Impedance Inverting and Scaling Baluns,” IEEE Journal of Solid-State Circuits, vol. 55, no. 5, pp. 1212-1223, May 2020.
[67′] F. Wang and H. Wang, “A Broadband Linear Ultra-Compact mm-Wave Power Amplifier With Distributed-Balun Output Network: Analysis and Design,” IEEE Journal of Solid-State Circuits, vol. 56, no. 8, pp. 2308-2323, August 2021.
[68′] M. Awad, P. Benech and J. Duchamp, “Design of Dickson rectifier for RF energy harvesting in 28 nm FD-SOI technology,” Joint International EUROSOI Workshop and International Conference on Ultimate Integration on Silicon, pp. 1-4, May 2018.
[69′] M. Huang, T. Chi, F. Wang and H. Wang, “An All-Passive Negative Feedback Network for Broadband and Wide Field-of-View Self-Steering Beam-Forming With Zero DC Power Consumption,” IEEE Journal of Solid-State Circuits, vol. 52, no. 5, pp. 1260-1273, May 2017.
[70′] T. S. Rappaport et al., “Millimeter wave mobile communications for 5G cellular: It will work!” IEEE Access, vol. 1, pp. 335-349, May 2013.
[71′] S. Rangan, T. S. Rappaport, and E. Erkip, “Millimeter-wave cellular wireless networks: Potentials and challenges,” Proc. IEEE, vol. 102, no. 3, pp. 366-385, March 2014.
[72′] V. Camarchia, R. Quaglia, A. Piacibello, D. P. Nguyen, H. Wang, and A.-V. Pham, “A review of technologies and design techniques of millimeter-wave power amplifiers,” IEEE Transactions on Microwave Theory and Techniques, vol. 68, no. 7, pp. 2957-2983, July 2020.
[73′] “3GPP 5G-NR specifications.” http://www.3gpp.org/DynaReport/38-series.htm (accessed April, 2020).
[74′] S. Lee, M.-Y. Huang, Y. Youn and H. Wang, “A 15-55 GHz Low-Loss Ultra-Compact Folded Inductor-Based Multi-Section Wilkinson Power Divider for Multi-Band 5G Applications,” IEEE MTT-S International Microwave Symposium, pp. 432-435, July 2019.
[75′] U. Basumata, A. Mondal, S. Das and H. Rahaman, “Design of Two-Stage Fully-Differential Driver in SAR ADC with Indirect Feedback Compensation Technique,” International Symposium on Devices, Circuits and Systems, pp. 1-5, April 2021.
[76′] O. H. Schade and E. J. Kramer, “A low-voltage BiMOS op amp,” IEEE Journal of Solid-State Circuits, vol. 16, no. 6, pp. 661-668, December 1981.
[77′] M. Franciotta, G. Colli and R. Castello, “A 100-MHz 4-mW four-quadrant BiCMOS analog multiplier,” IEEE Journal of Solid-State Circuits, vol. 32, no. 10, pp. 1568-1572, October 1997.
[78′] Bosen Tzeng, Chun-Hsien Lien, H. Wang, Yu-Chi Wang, Pane-Chane Chao and Chung-Hsu Chen, “A 1-17-GHz InGaP—GaAs HBT MMIC analog multiplier and mixer with broad-band input-matching networks,” IEEE Transactions on Microwave Theory and Techniques, vol. 50, no. 11, pp. 2564-2568, November 2002.
[79′] D. Munzer, N. S. Mannem, J. Lee and H. Wang, “A Broadband Mm-Wave Current/Voltage Sensing-based VSWR-Resilient True Power/Impedance Sensor Supporting Single-Ended Antenna Interfaces,” IEEE Journal of Solid-State Circuits, In Press.

What we claim is:

1. A system comprising:
a set of amplifiers, wherein each of the set of amplifiers is connected via an output transmission line to a respective phased array antenna element of a phased array antenna; and
a set of built-in self-test circuits, including a first built-in self-test circuit, wherein each of the set of built-in self-test circuits is configured to measure a voltage standing wave ratio (VSWR) or load impedance deviation for a respective amplifier of the set of amplifiers, including a first amplifier (e.g., to reconfigure the respective amplifier to compensate for phased array antenna element coupling or other couplings),
wherein the first built-in self-test circuit comprises:
a self-test circuit sensing circuit configured to output a sensed power signal and a sensed impedance signal, via coupler-based sensing, as the measure of the voltage standing wave ratio (VSWR) or load impedance deviation;
a first sensing electromagnetic (EM) structure as a first sensing transmission line that is co-located to the output transmission line to be capacitively coupled therewith, the first sensing electromagnetic structure having (i) a first end that connects to a corresponding end of the output transmission line through a pre-defined impedance and (ii) a second end that connects to a first input of the built-in self-test circuit sensing circuit; and
a second sensing electromagnetic structure as a second sensing transmission line that is co-located to the output transmission line to be capacitively coupled therewith, the second sensing electromagnetic structure having (i) a first end that connects to an impedance element having a value corresponding the phased array antenna element and (ii) a second end that connects to a second input of the built-in self-test circuit sensing circuit.

2. The system of claim 1, wherein the first sensing electromagnetic structure and the second sensing electromagnetic structure each has a length of λ/4.

3. The system of claim 1, wherein the self-test circuit sensing circuit includes an impedance sensing circuit comprising (i) a first amplitude detector (e.g., multi-stage Dickson rectifier) for a first sensed signal at the first input and (ii) a second amplitude detector (e.g., multi-stage Dickson rectifier) for a second sensed signal at the second input, wherein one of the first sensed signal or the second sensed signal corresponds to a sensed current signal and the other to a sensed voltage signal, and wherein the sensed current signal and sensed voltage signal are combined to a provide the sensed impedance signal.

4. The system of claim 3, wherein the first amplifier comprises an output matching network that connects to a first output of the self-test circuit sensing circuit, wherein the output matching network is configured to receive the sensed impedance signal to adjust output of the first amplifier to compensate for phased array antenna element coupling or other couplings.

5. The system of claim 1, wherein the self-test circuit sensing circuit includes an impedance sensing circuit comprising (i) a first phase shifter (e.g., multi-stage Dickson rectifier) for a first sensed signal at the first input and (ii) a second phase shifter (e.g., multi-stage Dickson rectifier) for a second sensed signal at the second input, wherein the one of the first sensed signal or the second sensed signal corresponds to a sensed current signal and the other to a sensed voltage signal, and wherein the sensed current signal and sensed voltage signal are combined to a provide the sensed power signal.

6. The system of claim 5, wherein the first amplifier comprises an output matching network that connects to a second output of the self-test circuit sensing circuit, wherein the output matching network is configured to receive the sensed power signal to adjust output of the first amplifier to compensate for phased array antenna element coupling or other couplings.

7. The system of claim 5, wherein the first phase shifter or the second phase shifter is configured to provide a 90° shift.

8. The system of claim 1, wherein the output transmission line, the first sensing electromagnetic structure, and the second sensing electromagnetic structure are fabricated in a multilayer structure, wherein the output transmission line is located on a first layer, wherein the first sensing electromagnetic structure is located on a second layer immediately above or proximal on the same layer to the first layer, and wherein the second sensing electromagnetic structure is located on a third layer immediately below or proximal to on the same layer to the first layer.

9. The system of claim 5, wherein the self-test circuit sensing circuit includes a power sensing circuit to combine the sensed current signal and sensed voltage signal, wherein the power sensing circuit includes an analog multiplier circuit.

10. The system of claim 1 further comprising the phased array antenna.

11. The system of claim 5, wherein at least one of the first phase shifter or the second phase shifter comprises a multi-stage Dickson rectifier.

12. The system of claim 1, wherein the system comprises a phased array RADAR system, phased array RADAR antenna component, a 5G and/or mmWave base station, a 5G or mmWave handset, or a 5G or mmWave phased array antenna component.

13. The system of claim 1, wherein the self-test circuit sensing circuit is configured to generate one or more test signals, via the coupler-based sensing, at one or more antenna array elements to be coupled to one or more adjacent or nearby antenna array elements to evaluate complex coupling, coefficient matrix, power flow, and impedance mismatches for multi-elements or all of the array.

14. The system of claim 13, wherein each antenna element, or a portion of the antenna elements, is coupled with a transmitter element.

15. The system of claim 13, wherein each antenna element, or a portion of the antenna elements, is coupled with a receiver element.

16. A method of compensating for phased array element coupling error during operation of a phased array antenna (e.g., phased array RADAR system, a 5G and/or mmWave base station, or a 5G or mmWave handset), the method comprising:
measuring a voltage standing wave ratio (VSWR) or load impedance deviation for an amplifier of a phased array element comprising a sensed power signal and a sensed impedance signal (e.g., impedance magnitude signal) measured at a set of sensing electromagnetic (EM) structures co-located to an output transmission line connecting between the amplifier and phased array element, wherein the set of sensing electromagnetic (EM) structures includes:
a first sensing electromagnetic (EM) structure as a first sensing transmission line that is co-located to the output transmission line to be capacitively coupled therewith, the first sensing electromagnetic structure having (i) a first end that connects to a corresponding end of the output transmission line through a pre-defined impedance and (ii) a second end that connects to a first input of the built-in self-test circuit sensing circuit; and
a second sensing electromagnetic structure as a second sensing transmission line that is co-located to the output transmission line to be capacitively coupled therewith, the second sensing electromagnetic structure having (i) a first end that connects to an impedance element having a value corresponding the phased array antenna element and (ii) a second end that connects to a second input of the built-in self-test circuit sensing circuit; and
reconfiguring (i) the amplifier, (ii) a phased array element associated circuit, or (iii) a combination thereof, using the sensed power signal and the sensed impedance signal.

17. The method of claim 16, wherein the measuring the voltage standing wave ratio (VSWR) or load impedance deviation includes:
sensing amplitude signals, as the sensed impedance signal, corresponding to impedance magnitude via sensing circuitries connected the first sensing electromagnetic (EM) structure and the second sensing electromagnetic (EM) structure.

18. The method of claim 16, wherein the measuring the voltage standing wave ratio (VSWR) or load impedance deviation includes:
generating at least one phased shifted signal via an analog circuitry from at least one signal sensed by the first sensing electromagnetic (EM) structure or the second sensing electromagnetic (EM) structure; and
combining (i) the phased shifted signal and (ii) the other of the first sensing electromagnetic (EM) structure or the second sensing electromagnetic (EM) structure not used to generate the phased shifted signal to generate the sensed power signal.

19. The method of claim 18, wherein the phased shifted signal is 90° shifted.

20. The method of claim 18 further comprising:
measuring the voltage standing wave ratio (VSWR) or load impedance deviation for a second amplifier of a second phased array element comprising a second sensed power signal and a second sensed impedance signal (e.g., impedance magnitude signal) measured at a second set of sensing electromagnetic structures co-located to a second output transmission line connecting between the second amplifier and the second phased array element (e.g., wherein the second set of sensing electromagnetic (EM) structures includes (a) a first sensing electromagnetic (EM) structure as a first sensing transmission line that is co-located to the output transmission line to be capacitively coupled therewith, the first sensing electromagnetic structure having (i) a first end that connects to a corresponding end of the output transmission line through a pre-defined impedance and (ii) a second end that connects to a first input of the built-in self-test circuit sensing circuit; and (b) a second sensing electromagnetic structure as a second sensing transmission line that is co-located to the output transmission line to be capacitively coupled therewith, the second sensing electromagnetic structure having (i) a first end that connects to an impedance element having a value corresponding the phased array antenna element and (ii) a second end that connects to a second input of the built-in self-test circuit sensing circuit; and
reconfiguring (i) the second amplifier, (ii) a second phased array element associated circuit, or (iii) a combination thereof, using the second sensed power signal and the second sensed impedance signal.
